(19) United States
(12) Patent Application Publication
(10) Pub. No.: US 2025/0138260 A1
(43) Pub. Date: May 1, 2025

(54) SELF-ALIGNED BURIED HETERO STRUCTURE LASER STRUCTURES AND INTERPOSER

(71) Applicant: POET Technologies, Inc., Allentown, PA (US)

(72) Inventor: SURESH VENKATESAN, Los Gatos, CA (US)

(21) Appl. No.: 19/004,737

(22) Filed: Dec. 30, 2024

Related U.S. Application Data
(63) Continuation of application No. 18/109,490, filed on Feb. 14, 2023.
(60) Provisional application No. 63/310,194, filed on Feb. 15, 2022.

(51) Int. Cl. G02B 6/42; H01S 5/068; H01S 5/223

(52) U.S. Cl. CPC G02B 6/4227; G02B 6/4238; G02B 6/4245; G02B 6/4257; H01S 5/06825; H01S 5/2238

(57) ABSTRACT

A method of forming an assembly that includes a laser die having alignment aids and an interposer having a plurality of cavities and alignment aids formed in the plurality of cavities. One or more laser die is positioned in one or more cavity on the interposer substrate and locally heated to bond each laser die to contacts in the cavities of the interposer. The interposer substrate and the plurality of laser die are then heated to move the one or more die to aligned positions within the respective cavities. Complementary alignment aids on the laser die and in the interposer cavities facilitate the alignment of the laser die into aligned positions.

The present patent application is a continuation of U.S. patent application Ser. No. 18/109,490, filed on Feb. 14, 2023, entitled “SELF-ALIGNED BURIED HETERO STRUCTURE LASER STRUCTURES AND INTERPOSER”, which claims priority from U.S. Provisional Patent Applicant Ser. No. 63/310,194, filed on Feb. 15, 2022, entitled “SELF-ALIGNED BURIED HETEROSTRUCTURE LASER STRUCTURES AND INTERPOSER”, of the same inventors, hereby incorporated by reference in its entirety.

The present application relates to patent application Ser. No. 17/752,226, filed on May 24, 2022, entitled “SELF-ALIGNED RIDGE WAVEGUIDE LASER STRUCTURE, METHOD FOR FABRICATION, AND METHOD FOR USE WITH INTERPOSER-BASED PICS,” attorney docket OPE-113.

### FIELD OF THE INVENTION

Embodiments described herein are related to the formation of photonic integrated circuits, and more particularly, to the formation of buried heterostructure laser die structures used in photonic integrated circuits.

### BACKGROUND

Developments in the methods of manufacturing of photonic integrated circuits (PICs) have enabled the fabrication and integration of optical, optoelectrical, and electrical devices on the same interposer substrates. In some applications, pre-fabricated optoelectrical die are integrated within the PICs to provide functionality that may not be obtainable with similar devices formed directly on or within the PIC interposer. Semiconductor lasers that emit at specific optical wavelengths used in telecommunications applications for transmission through optical fiber cables, for example, are readily fabricated from indium phosphide and gallium arsenide compound semiconductor materials, but the fabrication of these devices is not practical or technologically achievable using silicon-based materials. The benefits of decades of development in silicon processing can thus benefit with the integration of lasers formed from compound semiconductor materials into silicon-based PIC substrates to obtain the specific wavelength ranges provided by compound semiconductor lasers. One method of integration of these and other compound semiconductor devices is the formation of discrete compound semiconductor die that are suitable for mounting onto silicon-based PIC substrates and interposers.

The integration of discrete compound semiconductor lasers onto silicon-based interposers can benefit from mounting structures formed on the laser die that are compatible with mounting structures formed on the PIC interposer. Effective mounting structures accommodate the mechanical, electrical, and optical coupling requirements between laser die and the complementary interposers to which the die are mounted, and provide mechanical stability, electrical contact, and optical signal transfer between the laser die and optical devices on the interposer.

The integration of optoelectrical die into PICs can also benefit from structures that enable precise placement onto the interposer substrates, and that can enable subsequent passive alignment, after placement, of optical and electrical features on the die with optical and electrical features on the interposer. Optical output from an integrated laser die, for example, must align with optical planar waveguides or other optical devices on the interposer to enable efficient optical signal transfer with low loss between the laser and other optical or optoelectrical devices in interposer-based PICs. Methodologies that enable the implementation of passive alignment techniques that do not require direct feedback during the alignment process are preferable over techniques and integration schemes that require potentially time-consuming active alignment steps that require optical or electrical feedback.

The formation of mechanical alignment structures on optoelectrical die that are compatible with alignment structures that are formed on the PIC substrate, that are compatible with PIC fabrication techniques and methods and suitable for high-volume production, and that enable precise placement and a passive alignment methodology, can provide both technical and economic benefits in the formation of PICs that are fabricated using such mechanical alignment structures and the methodologies for implementing these structures.

Thus, a need in the art of PIC fabrication exists for compound semiconductor device structures and methods that can simplify the integration of optoelectrical devices such as lasers onto interposers and other substrates, and that provide suitable referencing and mounting schemes to enable effective alignment and coupling of the integrated die with waveguides and other optical devices on interposer.

### SUMMARY

Embodiments of a structure and methodology for providing mechanical alignment aids and fiducial alignment references on a buried heterostructure (BH) laser die are disclosed herein. The BH laser die formed with mechanical alignment aids, and the methods of formation of these structures, enable the integration of these laser die into photonic integrated circuits (PICs) onto interposers using passive alignment techniques to align the optical axes of the BH lasers with the optical axes of planar waveguides or other optical devices on the interposers.

Embodiments herein describe the BH laser structures and methods of formation of BH laser die with mechanical alignment aids. Also described herein are methods for achieving alignment of these laser die in PIC assemblies on interposer substrates that are formed with complementary mechanical alignment aids. BH laser die that are formed with mechanical alignment aids can facilitate the placement and subsequent alignment of these lasers on interposer substrates used in the fabrication of PICs.

Effective alignment of the optical axes of photonic circuit elements such as lasers and photodiodes with planar waveguides formed on the interposers facilitates optical signal transfer between the mounted optical circuit elements and the planar waveguides or other optical devices on the PIC interposer. In embodiments, semiconductor fabrication methods are used to form the mechanical alignment aids on BH laser die that are compatible with methods used in the formation of the epitaxial layer structures from which BH lasers are formed, and are thus compatible with existing BH laser fabrication processes and methods of fabrication.

Alignment aids described herein include vertical alignment aids, lateral alignment aids, and fiducials. The alignment aids are formed using etch stop layers positioned in BH laser layer structures, coupled with processing methodologies to form the alignment aids from these modified layer structures. In an embodiment, the vertical alignment aids, and vertical protrusions of lateral alignment aids are formed using etch stop layers positioned in the buried heterostructure laser layer structure coupled with a patterning methodology to form horizontal reference surfaces on the BH laser die that can be aligned with complementary horizontal reference surfaces on interposers to which the laser die can be coupled. Lateral alignment aids, in embodiments, are formed using a same mask layer as the ridge structure of the laser coupled with a patterning methodology to form vertical reference surfaces on interposers to which the laser die can be coupled. The vertical reference surfaces provide fiducials marks that are positioned in reference to the emission layer of the BH laser ridge structure. Use of a same mask layer, coupled with a same patterning method to form the ridge structures, the lateral alignment aids, and the fiducials, provides a BH laser structure on which these features are formed with a high degree of relative positional accuracy.

In an embodiment, a first etch stop layer is formed on a compound semiconductor substrate, and a first portion of a BH laser layer structure is formed on the first etch stop layer. The first portion of the BH laser layer structure is comprised of one or more semiconductor layers that may include one or more of one or more of an active layer, a waveguide layer, a confinement layer, a spacer layer, and a cladding layer, and other layers used in the formation of BH laser structures. A second etch stop layer is formed on the first portion of the BH laser layer structure. A first patterned hard mask layer is formed on the second etch stop layer, and this first hard mask is used in the patterning of the second etch stop layer, the first portion of the BH laser layer structure, the first etch stop layer, and a portion of the substrate to form a BH laser ridge structure, one or more lateral alignment aids, and one or more partially formed vertical alignment aids on the BH laser die. Following the formation of a current blocking layer, a second patterned mask layer is used in the patterning of one or more BH laser pedestals on the BH laser die. A third patterned mask layer, in this embodiment, is used to protect the BH laser pedestals containing the BH ridge structures, and is used in the patterning of a remaining portion of the one or more vertical alignment aids.

In embodiments, one or more lateral alignment aids and one or more vertical alignment aids are formed on a BH laser die. In some embodiments, the lateral alignment aids are pillar-type lateral alignment aids. In other embodiments, cavity-type lateral alignment aids are formed. Fiducials are formed from vertical surfaces on one or more of the lateral alignment aids.

The mechanical alignment aids that are formed on the buried heterostructure laser die are further used in combination with compatible alignment structures that are formed on interposer substrates wherein the interposers are used as substrates for forming PIC assemblies.

Other aspects and features of embodiments will become apparent to those skilled in the art upon review of the following detailed description in conjunction with the accompanying figures.

### BRIEF DESCRIPTION OF THE FIGURES

The accompanying drawings illustrate various embodiments of systems, methods, and other aspects of the invention. It will be apparent to a person skilled in the art that the illustrated element boundaries (e.g., boxes, groups of boxes, or other shapes) in the figures represent one example of the boundaries. In some examples, one element may be designed as multiple elements, or multiple elements may be designed as one element. In some examples, an element shown as an internal component of one element may be implemented as an external component in another, and vice versa.

Various embodiments of the present invention are illustrated by way of example, and not limited by the appended figures, in which like references indicate similar elements, and in which:

FIG. 1A shows a cross section drawing of an embodiment of a BH laser die having multiple vertical alignment features and a single pillar-type lateral alignment feature that includes a self-aligned fiducial.

FIG. 1B shows an exploded cross section drawing of a PIC assembly that includes the embodiment of a BH laser die from FIG. 1A and an interposer formed with complementary alignment aids.

FIG. 1C shows a PIC assembly that includes the embodiment of a BH laser die from FIG. 1A and an interposer formed with complementary alignment aids: (i) Section A-A′ from (ii); (ii) top view of (i).

FIG. 2A shows a cross section drawing of an embodiment of a BH laser die having multiple vertical alignment features and multiple pillar-type lateral alignment features that include self-aligned fiducials.

FIG. 2B shows a cross section drawing of an embodiment of a BH laser die having vertical alignment features and a single cavity-type lateral alignment feature that includes self-aligned fiducials.

FIG. 2C shows a cross section drawing of an embodiment of a BH laser die having vertical alignment features and multiple cavity-type lateral alignment features that include self-aligned fiducials. Inset shows a top-down view of the cavity in the embodiment.

FIG. 3 shows a flowchart for an embodiment of a method of forming a BH laser die with vertical and lateral alignment aids.

FIGS. 4(i)-4(xiii) show cross section drawings of some steps in an embodiment of a method of forming a BH laser die having vertical and lateral alignment aids.

FIG. 5 shows a flowchart for an embodiment of a method of forming a BH laser die with vertical alignment aids.

FIG. 6 show cross section drawings of some steps in an embodiment of a method of forming a BH laser die with vertical alignment aids.

FIG. 7 shows a flowchart for an embodiment of a method of forming a BH laser die with lateral alignment aids.

FIG. 8 shows cross section drawings of some steps in an embodiment of a method of forming a BH laser die with lateral alignment aids.

FIGS. 9(i)-9(iv) show cross section drawings of embodiments of BH laser die formed with alignment aids and positioned on interposers with complementary alignment aids and complementary planar waveguide layer configurations. The drawings show some example positionings of first and second etch stop layers used in the formation of the BH laser die alignment aids for each embodiment shown.

FIG. 10(i) shows a cross section of an embodiment of a BH laser die having alignment aids for which the spacing between the optical axis of the active layer of the BH laser and the first etch stop layer is formed to be equal to, or approximately equal to, the spacing between the top of the vertical alignment aid and the optical axis of the planar waveguide layer on the interposer, and (ii) shows an enlargement of a dotted line enclosed portion of the embodiment in (i).

FIG. 11A(i) shows a cross section drawing of a complementary interposer configured for mounting a BH laser die having alignment aids in which the planar waveguide layer of the interposer is positioned near the top of an alignment pillar, and (ii) shows a cross section drawing of a complementary interposer configured for mounting a BH laser die having alignment aids in which the planar waveguide layer of the interposer is positioned further from the top surface of the pillar than in (i).

FIG. 11B(i) shows a cross section drawing of an embodiment of a BH laser die having alignment aids positioned on the complementary interposer configuration from FIG. 11A(i) with a planar waveguide layer positioned near the top of the alignment pillar on the interposer, and (ii) shows a cross section drawing of an embodiment of a BH laser die having alignment aids on a complementary interposer configuration from FIG. 11A(ii) with a planar waveguide layer positioned further from the top surface of the alignment pillar on the interposer.

FIG. 11C(i) shows a cross section drawing of an interposer on which the alignment aids that align with complementary vertical alignment aids on an embodiment of a BH laser die are formed at a first height, and the alignment aids that provide a lateral constraint for lateral alignment aids are formed at a second height, and for which the vertical alignment aids at the first height is lower than the lateral alignment aid at the second height, (ii) shows a cross section drawing of an interposer on which the alignment aids that align with complementary vertical alignment aids on an embodiment of a BH laser die are formed at a first height, and the alignment aids that provide a lateral constraint for lateral alignment aids on the BH laser die are formed at a second height, and for which the vertical alignment aids at the first height is taller than the lateral alignment aid at the second height.

FIG. 11D(i) shows a cross section drawing of an assembly that includes an embodiment of a BH laser die having alignment aids that are complementary to the interposer configuration from FIG. 11C(i), and (ii) shows a cross section drawing of an assembly that includes an embodiment of a BH laser die having alignment aids that are complementary to the interposer configuration from FIG. 11C(ii).

FIG. 11E shows cross section drawing of an assembly that includes an embodiment of a BH laser die having alignment aids that are complementary to an interposer configured with alignment aids for which the vertical alignment aids are lower than those for the lateral alignment aids; the BH laser has an optional first etch stop layer that is not used in the formation of either the vertical or lateral alignment aids.

FIGS. 12A(i)-12A(iii) show cross section drawings of some steps in the formation of a BH laser die having alignment aids for an embodiment that includes multiple pillar-type lateral alignment aids.

FIGS. 12B(i)-12B(iii) show cross section drawings of some steps in the formation of a BH laser die having alignment aids for an embodiment that includes a single cavity-type lateral alignment aid.

FIGS. 12C(i)-12C(iii) show cross section drawings of some steps in the formation of a BH laser die having alignment aids for an embodiment that includes multiple cavity-type lateral alignment aids.

FIG. 13 shows a flowchart for a method of forming an interposer with alignment aids.

FIGS. 14A(i)-14A(x) show perspective drawings of some steps in the formation of an interposer with alignment aids.

FIG. 14B(i) shows a cross section drawing of an example planar waveguide structure on an interposer base structure, (ii) shows a cross section drawing of an example electrical interconnect layer structure on an interposer.

FIG. 15A(i) shows an exploded cross section drawing of an assembly that includes an embodiment of a BH laser die having multiple pillar-type alignment aids on an interposer with complementary alignment aids; (ii) shows a cross section drawing of the assembly from (i); and (iii) shows a top view drawing of the assembly in (ii).

FIG. 15B(i) shows an exploded cross section drawing of an assembly that includes an embodiment of a BH laser die having a single cavity-type alignment aid on an interposer with complementary alignment aids; (ii) shows a cross section drawing of the assembly from (i); and (iii) shows a top view drawing of the assembly in (ii).

FIG. 15C(i) shows an exploded cross section drawing of an assembly that includes an embodiment of a BH laser die having multiple cavity-type alignment aids on an interposer with complementary alignment aids; (ii) shows a cross section drawing of the assembly from (i); and (iii) shows a top view drawing of the assembly in (ii).

FIG. 16 shows a flow chart of an embodiment for a method of forming one or more PIC assemblies that include one or more BH laser die having alignment aids and an interposer.

FIG. 17A shows perspective drawings of a substrate having a multitude of BH laser die having alignment aids formed using wafer level fabrication techniques: (i) after BH laser die singulation, and (ii) after configuring to accommodate pick and place apparatus.

FIG. 17B shows a perspective drawing of an interposer formed having complementary alignment aids to the alignment aids of the embodiment of the BH laser die of FIG. 17A.

FIG. 17C(i) shows a perspective drawing of an interposer die having complementary alignment aids after placement of a first BH laser die into a first alignment position.

FIG. 17C(ii) shows a cross section drawing of an embodiment of a BH laser die having alignment aids positioned over a first alignment position of an interposer die.

FIG. 17C(iii) shows a cross section drawing of an embodiment of a BH laser die having alignment aids after placement in a first alignment position on an interposer die.

FIG. 17D shows a cross section drawing of an embodiment of a BH laser die having alignment aids after placement and after localized heating of the solder contacts to affix the BH laser die into a first alignment position on the interposer die.

FIG. 17E(i) shows a perspective drawing of an interposer die having complementary alignment aids after placement of a second BH laser die into a first alignment position.

FIG. 17E(ii) shows a perspective drawing of a portion of an interposer substrate showing a multitude of interposer die after placement of multiple BH laser die on each interposer die.

FIG. 17F(i) shows a perspective drawing of an interposer die having complementary alignment aids after a wafer level heating step that has moved the first and second BH laser die from first alignment positions on the interposer die to a second alignment position on the interposer die.

FIG. 17F(ii)-17F(iv) show cross section drawings of an embodiment of a BH laser having alignment aids after placement and initial localized heating, and after the application of wafer level heating in a reflow step: (ii) the solder contacts begin to melt; (iii) the solder contacts have melted and the BH laser die has begun to move from a first alignment position toward a second alignment position on the interposer die leading to a reduction in the gap between the facet of the laser and the facet of the waveguide in the interposer; and (iv) the solder contacts have melted and the BH laser die has moved from the first alignment position to a second alignment position on the interposer die closing the gap between the facet of the laser and the facet of the waveguide in the interposer.

FIG. 17G(i) shows a top view drawing of an embodiment of a BH laser die having alignment aids after wafer level solder reflow step in which the gap between the facet of the BH laser and the facet of the waveguide on the interposer die has narrowed and the optical axis of the BH laser die has been brought into alignment with the optical axes of a planar waveguide on an interposer die having complementary alignment aids. The approximate position of the BH laser die at placement, prior to the reflow heating and alignment step is shown in dotted outline as labeled.

FIG. 17G(ii) shows Section A-A′ from the top view of FIG. 17G(i).

FIG. 17G(iii) shows Section B-B′ from the top view of FIG. 17G(i) FIG. 18A(i) shows an embodiment of a BH laser die with example pillar-type alignment aids after placement in an interposer cavity in a first placement position; placement is within an example boundary of a placement range for a pick and place apparatus as shown by the dotted line, and (ii) shows an embodiment of a BH laser die after a reflow alignment process.

FIG. 18B shows a top view of an embodiment of a BH laser die with example cavity-type alignment aids and pillar-type alignment aids after placement and alignment in an interposer cavity; dotted lines show an example boundary for an example placement tolerance for a placement step for a pick and place apparatus.

FIG. 19A(i)-(ix) show some example pillar-type alignment aids (solid lines) for embodiments of a BH laser die with example complementary alignment aids on an interposer (dotted lines) in an example placement position and after alignment using a reflow process.

FIG. 19B(i)-(viii) show some example cavity-type alignment aids (solid lines) for embodiments of a BH laser die with example pillar-type complementary alignment aids on an interposer (dotted lines) in an example placement position and after alignment using a reflow process (arrows show an example point of contact between the alignment aids on the BH laser die and the alignment aids on the interposer.) FIG. 20A shows an embodiment of a BH laser with alignment aids configured with multiple ridge structures.

FIG. 20B(i) shows another embodiment of a BH laser with alignment aids configured with multiple ridge structures and aligned with planar waveguides formed on the interposer substrate; ridge structures are formed within each of the pedestal structures shown, (ii) shows an enlarged portion from (i).

Further areas of applicability of the present invention will become apparent from the detailed description provided hereinafter. It should be understood that the detailed description of exemplary embodiments is intended for illustration purposes only and is, therefore, not intended to necessarily limit the scope of the present invention.

### DETAILED DESCRIPTION

Described herein are embodiments of a buried heterostructure (BH) laser structure having alignment aids and the method for forming such embodiments.

The ensuing description provides exemplary embodiment(s) only, and is not intended to limit the scope, applicability or configuration of the disclosure. Rather, the ensuing description of the exemplary embodiment(s) will provide those skilled in the art with an enabling description for implementing an exemplary embodiment. It being understood that various changes may be made in the function and arrangement of elements without departing from the spirit and scope as set forth in the appended claims.

Various embodiments, of the present invention will be described more fully herein with reference to the accompanying drawings. This invention may be, however, embodied in many different forms and should not be construed as limited to the embodiments described herein but rather that the embodiments described are intended to convey the scope of the invention to those skilled in the art. Accordingly, the present invention is not limited to the relative sizes and spacings illustrated in the accompanying figures.

An “alignment aid” and an “alignment feature” as used herein are synonymous and can be used interchangeably.

As used herein, an alignment aid, used interchangeably with alignment feature, is a structure that includes one or more surfaces that are used as either physical or visual references that facilitate the positioning or placement of a die or device onto a substrate or interposer.

An “interposer” as used herein and throughout this disclosure refers to, but is not limited to, a substrate that provides mechanical support and electrical or optical interface routing from one or more electrical, optical, and optoelectrical devices to another. Interposers are typically used to route optical or electrical connections from various devices or die that are mounted on, or connected to, the interposer, and can provide for the optical interfacing between optical devices mounted, formed, or connected thereon.

An “optical device” as used herein and throughout this disclosure refers to, but is not limited to, devices that respond to, generate, or transmit optical signals. Types of optical devices include waveguides, gratings, spectrometers, lasers, photodetectors, lenses, among others. Some optical devices such as lasers and photodetectors, among others, are also electrical devices, optoelectrical devices, or electro-optical devices.

An “optical waveguide” as used herein and throughout this disclosure refers to, but is not limited to, a medium for transmitting optical signals.

An “optical axis” as used herein and throughout this disclosure refers to, but is not limited to, an axis at or near the center of activity or primary functionality for an optical device. An optical axis is an imaginary line along which there is some degree of rotational symmetry in an optical system such as a waveguide or other optical device or structure. An optical axis may or may not be at the geometric center or middle of a device or a layer within an optical device. Optical axes, as used herein, are comprised of lateral projections and vertical projections. A lateral projection of an optical axis is a perspective of an optical axis as viewed in a “side view” drawing or a “cross section” drawing as provided herein. Lateral projections of an optical axis are taken from a direction normal to a plane formed between a vertical axis (the “z” axis) and a lateral axis (the “x” and “y” axes). Reference coordinate systems are provided throughout that illustrate the orientations for the “x”, “y”, and “z” axes shown in relation with other features and aspects of the embodiments described. A vertical projection of an optical axis is a perspective of an optical axis as viewed in a “top view”, “top-down view”, “bottom view”, and “bottom-up view”. Vertical projections of an optical axis are taken from a direction normal to a plane formed between the two lateral axes, namely, the “x” and “y” axes. A lateral projection of one or more optical axis is used herein to facilitate visualization of the alignment of the optical axes of multiple optical devices at a reference height or “z’ direction. A vertical projection of one or more optical axis is used herein to facilitate visualization of the alignment of the alignment of the optical axes of multiple optical devices at a reference lateral location, namely, in one or more of an “x” and “y” direction. An optical axis is not a physical structure on an optical device but rather an imaginary line that is positioned at a characteristic center of propagation for an optical signal through an optical device. The optical axis of an optical device, although not a physical feature, can be determined empirically, can be measured, can be modelled, can be approximated based on geometric considerations, among other techniques.

A “semiconductor” as used herein and throughout this disclosure refers to, but is not limited to, a material having an electrical conductivity value falling between that of a conductor and an insulator. The material may be an elemental material or a compound material. A semiconductor may include, but not be limited to, an element, a binary alloy, a tertiary alloy, and a quaternary alloy. Structures formed using a semiconductor or semiconductors may include a single semiconductor material, two or more semiconductor materials, a semiconductor alloy of a single composition, a semiconductor alloy of two or more discrete compositions, and a semiconductor alloy graded from a first semiconductor alloy to a second semiconductor alloy. A semiconductor may be one of undoped (intrinsic), p-type doped, n-typed doped, graded in doping from a first doping level of one type to a second doping level of the same type, and graded in doping from a first doping level of one type to a second doping level of a different type. Semiconductors may include, but are not limited to III-V semiconductors, such as those between aluminum (Al), gallium (Ga), and indium (In) with nitrogen (N), phosphorous (P), arsenic (As) and tin (Sb), including, for example, GaAs, InP, GaN, InAs, AlN, AlAs, and GaP. Other semiconductors may include, for example, InGaAsP, AlGaInAs, and other quaternary combinations that include In, Ga, Al, P, Sb, and Al. Compound semiconductors used in the formation of lasers and other optical and optoelectrical devices using these and other semiconductors are known in the art.

A “fiducial” as used herein and throughout refers to, but is not limited to, one or more of a vertical surface, a feature, a structure, and a portion of a structure, suitable for providing a locational reference. Locational references are commonly used in pattern recognition systems used in, for example, pick and place operations.

A “solder” as used herein and throughout this disclosure refers to, but is not limited to, a material (element, compound, and alloy) that has a low melting point (<400-500° C.) and has good bonding properties with other metals, and includes but is not limited to SnAgCu (SAC 105, SAC 305, SAC 405), SnAg, PbSn (95/5, 90/10), AuSn 80/20, InSn, and SnBi.

It should be understood that a “layer” as referenced herein may include a single material layer or a plurality of layers. For example, an “insulating layer” may include a single layer of a specific dielectric material such as silicon dioxide, or may include a plurality of layers such as one or more layers of silicon dioxide and one or more other layers such as silicon nitride, aluminum nitride, among others. The term “insulating layer” in this example, refers to the functional characteristic layer provided for the purpose of providing the insulation property, and is not limited as such to a single layer of a specific material. Similarly, an electrical interconnect layer, as used herein, refers to a composite layer that includes both the electrically conductive materials for transmitting electrical signals and the intermetal and other layers required to insulate the electrically conductive materials. An electrical interconnect layer may include a patterned layer of electrically conducting material such as copper or aluminum as well as an intermetal dielectric material such as silicon dioxide, and spacer layers above and below the electrically conductive materials, for example, among other layers. Additionally, references herein to a layer formed “on” a substrate or other layer may refer to the layer formed directly on the substrate or other layer or on an intervening layer or layers formed on the substrate or other layer. Like numbers in drawings refer to like elements throughout, and the various layers and regions illustrated in the figures are illustrated schematically.

References to “an embodiment”, “another embodiment”, “yet another embodiment”, “one example”, “another example”, “yet another example”, “for example” and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in an embodiment” does not necessarily refer to the same embodiment.

A BH laser structure having vertical and lateral alignment aids is formed with the inclusion of a first etch stop layer in an epitaxial film structure used in the formation of a vertical alignment aid, including a fiducial, and the inclusion of a second etch stop layer used in the formation of a lateral alignment aid. In embodiments, a vertical alignment aid is a structure that has a top surface that is configured to serve as a reference by the formation of a contact with a mating surface on an interposer or other substrate to establish a mounted position in the vertical direction, and a lateral alignment aid is a structure that has a side surface that is configured to serve as a reference by restricting the movement of the mounted BH laser die in one or more lateral directions by the formation of a contact with a mating surface on an interposer or other substrate.

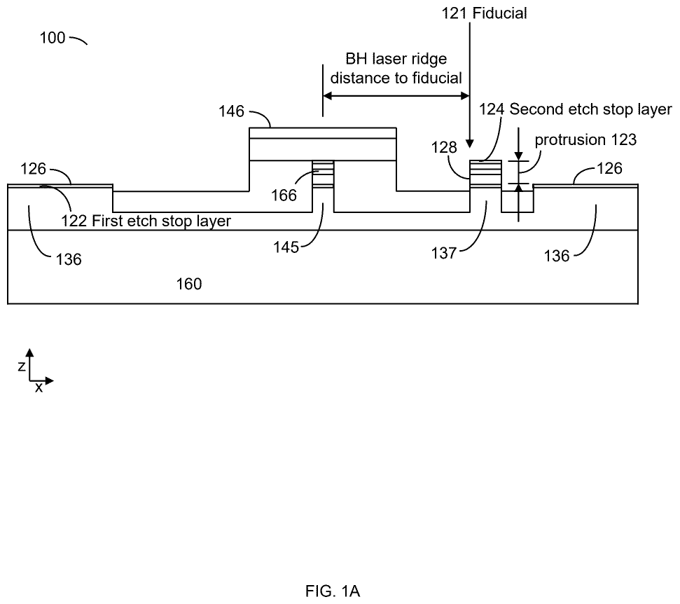

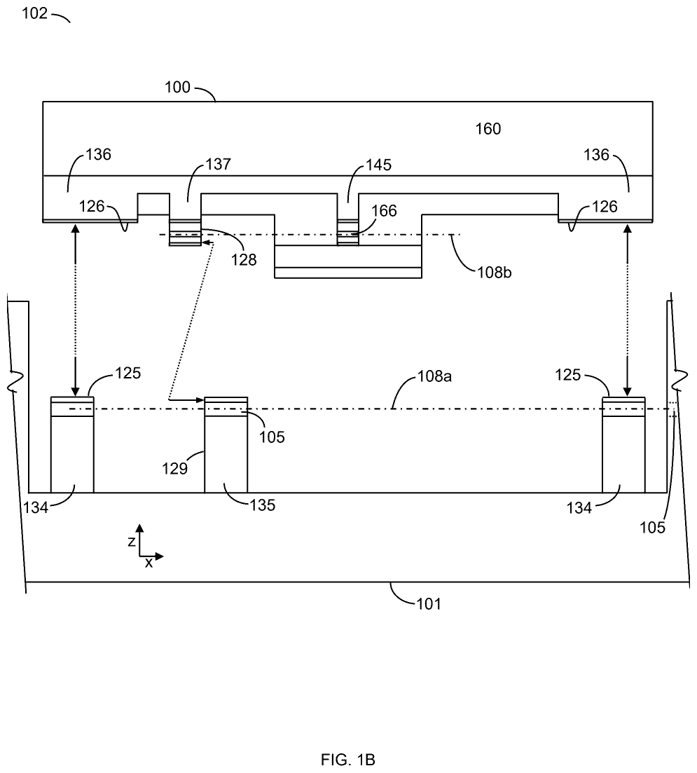

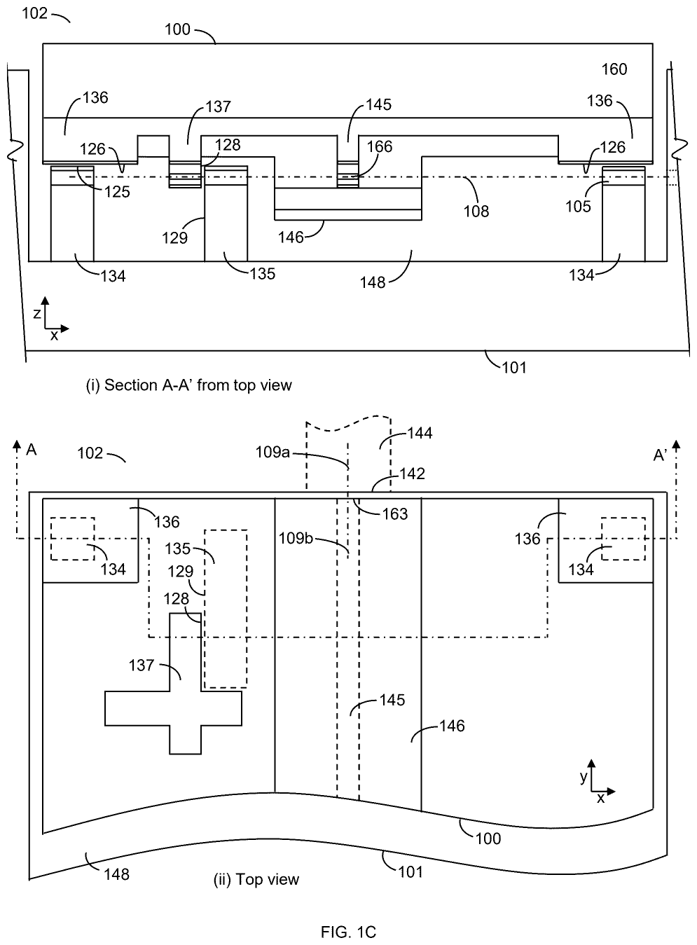

FIG. 1A shows a cross section drawing of an embodiment of a BH laser 100 having vertical alignment features 136 and a single pillar-type lateral alignment feature 137 that includes a fiducial 121.

As described herein, a vertical alignment feature 136 or vertical alignment aid 136 is a structure or structural element that facilitates alignment of mounted die in the vertical direction. The vertical direction, as used herein in the ensuing descriptions of embodiments, is the “z” direction shown in the reference coordinate system shown in FIGS. 1A and In other figures throughout. As described herein, a lateral alignment feature or lateral alignment aid is a structure or structural element that facilitates alignment in a lateral direction. A lateral direction, as used herein, is the “x” or “y” direction on the reference coordinate system shown in FIG. 1 and in other figures throughout this disclosure. The “x” direction is shown in the reference coordinate system shown in FIG. 1A and in other figures throughout. In FIG. 1A, the “y” direction is orthogonal to the x-y plane into the page.

The embodiment of the BH laser structure 100 shown in FIG. 1A has vertical alignment aid 136 that includes first etch stop layer 122 having top surface 126.

The embodiment of the BH laser structure 100 shown in FIG. 1A also has lateral alignment aid 137 that includes the second etch stop layer 124 and vertical surface 128. In embodiments, vertical surface 128 may be a smooth surface, as shown, or may be a rough surface, and may be vertical or near vertical. The lateral alignment aid 137 has protrusion 123 that, in the embodiment, extends vertically from the horizontal surface 126 of the vertical alignment aid 136 to the top of the second etch stop layer 124. Side surface 128 of the lateral alignment feature 137, as shown, provides self-aligned fiducial 121. The self-aligned fiducial 121 is formed using a same mask layer as the ridge 145 of BH laser 100, wherein the ridge 145 includes the active emission layer 166. Use of a same mask layer to pattern the ridge 145 and the lateral alignment aids 137 ensures that one or more vertical surfaces, or near vertical surfaces, are formed within the resolution of the lithographic and etching methods used in the patterning of the ridge 166 and the lateral alignment aids 137. Lithographic patterning can provide micron or sub-micron resolution, as can the processes used to etch the layers in the film structure. Fiducial 121 facilitates accurate placement of die using automated pick and place apparatus and the alignment of the active layer 166 with optical waveguides or other optical devices to which the BH laser die is to be coupled. The active layer 166 of buried heterostructure devices is formed within BH laser pedestal 146, and not accessible to the visual pattern recognition systems used in automated processing equipment that rely on fiducials to provide positioning reference. The formation of fiducials outside of the BH laser pedestal, at a known distance from the active emission layer 166 of the laser, is beneficial for reducing the required clearances for the components in forming an assembly that includes the BH laser, and is beneficial for achieving improved alignment of the optical axes of mounted die 100 with the optical axes of optical devices on the interposer portion of an assembly.

In the absence of fiducials that are formed in alignment with the BH laser emission layer, and in alignment with alignment features, the spacing tolerances and clearances between features must be expanded to compensate for the placement uncertainty. Highly accurate positioning of fiducial markings 121 in relation to the optical axis of the emitted radiation signal from the active emission layer 166 of the BH laser die 100, however, facilitate the use of feature sizes and spacings between feature sizes that can be formed without unnecessary or excess clearances. In FIG. 1A, the distance between the center, or any other location, of the active emission layer 166 to the fiducial 121 formed by vertical side 128 of lateral alignment aid 137, labeled, “BH laser ridge distance to fiducial”, can be known within the resolution of the lithographic patterning method used. In the figure, one of the two sides shown is labeled as the fiducial 121. Other vertical sides of the lateral alignment features 137 that are formed using the same patterning process as the ridge structure within which the active emission layer 166 resides may also be used to provide accurate fiducial marks 121.

The first etch stop layer 122 and second etch stop layer 124 are formed, in preferred embodiments, in layered compound semiconductor film structures using epitaxial crystallographic growth techniques. In FIG. 1A, BH laser 100 is formed on substrate 160. Substrate 160 is a substrate that facilitates growth of epitaxial film structures conducive to the formation of BH laser structures. Most notably, indium phosphide and gallium nitride compound semiconductor substrates are used in the formation of BH laser structures in common use. Other substrate materials may also be used that facilitate the formation of BH laser structures.

FIG. 1B shows an exploded cross section drawing of a photonic integrated circuit (PIC) assembly 102 that includes the embodiment of a BH laser die 100 from FIG. 1A and an interposer 101 formed with complementary alignment aids 134,135. An objective of embodiments is the alignment of the optical axis of the BH laser die 100 with the optical axis of a planar waveguide or other optical device formed on an interposer 101 or other substrate. After the initial positioning and placement of a BH laser die 100 onto a substrate with complementary alignment aids, facilitated by a fiducial 121 as shown, for example, in FIG. 1A, the alignment of the optical axes is further facilitated by the vertical alignment features 136 and lateral alignment features 137 in conjunction with the complementary alignment features 134, 135, respectively, formed on the interposer.

As described herein, an optical axis is an imaginary line through which there is some degree of rotational symmetry in an optical device. In a waveguide constructed from a uniform medium, for example, the optical axis may be the geometric center in the direction of propagation of an optical signal propagating through the waveguide. In a photodetector, for example, the optical axis may be the geometric center of the area within which an optical signal is received by the detector. In a laser, for example, the optical axis may be the geometric center of the emission layer or may be the geometric center of propagation for the waveguiding structure of the laser. The peak optical intensity of an optical signal in an optical system is commonly observed at the optical axis.

As described herein, an optical axis of an optical device, for example, can be viewed as having a lateral projection and a vertical projection. Alignment of the optical axes of two optical devices typically involves the alignment of the lateral projections of the two optical devices, the vertical projections of the two optical devices, and the optimization of the spacing between the facets of the two optical devices, wherein the facets are the faces through which the optical axes of the optical devices emerge perpendicularly from the device. The spacing between facets of two aligned optical devices is commonly minimized to provide maximum optical signal transfer between the two devices but other factors may also be need to be taken into consideration.

The alignment of two or more optical devices in the vertical direction, as used herein to illustrate the embodiments of the BH laser die, can be assessed with an examination of the lateral projections of the optical axes of the two optical devices, and conversely, the alignment of two or more devices in a lateral direction, as used herein, can be assessed with an examination of the vertical projections of the two optical devices.

The vertical direction, as used herein and labeled throughout as the “z” direction, is used in comparing, for example, the relative heights of a physical feature of two or more devices. Physical features of a device can include, for example, a layer or group of layers within a device, a mechanical structure such as an alignment aid, and an active portion of a device, among other physical features. The vertical direction can also be used to compare non-physical features of two or more optical devices such as, for example, the lateral projections of optical axes of optical devices. An example of a lateral projection of an optical axis, as used herein, is the projection that would appear in a cross section drawing of the optical axis that shows the relative height of the optical axis relative to other physical and non-physical features within the cross section drawing.

A lateral direction, as used herein and labeled throughout as an “x” or “y” direction, is used in comparing, for example the relative lateral positions, locations of two or more devices, and the relative lateral positions and locations of features of these devices, for example. A lateral direction can also be used to compare non-physical features of two or more optical devices such as, for example, the vertical projections of optical axes of optical devices. An example of a vertical projection of an optical axis, as used herein, is the projection that would appear in a top view drawing of the optical axis that shows the relative lateral position of the optical axis relative to other physical and non-physical features within the top view drawing.

In the exploded view in FIG. 1B, the vertical alignment features 136 having surfaces 126 are shown aligned to form contacts with the top surfaces 125 of the vertical alignment pillars 134 on interposer 101. As the surfaces 126 of the BH laser die 100 are brought into contact with the surfaces 125 of interposer 101, the lateral projection of the optical axis 108b of the BH laser die 100 is brought into alignment with the lateral projection of the optical axis 108a of the interposer 101. As the optical axes 108a,108b are brought into alignment, the emission layer 166 within the ridge 145 is brought into alignment with the planar waveguide layer 105 of the interposer 101.

It should be noted that portions of the planar waveguide layer 105 on the interposer 101, as further described herein, are used in the formation of the alignment pillars 134 and the planar waveguides to which the optical axes of the BH laser die 100 are to be aligned in the PIC assembly 102 shown in FIG. 1B. The alignment of the lateral projections 108b of the optical axis in BH laser die 100 with the optical axis 108a of a portion of the planar waveguide layer 105 on the alignment pillars 134 is similar to the alignment of planar waveguides formed elsewhere on interposer 101 from the same planar waveguide layer 105 for this embodiment. The relative height of the planar waveguide layer 105 and that of planar waveguides formed from the planar waveguide layer 105 is shown in dotted lines at the right portion of the drawing for reference. In the PIC assembly shown in FIG. 1B, the lateral projections of the optical axis 108b of the BH laser die 100 are thusly shown in alignment with the lateral projections of the optical axis 108a of the planar waveguide layer 105 shown in the alignment pillars 134, 135. Not shown in the assembly in FIG. 1B, but further described herein, the vertical projection of the optical axis of interposer 101 to which the vertical projection of the optical axis of the BH laser die 100 is to be aligned in the embodiment of PIC assembly 102, resides with a planar waveguide formed from the planar waveguide layer 105.

In the exploded view of the PIC assembly in FIG. 1B, lateral alignment feature 137 having side 128 is also shown in approximate alignment with lateral feature 135 having side 129 such that the lateral movement of the BH laser die 100 on the interposer 101 is restricted by the formation of the contact of the side 128 of the BH laser die feature 137 with the side 129 of the interposer feature 135. In the cross section drawing shown in FIG. 1A, for the embodiment shown, lateral movement of the BH laser die 100 is restricted on the interposer 101 in the “+x” direction as indicated by the reference coordinate system shown in FIG. 1B, when a contact between surfaces 128,129 is formed.

FIG. 1C(i) shows the unexploded cross section drawing of the PIC assembly of FIG. 1B that includes the embodiment of a BH laser die 100 from FIG. 1A and an interposer 101. The cross section is Section A-A′ from FIG. 1C(ii). FIG. 1C(ii) shows a top view of a portion of the BH laser die 100 and a portion of interposer 101.

In the assembly 102 in FIGS. 1C(i) and 1C(ii), the vertical alignment features 136 of the BH laser die 100 are shown positioned upon vertical alignment pillars 134 within a recess 148 formed in interposer 101. In FIG. 1C(i), the lateral projections 108a,108b of the optical axes of the BH laser die 100 and the interposer 101, respectively, are shown in alignment to form an aligned lateral projection of the optical axes 108 as a result of the horizontal surface 126 of the BH laser die 100 being brought into contact with the horizontal surface 125 of interposer 101. Alignment of the lateral projections of the optical axes 108a,108b to form the aligned lateral projection of the optical axes 108 of the PIC assembly 102 reflects the alignment of the active emission layer 166, for the embodiment of the BH laser die 100 shown in FIG. 1C(i), with the planar waveguide layer 105. It should be noted that in other embodiments the optical axis of the BH laser die 100 may not coincide with the geometric middle of layer 166, and that in these and other embodiments, the alignment of the lateral projections of the optical axis of the BH laser die and the optical axis on the interposer to which the optical axis of the BH laser is to be aligned, may require alignment structures 134,136 at heights that enable such alignment.

In the top view of the PIC assembly 102 shown in FIG. 1C(ii), a portion of BH laser die 100 is shown in recess 148 with solid lines depicting the features on the bottom side of the BH laser die 100 and the dotted lines depicting the hidden features on interposer 101. The perimeter of the interposer cavity 148 is shown with a solid line. FIGS. 1C(i) and 1C(ii) show BH laser pedestal 146 and ridge structure 145. In the top view of FIG. 1C(ii), the front facet 163 of the BH laser die 100 is shown in alignment with facet 142 of a planar waveguide 144 formed in the planar waveguide layer 105 of the interposer 101.

Also shown in the top view of FIG. 1C(ii) are the aligned vertical projections of the optical axis 109b of the BH laser die 100 and the optical axis 109a of a planar waveguide 144 on interposer 101 of the assembly 102. Alignment of the vertical projections of the optical axes 109a,109b of the BH laser die 100 and planar waveguide 144 in the PIC assembly 102 is facilitated in part by the restriction in lateral movement provided by the side surface 128 of the lateral alignment aid 135 of the BH laser die 100 forming a contact with the side surface 129 of the lateral alignment feature 135 of the interposer 101. The lateral alignment aids 137 on embodiments of the BH laser die 100 can be formed in a variety of shapes that facilitate the restriction in lateral movement, and that can be used in conjunction with a variety of complementary alignment aids 135 on the interposer 101. The embodiment of the BH laser die 100 in FIGS. 1A-1C, shows a single alignment pillar on the BH laser die 100 in the shape of a plus-sign in the top view. In other embodiments, more than a single lateral alignment pillar may be provided. And in yet other embodiments, other shapes for the alignment pillars 137 may be used that provide one or more contact surfaces 128, and that can be used in conjunction with complementary lateral alignment aids formed on an interposer 101.

In the PIC assembly 102, contact need not be formed between the sides 128,129 of the lateral alignment aids 137,135, respectively, for the movement of the die 100 to be constrained in a lateral direction on the interposer 101. The lateral alignment features, for example, may not make contact but rather may limit the movement should the side 128 of the BH laser die 100 form a contact with side 129 of the interposer 101, for example, in an assembly or alignment process. The potential range of movement, in the embodiment described in FIGS. 1A-1C is constrained in the “+x” direction and restricted in the “+y” direction by the lateral alignment aids 137 on the BH laser die 100 and the complementary alignment aids 135 on interposer 101. In the “+y” direction, a contact formed between the alignment aid 137 on the BH laser die 100 with the alignment aid 135 on the interposer 100 will limit the distance between facets 163, 142 of these two devices during one or more of an alignment and assembly process, for example. In other embodiments, as described herein, lateral movement can constrained, restricted, or constrained and restricted in one or more of the “+x” direction, the “−x” direction, the “+y” direction, and the “−y” direction, or any of a number of combinations of these directions, as referenced by the coordinate system superimposed on drawings herein.

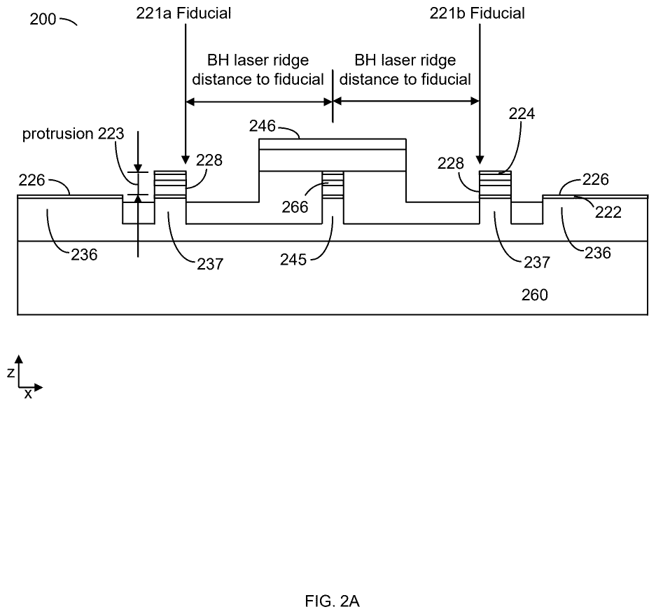

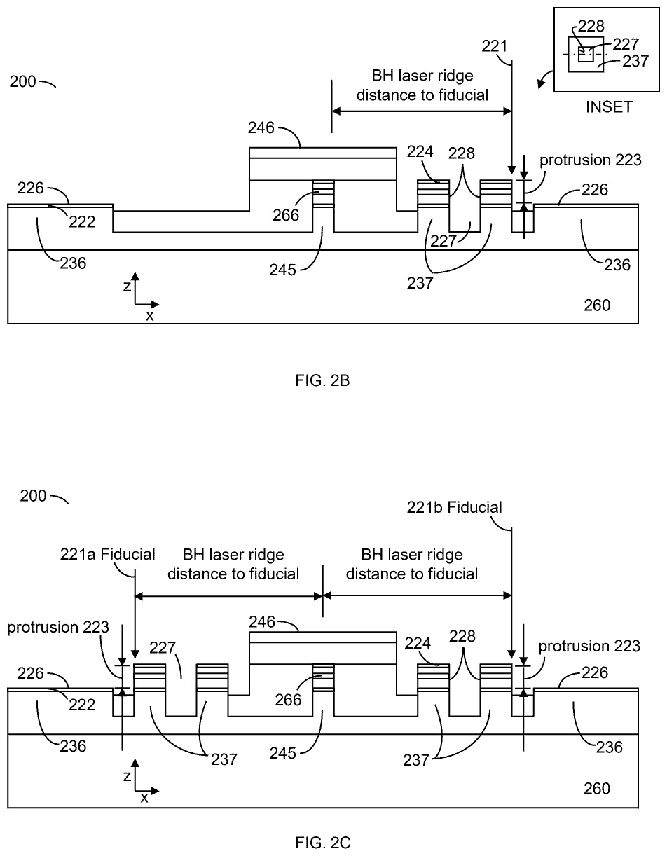

FIGS. 2A-2C show embodiments of BH laser die 200 having pillar-type lateral alignment features 237 that provide additional constraints in constraining and constricting lateral movement in comparison to the embodiment 100 shown in FIGS. 1A-1C, and that provide similar vertical alignment features.

FIG. 2A shows a cross section drawing of an embodiment of a BH laser die 200 with vertical alignment features 236 and multiple pillar-type lateral alignment features 237 that include fiducials 221a,221b. The vertical alignment features 236 having horizontal surfaces 226 as shown in FIG. 2A are similar to those shown in the embodiment of FIG. 1A. The lateral alignment pillars 237 have side surfaces 228 that provide fiducials 221a,221b that are formed at lithographically determined distances from the ridge structure 245 using a same mask layer as that used in the patterning of the ridge 245. The distances between the center of the ridge structure and the fiducials 221a,221b are indicated in FIG. 2A by the labels, “BH laser ridge distance to fiducial”. The precision to which the “BH laser ridge distance to fiducial” can be reliably positioned from the ridge 245 within the BH laser pedestal 246 is dependent on the lithographic patterning technique employed, and the etch or other patterning processes used to pattern the fiducial-containing alignment feature. Use of a same mask layer to pattern the ridge structure 245 and the lateral alignment aids 237 that include the fiducials 221, reduces the potential for additive misalignment when multiple masking layers and processes are used in the formation of the ridge structures 245 and the fiducials 221.

The distances between the ridge 245 having active layer 266, and the fiducials 221a, 221b are shown to be approximately equal in the embodiment in FIG. 2A. In other embodiments, the distances between the ridge 245 and two or more fiducial-containing alignment aids need not be the same. BH laser die 200 is formed on substrate 260 and includes first etch stop layer 222 and second etch stop layer 224. Protrusion 223 is formed with a height that is equal to, or approximately equal to, the distance between the top surfaces of the etch stop layers 222,224. The side surfaces 228 of the lateral alignment aids 237 are formed on the protrusion 223 of the lateral alignment aids 237. In an assembly with a substrate or interposer having complementary alignment features, such as one or more of the interposers described herein, the inclusion of multiple lateral alignment features 237 each with side surfaces 228 on embodiments of the BH laser die 200 can provide additional constraint to the lateral movement of the BH laser die 200 on the interposer in comparison to embodiments with a single lateral alignment feature such as the embodiment shown in FIG. 1A.

In addition to pillar-type alignment aids, such as the example embodiments shown in FIGS. 1A and 1B, on which one or more side surfaces are formed on a protruding structure that are available to form a contact with one or more pillar-type structures formed on a complementary interposer, other forms of lateral alignment aids may also be used. Cavity-type alignment aids, for example, are structures having an enclosed inner surface that can form an enclosure for a pillar-type alignment aid of an interposer.

FIG. 2B shows a cross section drawing of an embodiment of a BH laser die 200 with vertical alignment features 236 and a single, cavity-type lateral alignment feature 237 that includes self-aligned fiducial 221. The vertical alignment features 236 having horizontal surfaces 226 as shown in FIG. 2B are similar to those shown in the embodiment of FIG. 1A. The lateral alignment aids 237, in the embodiment shown in FIG. 2B, have side surfaces 228 that are formed at lithographically defined distances from the ridge 245 using a same mask layer used in the patterning of the ridge 245. Side surfaces 228 provide fiducial 221 at a known distance from the ridge 245 and active layer 266 as indicated by the label, “BH laser ridge distance to fiducial”. The precision to which the “BH laser ridge distance to fiducial” can be reliably positioned from the ridge 245 within the BH laser pedestal 246 is dependent on the lithographic patterning technique employed, and the etch or other patterning processes used to pattern the fiducial-containing alignment feature. Use of a same mask layer to pattern the BH laser ridge structure 245 and the alignment aids 237 eliminates the variation that can be present as a result of using multiple masking layers to form these features.

BH laser die 200 is formed on substrate 260 and includes first etch stop layer 222 and second etch stop layer 224. Protrusion 223 is formed with a height that is equal to, or approximately equal to, the distance between the top surfaces of the etch stop layers 222,224. The side surfaces 228 of the lateral alignment aids 237 are formed on the protrusion 223 of the lateral alignment aids 237. In FIG. 2B, the fiducial is shown as the outside edge of the feature 237 but other vertical sides of the feature 237 also provide fiducial reference marks and may also be used as fiducials 221.

Lateral alignment feature 237 shown in FIG. 2B is a cavity-type alignment feature having a cavity 227 with side surfaces 228. Side surfaces 228 in cavity 227, in an assembly with a substrate such as an interposer, can form a contact with a side surface of an alignment feature on the interposer to constrain the lateral movement of the die 200 on the interposer. Unlike the embodiment shown in FIG. 1A having a single pillar-type lateral alignment aid 137, the embodiment of the laser die 200 with the cavity-type alignment pillar 237 can constrain the movement in multiple lateral directions in that the cavity 227 has four internal side surfaces 228 that can form a contact with a complementary pillar-type lateral alignment feature on an interposer or other substrate to which the die 200 can be mounted (as further described herein.) In the INSET in FIG. 2B, a top view of an embodiment of a cavity-type lateral alignment feature is shown with surfaces 228 shown within the cavity. Each of the interior vertical walls of the cavity form a side surface 228 that can act to restrict or constrain lateral movement of the die 200 on a substrate to which the die 200 can be mounted.

FIG. 2C shows a cross section drawing of an embodiment of a BH laser die 200 having vertical alignment features 236 and multiple cavity-type lateral alignment features 237 that include self-aligned fiducials 221a,221b. The vertical alignment features 236 having horizontal surfaces 226 as shown in FIG. 2C are similar to those shown in the embodiment of FIG. 1A. The lateral alignment aids 237, in the embodiment shown in FIG. 2C, have side surfaces 228 that are formed at lithographically defined distances from the ridge 245 in the lithographic pattern used in the patterning of the ridge 245 and the lateral alignment feature 237. Side surfaces 228 provide fiducials 221a,221b at a known distance or distances from the ridge 245 and active layer 266 as indicated by the label, “BH laser ridge distance to fiducial”. The precision to which the “BH laser ridge distance to fiducial” can be reliably positioned from the ridge 245 within the BH laser pedestal 246 is dependent on the lithographic patterning technique employed, and the etch or other patterning processes used to pattern the fiducial-containing alignment feature. The distances between the ridge 245 having active layer 266, and the fiducials 221a, 221b are shown to be approximately equal in the embodiment in FIG. 2A. In other embodiments, the distances between the ridge 245 and two or more fiducial-containing alignment aids need not be the same.

BH laser die 200 is formed on substrate 260 and includes first etch stop layer 222 and second etch stop layer 224. Protrusion 223 is formed with a height that is equal to, or approximately equal to, the distance between the top surfaces of the etch stop layers 222,224. The side surfaces 228 of the lateral alignment aids 237 are formed on the protrusion 223 of the lateral alignment aids 237. BH laser die 200 is formed on substrate 260 and includes first etch stop layer 222 and second etch stop layer 224. Protrusion 223 is formed with a height that is equal to, or approximately equal to, the distance between the top surfaces of the etch stop layers 222,224. The side surfaces 228 of the lateral alignment aids 237 are formed on the protrusion 223 of the lateral alignment aids 237. In FIG. 2C, the fiducials are shown as the outside edges of the features 237 but one or more other vertical sides of the feature 237 may also be used as a fiducial 221a,221b. Lateral alignment features 237 shown in FIG. 2C are cavity-type alignment features having cavities 227 with side surfaces 228. Side surfaces 228 in cavities 227, in an assembly with a substrate such as an interposer, can form a contact with a side surface of an alignment feature on the interposer to constrain the lateral movement of the die 200 on the interposer. Unlike the embodiment shown in FIG. 1A having a single pillar-type lateral alignment aid 137, the embodiment of the laser die 200 with cavity-type alignment pillars as shown in FIGS. 2B and 2C, can constrain the movement in multiple lateral directions in that a cavity 227 has four internal side surfaces 228 that can form a contact with a complementary pillar-type lateral alignment feature on an interposer or other substrate to which the die 200 can be mounted (as further described herein.) In the INSET in FIG. 2B, a top view of an embodiment of a cavity-type lateral alignment feature is shown with inside surface 228, similar to the embodiment shown in FIG. 2C. Each of the interior vertical walls of the cavity form a side surface 228 that can act to restrict or constrain lateral movement of the die 200 on a substrate to which the die 200 can be mounted. The embodiments shown in FIGS. 2A and 2C show BH laser die 200 having multiple lateral alignment aids 237 that are all either pillar-type or cavity-type alignment aids. In other embodiments, one or more pillar-type alignment aid may be combined in whole or in part with one or more cavity-type alignment aids.

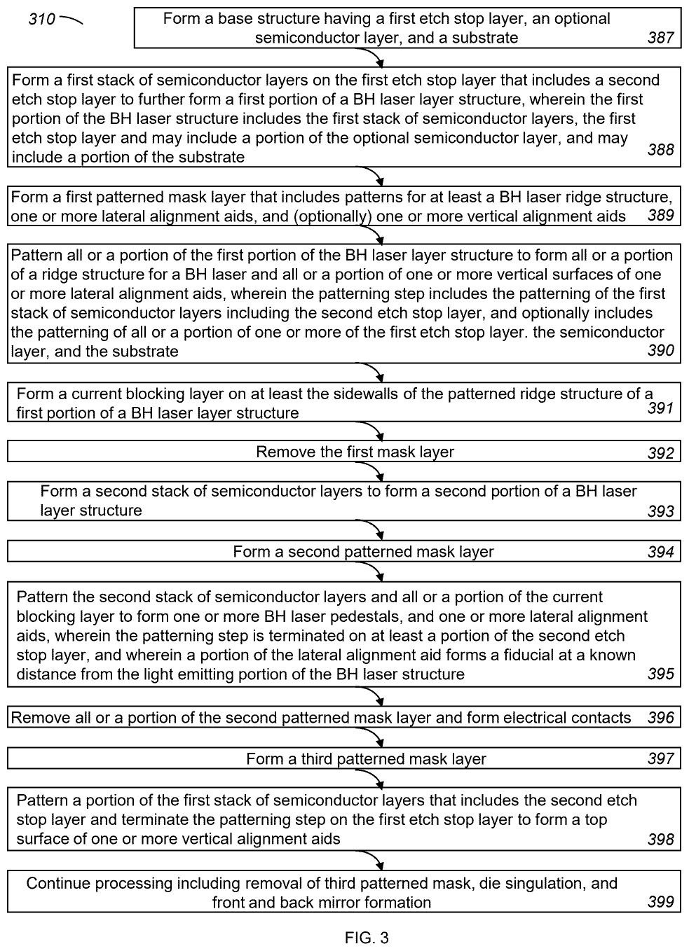

FIG. 3 shows a flowchart for an embodiment of a method 310 of forming a BH laser die having one or more lateral alignment aids and having a vertical alignment aid formed from a first etch stop layer.

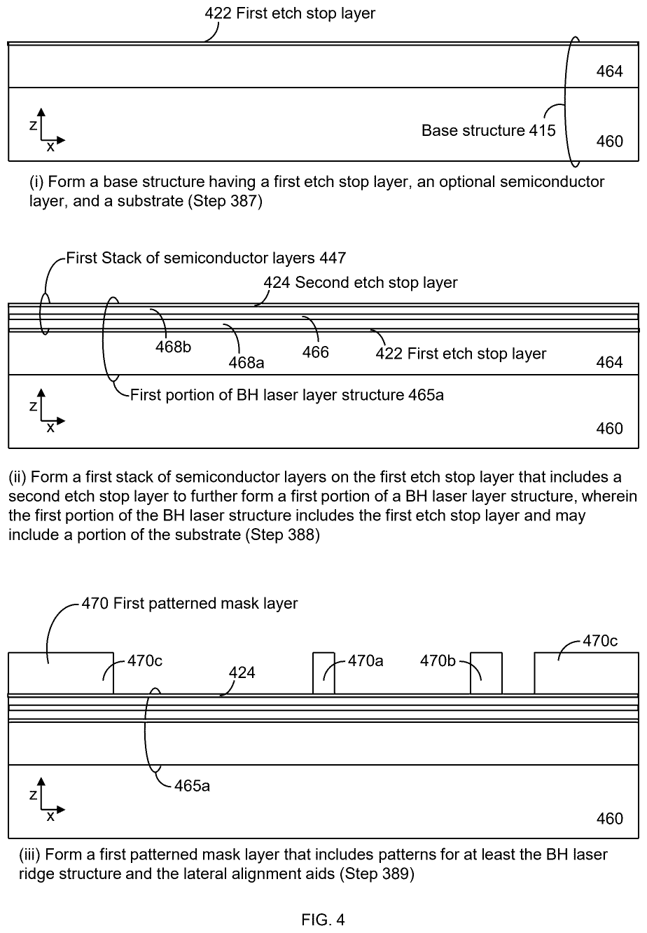

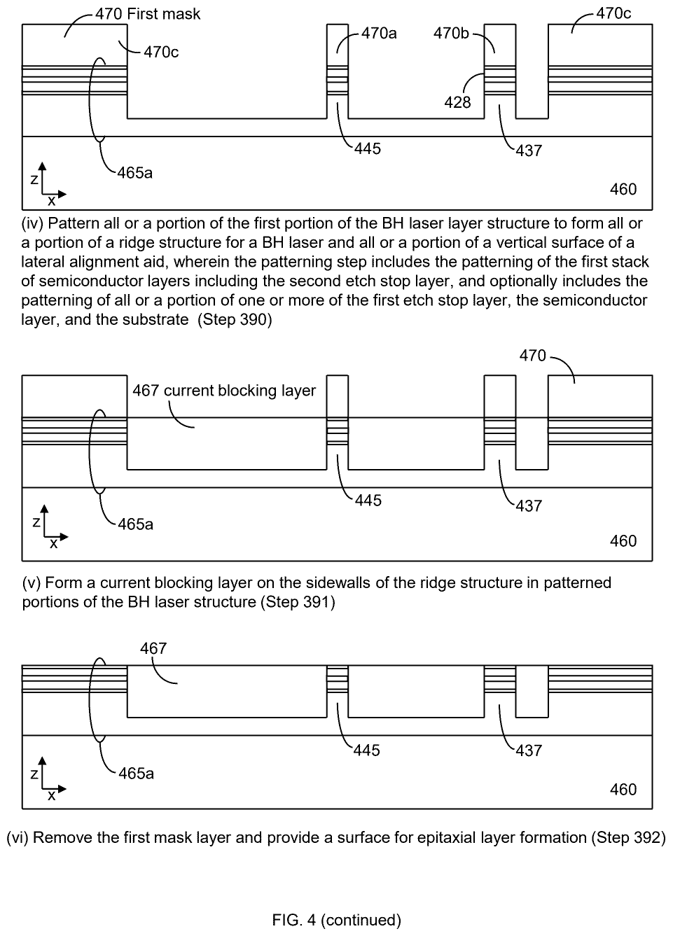

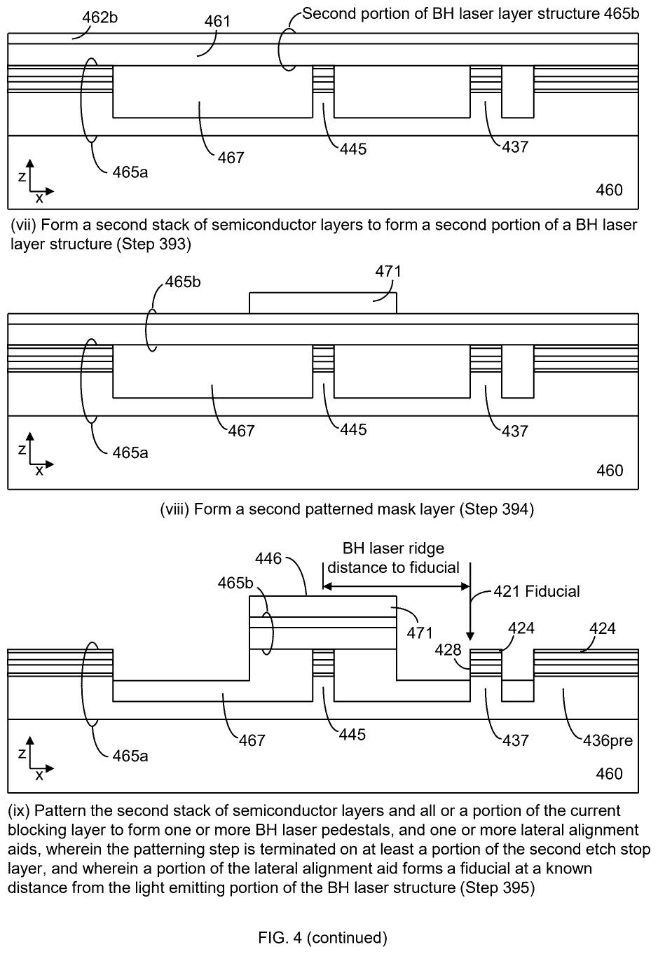

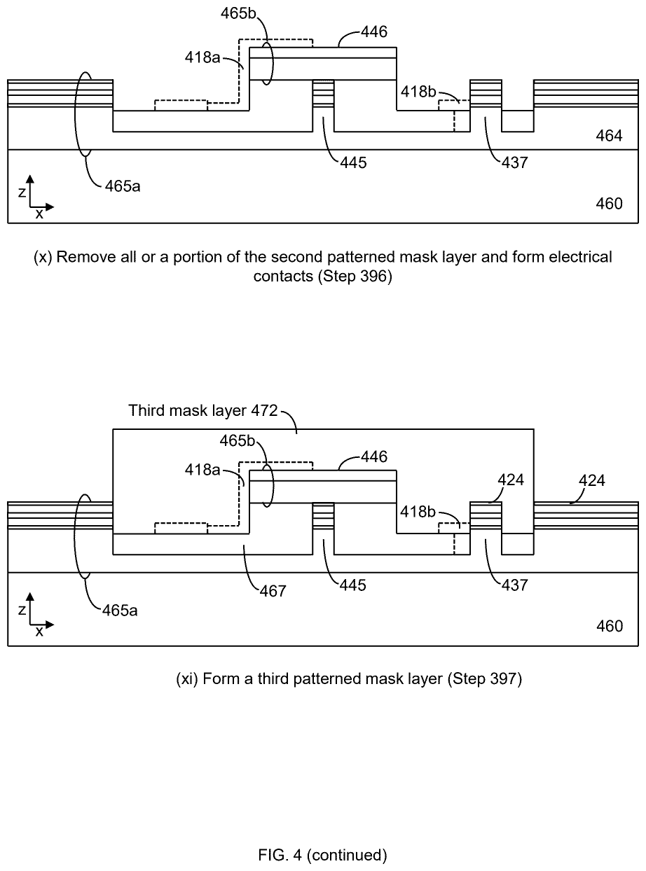

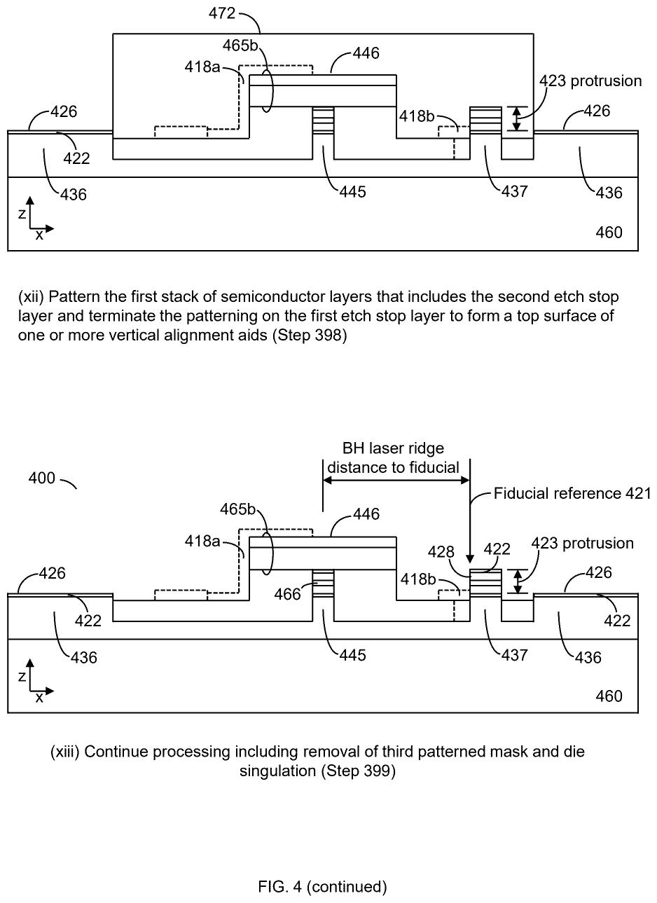

The method 310 of FIG. 3 is described in conjunction with FIGS. 4(i)-4(xiii) that show cross section schematic drawings for a number of steps in an embodiment of the method 310 of forming a BH laser die having vertical and lateral alignment aids.

Step 387 of method 310 is a forming step in which a base structure 415 for a BH laser die having alignment aids is formed, wherein the base structure 415 includes a first etch stop layer 422, an optional semiconductor layer 464, and a substrate 460. A schematic cross section drawing of an embodiment of a base structure 415 with first etch stop layer 422 is shown in FIG. 4(i). Substrate 460, in preferred embodiments is a compound semiconductor substrate such as indium phosphide or gallium arsenide. In other embodiments, substrate 460 can be a layered structure of a base material such as silicon or other semiconductor upon which a layer of a compound semiconductor is formed by such means as a deposition process or a bonded layer, for example. In other embodiments, substrate 460 can be a layered structure of a base material such as an insulating dielectric material, a ceramic, a metal, or other material upon which a layer of a compound semiconductor is formed by such means as a deposition process or a bonded layer, for example, among others. In preferred embodiments, BH laser die having alignment aids are formed from compound semiconductor materials based on indium phosphide or gallium arsenide, and are epitaxially grown structures. Epitaxial growth requires substrate materials that can provide lattice matching of the crystallographic structures for the various layers in the BH laser structure. FIG. 4(i) shows a semiconductor layer 464 on the substrate 460. In embodiments, semiconductor layer 464 is a layer formed on the substrate 460 that is a portion of a first set of layers of a BH laser structure that can include a lower cladding layer, one or more confinement layers, one or more waveguiding layers, and an active emission layer, among others, as further described herein. In some embodiments, the semiconductor layer 464 can form all or a portion of a buffer layer, a spacer layer, or other layer used in the formation of a BH laser structure.

First etch stop layer 422 is formed on the semiconductor layer 464. First etch stop layer, can be, for example, a quaternary layer comprised of indium phosphide or gallium nitride and other elements than can be epitaxially formed onto the semiconductor layer 464. On an indium phosphide substrate, for example, quaternary layers can be formed on the semiconductor layer 464 that maintain the crystallographic structure of the underlying substrate or layer. High etch selectivities between quaternary compounds can be achieved relative to the base compound semiconductor layers in the structure that enable the quaternary layers to be used as etch stop layers. Other quaternary alloys may also be used to form the etch stop layers as can ternary layers. In a GaAs structure, for example, the addition of aluminum to the GaAs to form AlGaAs, for example, can be used to form an etch stop layer. High etch selectivity between the layers formed above and below the etch stop layer and the etch stop layer can be achieved for one or more of wet chemical etching or dry etching processes. High etch selectivity implies a higher etch rate for the materials above and below the etch stop in comparison to the etch rate of the etch stop layer.

Step 388 of method 310 is a forming step in which a first stack of semiconductor layers 447 is formed on the first etch stop layer to further form a first portion of a BH laser structure 465a, wherein the first stack of semiconductor layers 447 includes a second etch stop layer 424, and wherein the first portion of the BH laser structure 465a includes the first stack of semiconductor layers 447, the first etch stop layer 422 and may include a portion of the optional semiconductor layer 464 of the base structure 415, and may include a portion of the substrate 460. A schematic cross section drawing of an embodiment of a first stack of semiconductor layers 447 formed on the first etch stop layer 422 is shown in FIG. 4(ii). In the embodiment shown in FIG. 4(ii), the first stack of semiconductor layers 447, first etch stop layer 422, and semiconductor layer 464 form a first portion of BH laser layer structure 465a. The first stack of semiconductor layers 447, as shown, includes an active layer 466, lower and upper semiconductor layers 468a, 468b, respectively, and second etch stop layer 424. The active layer 466 is an emission layer for the BH laser structure and may include one or more quantum wells. Quantum well structures used in the formation of BH lasers are known in the art of BH laser fabrication as are other methods for forming the emission layers of these devices. Lower and upper semiconductor layers 468a, 468b can be confinement layers, graded index layers, waveguiding layers, grating layer, or other layers used in the formation of BH layer structures. Lower semiconductor layer 468a may be a similar structure to that of the upper semiconductor layer 468b or the layer 468a may be a different structure to that of the upper semiconductor layer 468b. The lower and upper semiconductor layers 468a,468b may be such to provide coincidence in the heights of the center of the optical emission of a laser and the center of the optical signal mode of the waveguiding layers or the lower and upper semiconductor layers 468a,468b may be such to provide an offset in the heights of the center of the optical emission layer and the center of the optical signal mode of the waveguiding layers.

The second etch stop layer 424 is shown as a top layer of the first portion of the BH laser layer structure 465a in the embodiment shown in FIG. 4(ii). Second etch stop layer 424 may be a layer specifically introduced into the first stack of semiconductor layers 447 as an etch stop layer or the second etch stop layer 424 may be a layer within the layer structure that has another function or purpose in the functionality or operation of the BH laser diode. A graded index layer, for example, formed from a quaternary compound layer may be used as second etch stop layer 424.

Step 389 of method 310 is a forming step in which a first patterned mask layer 470 is formed on the second etch stop layer 424 that includes a portion 470a for at least a BH laser ridge structure and portions 470b for one or more lateral alignment features. A schematic cross section drawing of an embodiment of a first patterned mask layer formed on a first portion of a BH laser layer structure 465a is shown in FIG. 4(iii) with identified mask portion 470a and mask portion 470b for a ridge structure and lateral alignment feature, respectively. In some preferred embodiments, the first patterned mask layer 470 includes a patterned portion 470a for at least one BH laser ridge structure, patterned portions 470b for one or more lateral alignment features, and patterned portions 470c for one or more vertical alignment features. In other embodiments, the first patterned mask layer 470 includes a patterned portion 470a for at least one BH laser ridge structure and patterned portions 470b for one or more lateral alignment features. In embodiments that do not include the patterned portions 470c or other patterned portions that facilitate the formation of the vertical alignment features, these patterned portions may be provided using a separate masking layer or may not be provided.

Step 390 of method 310 is a patterning step in which all or a portion of a first portion 465a of an embodiment of a BH laser structure is patterned to form all or a portion of a ridge structure 445 for a BH laser and all or a portion of one or more vertical surfaces 428 of one or more lateral alignment features 437, wherein the patterning step includes the patterning of the first stack of semiconductor layers 447 including the second etch stop layer 424, and optionally includes the patterning of all or a portion of one or more of the first etch stop layer 422, the semiconductor layer 464, and the substrate 460. A schematic cross section drawing of a first portion of an embodiment of a BH laser structure that illustrates the patterning of a portion of a first portion of a BH laser layer structure 465a is shown in FIG. 4(iv). In FIG. 4(iv), first portion of a BH laser layer structure 465a is shown patterned to form ridge structure 445 and a lateral alignment feature 437.

Step 391 of method 310 is a forming step in which a current blocking layer is formed at least on the sidewalls of the patterned ridge structure of a first portion of a BH laser structure. A schematic cross section drawing of a first portion of a BH laser layer structure 465a having current blocking layer 467 in contact with the sidewall of the patterned ridge structure 445 in an embodiment of a BH laser structure is shown in FIG. 4(v). In some preferred embodiments, the blocking layer 467 is an epitaxially grown intrinsic (undoped) compound semiconductor layer. The high resistivity properties of an intrinsic semiconductor layer formed on the ridge structure 445 act to direct diode current flow through the ridge structure and act to block parasitic current flow through the blocking layer. In some embodiments, other resistive layers can be used to form the current blocking layer 467 such as one or more of intrinsic semiconductor layers, lightly doped semiconductor layers, insulating layers, dielectric layers, among others. In embodiments, the current blocking layer 467 blocks leakage current pathways that divert current flow through the laser diode ridge structure 445. In some embodiments, the current blocking layer may be a composite structure in which a first current blocking layer is formed on the sidewall of the ridge structure 445 and one or more additional layers are formed in addition to the first current blocking layer to form current blocking layer 467. The current blocking layer 467 is formed at least on the sidewalls of the BH laser ridge structure 445. In preferred embodiments, the current blocking layer 467 replaces, or substantially replaces, the portions of the semiconductor film structure that are removed in Step 390 as shown in FIG. 4(v).

Step 392 of method 310 is a removing step in which a first patterned mask layer 470 is removed from a first portion of an embodiment of the BH laser layer structure. A schematic cross section drawing of first portion 465a of an embodiment of a BH laser structure that illustrates the removal of the first mask layer 470 from the BH laser structure after the formation of a current blocking layer 467, is shown in FIG. 4(vi). The removal of a first mask layer 470 after the formation of the current blocking layer 467 can be a wet etch or dry etch process, for example, for embodiments in which the first mask layer 470 is a dielectric hard mask layer such as silicon nitride, silicon oxide, and silicon oxynitride. The removal of a first hard mask layer 470 after the formation of the current blocking layer 467 can be a dry strip process for embodiments in which the first hard mask layer 470 is a photoresist or other polymeric film. In other embodiments of the first mask layer 470, one or more of these and other removal processes may be used to remove the mask layer 470. In some embodiments, the removal step may include a planarization step to facilitate subsequent processing, wherein the planarization may include one or more of a deposition step, a fill step, an etch step, and a removal step, among other steps required to facilitate subsequent processing that may include epitaxial layer formation.

Step 393 of method 310 is a forming step in which a second stack of semiconductor layers is formed to form a second portion of a BH laser layer structure. A schematic cross section drawing that illustrates the formation of a second portion 465b on a first portion 465a of an embodiment of a BH laser layer structure is shown in FIG. 4(vii). Second portion 465b of a BH laser layer structure may include one or more of one or more of a confinement layer, a waveguide layer, a buffer layer, a grating layer, a spacer layer, a cladding layer, a contact layer, among others. In embodiments, first portion 465a of BH laser layer structure forms a first portion of a BH laser layer structure, and second portion 465b of BH laser layer structure forms a second portion of a BH laser diode structure. In preferred embodiments, first portion 465a and second portion 465b form a BH laser diode structure. In other embodiments, first portion 465a of BH laser layer structure forms a first portion of a BH laser layer structure, and second portion 465b of BH laser layer structure forms a second portion of a BH laser layer structure, that when combined form all or a substantial portion of a BH laser diode structure. In some embodiments, one or more additional layers may be required to form a complete BH laser diode structure. In some embodiments, one or more additional layers may be added to form a complete BH laser diode structure.

Step 394 of method 310 is a forming step in which a second patterned mask layer is formed on the BH laser layer structure. A schematic cross section drawing that illustrates the formation of a second patterned mask layer 471 on second portion 465b of an embodiment of a BH laser layer structure is shown in FIG. 4(viii). In some embodiments, second mask layer 471 is a hard mask layer. In some embodiments, hard mask layer 471 is formed from one or more of silicon oxide, silicon nitride, and silicon oxynitride. In other embodiments, other hard mask materials may be used.

Step 395 of method 310 is a patterning step in which a second portion of a BH laser layer structure 365b and all or a portion of the current blocking layer 367 from a first portion of a BH laser layer structure 365a are patterned to form one or more BH laser pedestals 446 and one or more lateral alignment features 437, wherein the patterning step 395 is terminated on at least a portion of the second etch stop layer 424, and wherein a portion of the lateral alignment feature 437 forms a fiducial 421 at a known approximate distance from at least a portion of the light emitting active layer 466 in the ridge portion 445 of the BH laser layer structure. A schematic cross section drawing that illustrates the patterning of the second portion of the BH laser layer structure 465b and a portion of current blocking layer 467 of an embodiment of a BH laser layer structure is shown in FIG. 4(ix). FIG. 4(ix) shows an embodiment of a BH laser layer structure with laser pedestal 446 and lateral alignment feature 437 after patterning step 395. In the embodiment, vertical surface 428 of the lateral alignment features 437 form fiducial 421 with a distance to the BH laser ridge 445 that can be precisely or approximately known from the spacing of these features in the first patterned mask layer 470. In preferred embodiments, the patterning process in step 395 selectively etches the layers in the second portion 465b of the BH laser layer structure and the current blocking layer 467 leaving the second etch stop layer 424, and all or a significant portion of the layers underlying the second etch stop layer 424, as shown in FIG. 4(ix). Second etch stop layer 424 is shown in the figure remaining on the lateral alignment feature 437 and the partially formed vertical alignment feature 436pre in the embodiment.

Step 396 of method 310 is a forming step in which electrical contacts 418a, 418b are formed on the BH laser structure, and in which all or a portion of the second patterned mask layer 471 is optionally removed from the BH laser structure. A schematic cross section drawing that illustrates the formation of electrical contacts 418a,418b on an embodiment of a BH laser layer structure and the removal of all or a portion of second mask layer 471 is shown in FIG. 4(x). The second mask layer 471 is shown removed in the embodiment in the cross section drawing of FIG. 4(xi). Electrical contacts 418a, 418b, shown in dotted lines in FIGS. 4(x)-4(xiii), and projected from another cross-sectional plane in the structure than that of the lateral alignment aid 437, form a first contact with a contact layer of the second portion of the BH laser layer structure in the BH laser pedestal 446 and a second contact 418b with a portion of the semiconductor layer 464 or other layer in the first portion of the BH laser layer structure required to form the second contact with laser ridge 445. First contact 418a and second contact 418b provide the two electrical contacts required for operation of the diode laser. Formation of first contact 418a to the second portion of the BH laser layer structure 465b and the formation of the second contact 418b to the first portion of the BH laser layer structure 465a provide all or a portion of the two contacts required for operation of the diode laser. In embodiments, all or a portion of the second mask layer 471 is removed to enable formation of a conductive contact between a metallization layer 418a and a contact layer of the second portion 465b of the BH laser layer laser structure.

Step 397 of method 310 is a forming step in which a third patterned mask layer is formed on the BH laser structure. A schematic cross section drawing that illustrates the formation of third patterned mask layer 472 on an embodiment of a BH laser layer structure is shown in FIG. 4(xi). In some embodiments, the third mask layer is a photoresist layer. In other embodiments, other mask layers or combination of mask layers may be used. The third mask layer 472 is shown in the embodiment of FIG. 4(xi) to form a protective layer over the laser pedestal 446, the lateral alignment features 437, all or a portion of the current blocking layer 467, and the electrical contacts 418a, 418b. The layer used to form the patterned third mask layer 472 is removed from all or a portion the BH laser layer structure having remaining second etch stop layer 424 to form the third patterned mask layer 472 as shown in the embodiment in FIG. 4(xi).

Step 398 of method 310 is a patterning step in which all or a portion of the first stack of semiconductor layers 447 that includes the second etch stop layer 424 is etched or otherwise removed, wherein the patterning step is terminated on the first etch stop layer to form a top surface 426 of one or more vertical alignment features 436. A schematic cross section drawing that illustrates the patterning of a portion of the first stack of semiconductor layers 447 that includes the second etch stop layer 424 to form a top surface 426 of one or more vertical alignment features 436 is shown in FIG. 4(xii). Formation of the top surface 426, in the embodiment shown, results from the selective removal of the layers 447 above the first etch stop layer 422 and the termination of a selective etch process on this first etch stop layer 422. In embodiments, a multistep process is used with a first etch step to selectively remove the second etch stop layer 424 and another etch step to selectively remove the semiconductor layers between the second etch stop layer 424 and the first etch stop layer 422. Selective etch processes may be wet chemical etches or dry etch processes or a combination of one or more wet etch processes and one or more dry etch processes. In some embodiments, all or a portion of the first etch stop layer 422 may be removed and remain within the scope of embodiments. In some embodiments, one or more of an oxidation step, a fluoridization step, an annealing step, or other step may be included in the patterning step to alter the properties of one or more films in the BH laser structure, or to add a layer to all or a portion of the BH laser structure and remain within the scope of embodiments.

In the embodiment shown in FIG. 4(xii), patterning step 398 causes the formation of protrusion 423 as shown. The height of the protrusion 423 in the embodiment shown, is equal to, or approximately equal to, the difference in height between the top surface 426 of the vertical etch feature 436 and the top surface of the lateral alignment feature 437, corresponding to the distance, or approximate distance, between the top surface of the first etch stop layer 422 and the second etch stop layer 424.

Step 399 of method 310 is a continuation step in which the processing of the BH laser structure is continued to form an embodiment of a BH laser structure with alignment aids as described herein and may include, for example, the removal of all or a portion of the third patterned mask layer, may include die singulation, may include the formation of front and back reflectors on the facets of the laser, may include the formation of solder contacts on the metallized layers if not already present, among other processes required to form a BH laser structure suitable for use in a PIC. A schematic cross section drawing that shows a schematic drawing of a BH laser structure 400 with vertical alignment features 436 and a single lateral alignment feature 437 is shown in FIG. 4(xiii).

The embodiment of BH laser structure 400 with alignment features includes the following alignment features:
1) lateral alignment feature 437 with one or more vertical surfaces 428
2) vertical alignment features 436 with horizontal surface 426
3) vertical or near vertical surfaces 428 that form fiducials 421 (at one or more distances determined in the first mask layer 470)
4) protrusion 423 (difference in height between vertical and lateral alignment features)

FIG. 4(xiii) shows an embodiment of a BH laser structure 400 having alignment aids using the method of formation described in FIG. 3. Variations of these embodiments may also be used in the formation of BH laser layer structures with alignment aids and remain within the scope of embodiments. In some embodiments, for example, the removal of the first hard mask layer 392 may be performed prior to the formation of the current blocking layer 467. Other steps may be required in such embodiments, such as a planarization step after the formation of the current blocking layer 467.

In the method of formation of the BH laser structure with alignment aids of FIG. 3, a method of fabrication was described in which the formation of two strategically positioned etch stop layers combined with a method of masking, patterning, and deposition steps results in the formation of embodiments of BH laser die with alignment aids. These BH laser die having alignment aids, provide features that are accurately positioned relative to other features on the die that includes the optical emission layer of the BH laser. In other embodiments, described herein, other embodiments are described with other forms and quantities of the lateral alignment features, and in the relative positioning of the first and second etch stop layers in the BH laser layer stack structure.

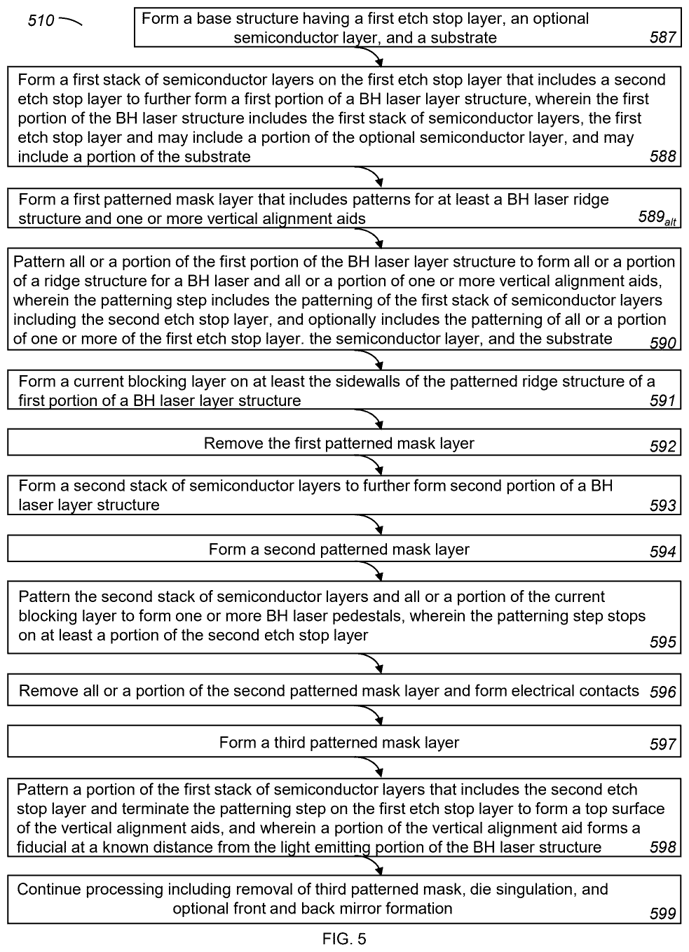

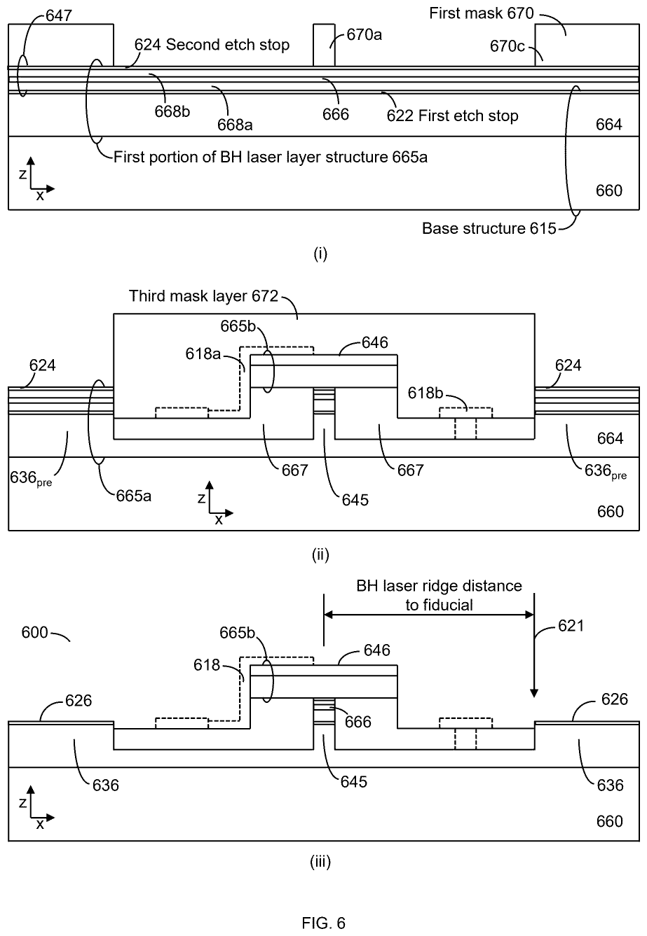

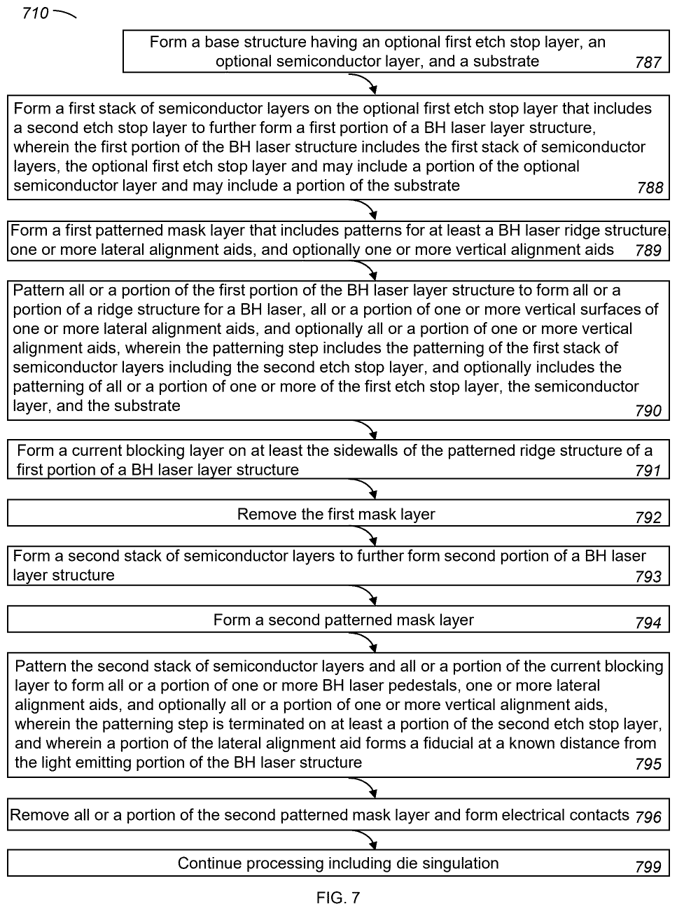

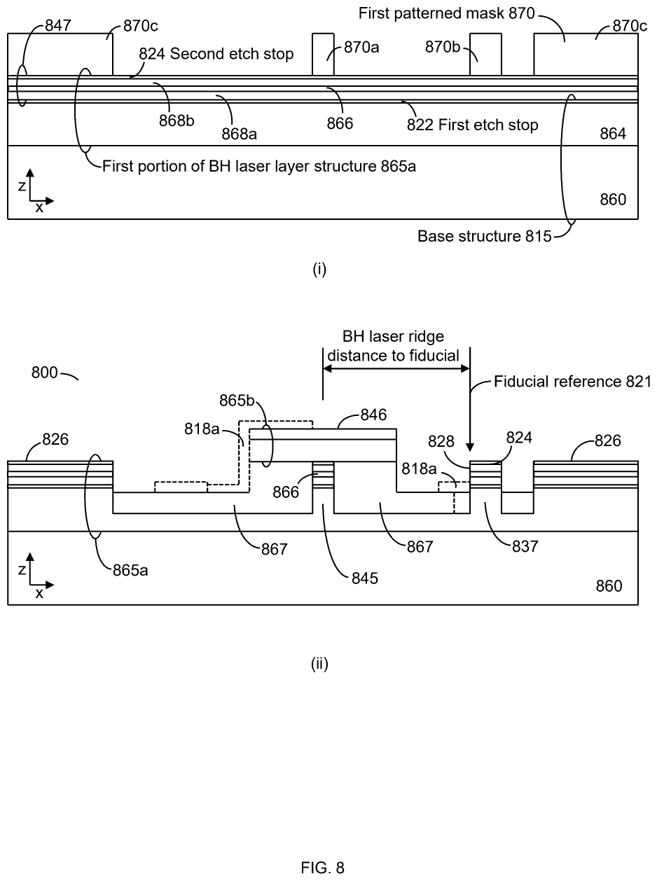

In FIG. 5, a flowchart for an embodiment of a method of formation of BH laser die having vertical alignment aids, without lateral alignment aids, is shown. Conversely, in FIG. 7, a flowchart for an embodiment of a method of formation of BH laser die having lateral alignment aids, without vertical alignment aids, is shown. FIGS. 6 and 8 show some cross section schematic drawings for a number of steps in the formation of the corresponding embodiments having vertical alignment aids and lateral alignment aids, respectively.

FIG. 5 shows a flowchart for an embodiment of a method 510 of forming a BH laser die having vertical alignment aids.

The method 510 of FIG. 5 is described in conjunction with FIGS. 6(i)-6(iii) that show cross section schematic drawings for a number of steps in an embodiment of the method 510 of forming a BH laser 500 with vertical alignment aids 536. The embodiments described in FIGS. 5 and 6 are not formed with lateral alignment aids such as lateral alignment aids 437, for example.

Step 587 of method 510 is a forming step in which a base structure 615 for a BH laser die having vertical alignment aids is formed, wherein the base structure 615 includes a first etch stop layer 622, an optional semiconductor layer 664, and a substrate 660. A schematic cross section drawing of an embodiment of a partially formed BH laser die is shown in FIG. 6(i) that includes base structure 615 comprised of first etch stop layer 622, optional semiconductor layer 664, and substrate 660.

Step 588 of method 510 is a forming step in which a first stack of semiconductor layers 647 is formed on the first etch stop layer 622 that includes a second etch stop layer 624 to further form a first portion of a BH laser structure 665a, wherein the first portion of the BH laser structure 665a includes the first stack of semiconductor layers 647, the first etch stop layer 622 and may include a portion of one or more of the semiconductor layer 664 and substrate 660.

Step 589ₐₗₜ of method 510 is a forming step in which a first patterned mask layer 670 is formed on the second etch stop layer 624 that includes a portion 670a for at least a BH laser ridge structure and portions 670c for one or more vertical alignment features. FIG. 6(i) shows a schematic cross section drawing of the first patterned mask layer 670 formed on a first portion of a BH laser layer structure 665a with identified mask portion 670a for the formation of a ridge structure and mask portions 670c for the formation of vertical alignment features. In embodiments, the first patterned mask layer 670 includes a patterned portion 670a for at least one BH laser ridge structure and a patterned portion 670c for one or more vertical alignment features.

Step 590 of method 510 is a patterning step in which all or a portion of a first portion 665a of an embodiment of a BH laser structure is patterned to form all or a portion of a ridge structure 645 for a BH laser die and all or a portion of one or more vertical alignment aids 636, wherein the patterning step includes the patterning of the first stack of semiconductor layers 647 including the second etch stop layer 624, and optionally includes the patterning of all or a portion of one or more of the first etch stop layer 622, the semiconductor layer 664, and the substrate 660.

Step 591 of method 510 is a forming step in which a current blocking layer 667 is formed at least on the sidewalls of the patterned ridge structure of a first portion of a BH laser layer structure.

Step 592 of method 510 is a removing step in which a first patterned mask layer 670 is removed from a first portion 865a of an embodiment of the BH laser layer structure.

Step 593 of method 510 is a forming step in which a second stack of semiconductor layers is formed to form a second portion 665b of a BH laser layer structure.

Step 594 of method 510 is a forming step in which a second patterned mask layer is formed on the BH laser layer structure.

Step 595 of method 510 is a patterning step in which the second portion 665b of the BH laser layer structure and all or a portion of the current blocking layer 667 are patterned to form one or more BH laser pedestals 646, wherein the patterning step 595 is terminated on at least a portion of the second etch stop layer 624.

Step 596 of method 510 is a forming step in which electrical contacts 618a,618b are formed on the BH laser structure, and in which all or a portion of the second patterned mask layer is optionally removed from the BH laser structure.

Step 597 of method 510 is a forming step in which a third patterned mask layer 672 is formed on the BH laser structure. A schematic cross section drawing that illustrates the formation of third patterned mask layer 672 on an embodiment of a BH laser layer structure is shown in FIG. 6(ii). In some embodiments, the third mask layer 672 is a photoresist layer. In other embodiments, other mask layers or combination of mask layers may be used. The third mask layer 672 is shown in the embodiment of FIG. 6(ii) to form a protective layer over the laser pedestal 646, all or a portion of the current blocking layer 667, and the electrical contacts 618a, 618b. The layer used to form the patterned third mask layer 672 is removed from all or a portion of the BH laser layer structure having remaining second etch stop layer 624 to form the third patterned mask layer as shown in FIG. 6(ii). FIG. 6(ii) also shows the BH laser pedestals 646 having ridge structure 645, a projection of the electrical contacts 618a,618b (not in same cross section plane), the first and second portions of the BH laser layer structure 665a,665b, respectively, the current blocking layer 667, and a first portion 636ₚᵣₑ of the vertical alignment structures.

Step 598 of method 510 is a patterning step in which all or a portion of the first stack of semiconductor layers 647 that includes the second etch stop layer 624 is etched or otherwise removed, wherein the patterning step is terminated on the first etch stop layer 622 to form a top surface 626 of one or more vertical alignment features 636, and wherein a portion of the vertical alignment feature 626 forms a fiducial 621 at a known approximate distance from the light emitting active layer 666 in the ridge portion 645 of the BH laser layer structure.

Step 599 of method 510 is a continuation step in which the processing of the BH laser structure is continued to form an embodiment of a BH laser structure 600 with alignment aids as described herein and may include, for example, the removal of all or a portion of the third patterned mask layer 672, may include die singulation, may include the formation of front and back reflectors on the facets of the laser, may include the formation of solder contacts on the metallized layers if not already present, among other processes required to form a BH laser structure suitable for use in a PIC. A schematic cross section drawing that shows an embodiment of a portion of a BH laser structure 600 with vertical alignment features 636 is shown in FIG. 6(iii). Self-aligned fiducial marks 621 are shown in FIG. 6(iii) that are formed from the use of the same first mask layer 670 to form the vertical alignment aids 636 and the ridge structure 645.

The embodiment of BH laser structure 600 with alignment features includes the following alignment features:
1) vertical alignment features 636 with horizontal surfaces 626
2) vertical or near vertical surfaces that form fiducials 621 (at one or more distances determined in the first mask layer 670)

FIG. 7 shows a flowchart for an embodiment of a method 710 of forming a BH laser die having lateral alignment aids and having one or more vertical alignment aids formed from a second etch stop layer.

The method 710 of FIG. 7 is described in conjunction with FIGS. 8(i)-8(ii) that show cross section schematic drawings for a number of steps in an embodiment of the method 710 of forming a BH laser die 700 with lateral alignment aids 737 and vertical alignment aids 736. The embodiments described in FIGS. 7 and 8 are formed with lateral and vertical alignment aids and the method described in the flowchart of FIG. 7 can be performed with fewer steps in comparison to the method of FIG. 3. The reduction in steps in the method of FIG. 7 results from the use of the second etch stop layer to form the horizontal surface of the one or more vertical alignment features.

Step 787 of method 710 is a forming step in which a base structure 815 for a BH laser die having lateral alignment aids is formed, wherein the base structure 815 includes a first etch stop layer 822, an optional semiconductor layer 864, and a substrate 460. A schematic cross section drawing of an embodiment of a partially formed BH laser die is shown in FIG. 8(i) that includes base structure 815 comprised of an optional first etch stop layer 822, optional semiconductor layer 864, and substrate 860.

Step 788 of method 710 is a forming step in which a first stack of semiconductor layers 847 is formed on the optional first etch stop layer 822 that includes a second etch stop layer 824 to further form a first portion of a BH laser structure 865a, wherein the first portion 865a of the BH laser structure includes the first stack of semiconductor layers 847, the first etch stop layer 822, and may include a portion of one or more of the semiconductor layer 864 and substrate 860.

Step 789 of method 710 is a forming step in which a first patterned mask layer 870 is formed on the second etch stop layer 824 that includes a portion 870a for at least a BH laser ridge structure, portions 870b for one or more lateral alignment features, and optionally 870c for one or more vertical alignment features. A schematic cross section drawing of an embodiment of a first patterned mask layer 870 formed on a first portion 865a of a BH laser layer structure is shown in FIG. 8(i) with identified mask portion 870a for a ridge structure, mask portion 870b for one or more lateral alignment features, and mask portion 870c for the one or more optional vertical alignment features. In embodiments, the first patterned mask layer 870 includes a patterned portion 870a for at least one BH laser ridge structure and patterned portions 870b for one or more lateral alignment features. In other embodiments, the first patterned mask layer 870 includes patterned portions 870a for at least one BH laser ridge structure, one or more patterned portions 870b for one or more lateral alignment features, and one or more patterned portion 870c for one or more vertical alignment features.

Step 790 of method 710 is a patterning step in which all or a portion of a first portion 865a of an embodiment of a BH laser structure is patterned to form all or a portion of a ridge structure 845 for a BH laser, all or a portion of one or more vertical surfaces 828 of one or more lateral alignment features, and optionally all or a portion of one or more vertical alignment aids, wherein the patterning step includes the patterning of the first stack of semiconductor layers 847 including the second etch stop layer 824, and optionally includes the patterning of all or a portion of one or more of the optional first etch stop layer 822, the semiconductor layer 464, and the substrate 860.

Step 791 of method 710 is a forming step in which a current blocking layer 867 is formed at least on the sidewalls of the patterned ridge structure of a first portion of a BH laser layer structure.

Step 792 of method 710 is a removing step in which a first patterned mask layer 870 is removed from a first portion 865a of a BH laser layer structure.

Step 793 of method 710 is a forming step in which a second stack of semiconductor layers is formed to form a second portion 865b of a BH laser layer structure.

Step 794 of method 710 is a forming step in which a second patterned mask layer is formed on the BH laser layer structure.

Step 795 of method 710 is a patterning step in which a second portion of a BH laser layer structure and all or a portion of a current blocking layer are patterned to form one or more BH laser pedestals, one or more lateral alignment features, and optionally all or a portion of one or more vertical alignment aids, wherein the patterning step 795 is terminated on at least a portion of the second etch stop layer, and wherein a portion of the lateral alignment feature forms a fiducial at a known approximate distance from the light emitting active layer in the ridge of the BH laser layer structure. FIG. 8(ii) shows patterned first portion 865a and patterned second portion 865b of an embodiment of BH laser structure 800 wherein the BH laser structure 800 includes a lateral alignment aid 837 having side surface 828, ridge structure 845 formed in laser pedestal 846, and vertical alignment aids 826 having horizontal alignment surfaces 826 formed from the second etch stop layer 824. Second portion 865b of a BH laser layer structure and all or a portion of a current blocking layer 867 are patterned to form one or more BH laser pedestals 846, one or more lateral alignment features 837, and optionally all or a portion of one or more vertical alignment aids 836, wherein the patterning step 795 is terminated on at least a portion of the second etch stop layer 824, and wherein a portion of the lateral alignment feature 837 forms a fiducial 821 at a known distance from the light emitting active layer 866 in the ridge 845 of the BH laser layer structure.

Step 796 of method 710 is a forming step in which electrical contacts 818a,818b, projections of which are shown in dotted lines in FIG. 8(ii), are formed on the BH laser structure, and in which all or a portion of the second patterned mask layer is optionally removed from the BH laser structure. The electrical contacts 818a, 818b, in the embodiment shown, are not formed in the same cross section plane as the lateral alignment contacts 837.

Step 799 of method 710 is a continuation step in which the processing of the BH laser structure is continued to form an embodiment of a BH laser structure with alignment aids as described herein and may include, for example, die singulation, may include the formation of front and back reflectors on the facets of the laser, may include the formation of solder contacts on the metallized layers if not already present, among other processes required to form a BH laser structure suitable for use in a PIC.

A schematic cross section drawing that illustrates the formation of a portion of a BH laser structure 800 with lateral alignment features 836 is shown in FIG. 8(ii). Electrical contacts 818a, 818b, shown in dotted lines in FIG. 8(ii), are projected from another cross-sectional plane in the structure than that of the lateral alignment aid 837. A first contact 818a is formed with a contact layer of the second portion 865b of the BH laser layer structure in the BH laser pedestal 846 and a second contact 818b is formed with a portion of the semiconductor layer 864 or other layer in the first portion 865a of the BH laser layer structure required to form a conductive path to the laser ridge 845. First contact 818a and second contact 818b provide the all or a portion of the two electrical contacts required for operation of the diode laser. Formation of first contact 818a to the second portion 865b of the BH laser layer structure and the formation of the second contact 818b to the first portion 865a of the BH laser layer structure provide the two contacts required for operation of the diode laser. In embodiments, all or a portion of the second mask layer 871 is removed to enable formation of a conductive contact between a metallization layer 818a and a contact layer of the second portion 865b of the BH laser layer laser structure. Contact layers in the BH laser layer structure, can be heavily doped semiconductor layers, for example.

FIG. 8(ii) shows a schematic cross section drawing of an embodiment of a portion of a BH laser structure 800 with lateral alignment aids 837 and vertical alignment aids 836. A fiducial mark 821 is also shown in FIG. 8(ii) that is formed from the use of the same patterned first mask layer 870 to form the lateral alignment aids 837 and the ridge structure 845. Lateral alignment aids 837 are formed with vertical side surfaces 828 that form the one or more fiducial marks 821. FIG. 8(ii) also shows the BH laser pedestals 846 having ridge structure 845, a projection of the electrical contacts 818a,818b (not in same cross section plane), the first and second portions of the BH laser layer structure 865a,865b, respectively, and the current blocking layer 867.

The embodiment of BH laser structure 800 with alignment features includes the following alignment features:
1) lateral alignment feature 837 with one or more vertical surfaces 828
2) vertical or near vertical surfaces 828 on lateral alignment aids 837 that form fiducials 821 (at one or more distances determined in the first mask layer 870)
3) multiple vertical alignment features 836 with horizontal surfaces 826

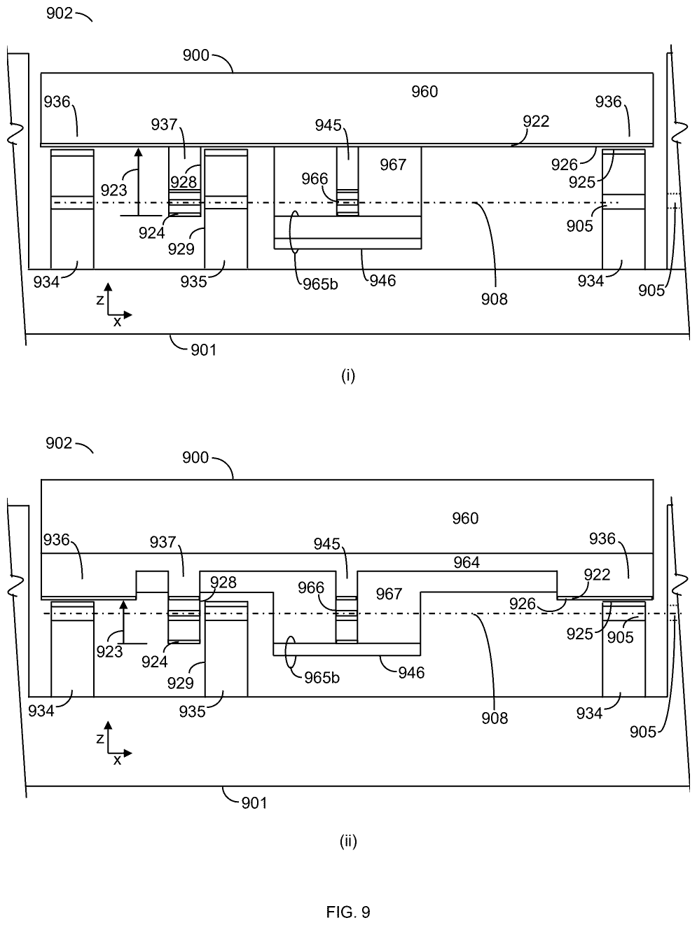

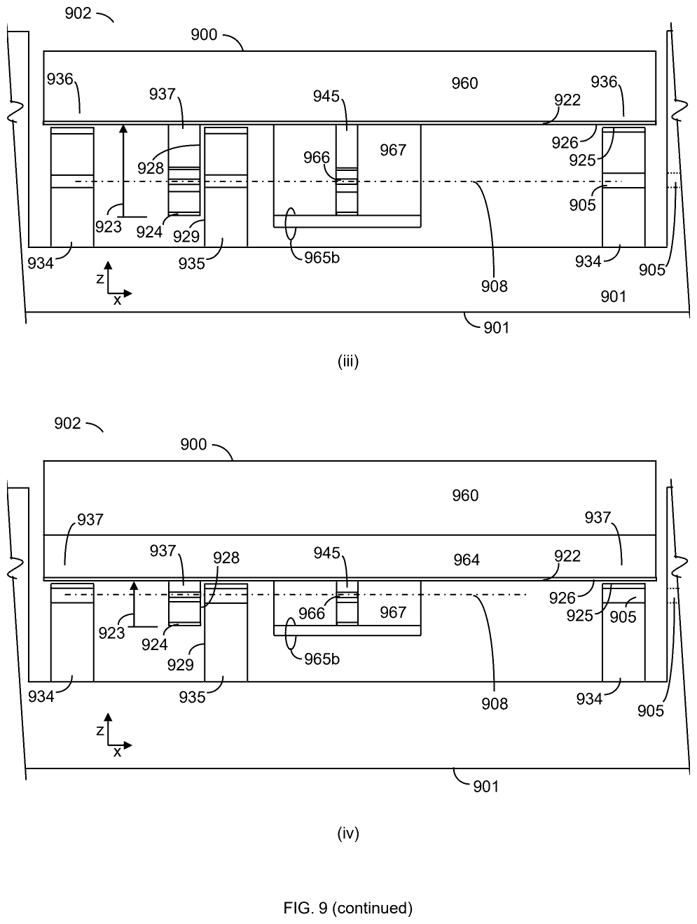

FIGS. 9(i)-(iv) show cross-section schematic drawings of embodiments of BH laser structures formed with alignment aids and positioned on interposers that are formed with complementary alignment aids and complementary planar waveguide configurations. The drawings show some examples of the placement of the first and second etch stop layers used in the formation of the BH laser alignment aids for each of the embodiments shown and the effect of the positioning of the first and second etch stop layers on example complementary interposers to which the embodiments of the BH lasers shown can be mounted. The positioning of the etch stop layers 922,924 in the BH laser layer structure affects the height of the protrusion 923 and the position of the active layer 966 of the BH laser relative to the first etch stop layer, which in turn affects the position or range of positions of the planar waveguide layers that can be used in complementary interposers.

FIG. 9(i) shows a cross-section schematic drawing of an embodiment of a BH laser 900 with a first etch stop layer 922 and second etch stop layer 924 configured as shown with a first etch stop layer 922 formed at or close to the substrate 960 in the layered structure and second etch stop layer 924 in this embodiment formed below the active layer 966 of the BH laser layer structure (for the orientation shown.) The embodiment of the BH laser 900 is shown mounted on interposer 901 in a top down (“flip chipped”) configuration to form PIC assembly 902.

In the embodiment 900, the protrusion 923 of the single pillar-type lateral alignment feature 937 is formed with a distance equal to, or approximately equal to, the distance (as shown) between the first and second etch stop layers 922, 924, respectively. The vertical distance between the first etch stop layer 922 and the middle of the active layer 966, assumed in the example to be the location of the optical axis for the laser, is the distance, or approximate distance, that can be used on a complementary interposer between the planar waveguide layer 905 and the top surface 925 of the vertical alignment pillar 934. The first etch stop layer 922 of the BH laser forms a surface 926 that is brought into contact with top surface 925 of the alignment feature 934 on the interposer 901 to form the alignment of the lateral projections of the optical axes 908 of the PIC assembly 902 that includes the BH laser die 900 and interposer 901.

Portions of the planar waveguide layer 905 of the interposer 901 are shown in the interposer pillars 934, 935. A portion of the planar waveguide layer 905 is also shown in dotted lines in the interposer of FIG. 9(i). In practice, the planar waveguides formed from the planar waveguide layer 905 would, in general, be positioned out of the plane of the page, in alignment with the optical output of the emission layer 966 from the ridge 945 of the laser 900. (This alignment between the output of the laser and planar waveguides formed in the interposer is shown in more detail herein.)

In the assembly, side surface 928 of the lateral alignment feature 937 is shown in contact with side surface 929 of the complementary lateral alignment feature 935 of the interposer 901. The side surfaces 927,928 of the lateral alignment features 937,935, respectively, constrain the lateral movement of the BH laser die 900 on the interposer 901 when a contact is formed.

Additional embodiments with similar numbering are provided in FIGS. 9(ii), 9(iii), and 9(iv). These embodiments are formed in ridge-up and ridge-down configurations, and are formed with multiple example placements of the first etch stop 922 and the second etch stop 924 in the layered BH laser structure.

FIG. 9(ii) shows a cross-section schematic drawing of an embodiment of the BH laser die 900 for which the first etch stop layer 922 is positioned within or on the optional semiconductor layer 964 (below the semiconductor layer 464 in the orientation of the BH laser die 900 shown in FIG. 9(ii)) and a second etch stop layer 924 positioned below the active layer 966 of the BH laser layer structure. In the embodiment, the second etch stop layer is positioned further from the active layer 966 than in the embodiment shown in FIG. 9(i). The embodiment of the BH laser 900 is shown mounted on interposer 901 in atop down (“flip chipped”) configuration to form PIC assembly 902.

As in the embodiment shown in FIG. 9(i), the protrusion 923 of lateral alignment feature 937 is formed with a distance equal to, or approximately equal to, the distance between the first and second etch stop layers 922, 924, respectively. The vertical distance between the first etch stop layer 922 and the middle of the active layer 966, assumed in the example to be the location of the optical axis for the laser, is the distance, or approximate distance, that can be used on a complementary interposer between the planar waveguide layer 905 and the top surface 925 of the vertical alignment pillar 934. The first etch stop layer 922 of the BH laser forms a horizontal surface 926 that is brought into contact with top surface 925 of the alignment feature 934 on the interposer 901 to form the alignment of the lateral projections of the optical axes 908 of the PIC assembly 902 that includes the BH laser die 900 and interposer 901.

In the embodiment shown in FIG. 9(ii), the vertical distance between the active layer 966 and the first etch stop layer 922 is considerably less than this distance in the embodiment of FIG. 9(i), and this reduction in vertical distance requires a reduction in the vertical distance between the top surface 925 of the interposer pillar 934 and the optical axis of the planar waveguide layer 905 for complementary interposer structures that can be utilized with the embodiment of FIG. 9(ii). In a complementary interposer 901, the spacing between the horizontal surface 926 of vertical alignment aid 936 and the optical axis of the BH laser 900 is equal to, or approximately equal to, the spacing between the top of alignment pillar 935 and planar waveguide layer 905 on the interposer 901.

In the assembly shown in FIG. 9(ii), side surface 928 of the lateral alignment feature 937 is shown in contact with side surface 929 of the complementary lateral alignment feature 935 of the interposer 901. The side surfaces 927,928 of the single pillar-type lateral alignment features 937,935, respectively, constrain the lateral movement of the BH laser die 900 on the interposer 901 when a contact is formed.

FIG. 9(iii) shows a cross-section schematic drawing of an embodiment of the BH laser die 900 for which the first etch stop layer 922 is formed at or close to the substrate 960 in the layered structure and second etch stop layer 924 in this embodiment is as shown below the active layer 966 of the BH laser layer structure of BH laser die 900 oriented at shown. In this embodiment 900, the first etch stop layer is positioned similarly to the position of the first etch stop layer shown in FIG. 9(i), and the second etch stop layer is positioned similarly to the second etch stop layer position of FIG. 9(ii) with regard to the distance between the etch stop layers and the active layer 966. The embodiment of the BH laser 900 is shown mounted on interposer 901 in a top down (“flip chipped”) configuration to form PIC assembly 902.

As in the embodiments of FIGS. 9(i) and 9(ii), the protrusion 923 of lateral alignment feature 937 is formed with a distance equal to, or approximately equal to, the distance between the first and second etch stop layers 922, 924, respectively. The vertical distance between the first etch stop layer 922 and the middle of the active layer 966, assumed in the example to be the location of the optical axis for the laser, is the distance, or approximate distance, that can be used on a complementary interposer between the planar waveguide layer 905 and the top surface 925 of the vertical alignment pillar 934. The first etch stop layer 922 of the BH laser forms a horizontal surface 926 that is brought into contact with top surface 925 of the alignment feature 934 on the interposer 901 to form the alignment of the lateral projections of the optical axes 908 of the PIC assembly 902 that includes the BH laser die 900 and interposer 901.

In the embodiment shown in FIG. 9(iii), the vertical distance between the active layer 966 and the first etch stop layer 922 is similar to that of the embodiment shown in FIG. 9(i), in that a significant portion of the first portion of the BH laser layer structure is included in the formation of the lateral alignment aid 937, and in the height of the resulting protrusion 923. As in the embodiment shown in FIG. 9(i), the vertical distance between the top surface 925 of the interposer pillar 934 and the optical axis of the planar waveguide layer 905 must be increased for complementary interposer structures that can be utilized with the embodiment shown in FIG. 9(iii). With the inclusion of the extended portion of the second portion of the BH laser layer structure, the protrusion of FIG. 9(iii) is shown to encompass a significant portion of the overall height of the BH laser ridge structure.

In a complementary interposer 901, the spacing between the horizontal surface 926 of vertical alignment aid 936 and the optical axis of the BH laser 900 is equal to, or approximately equal to, the spacing between the top of alignment pillar 935 and planar waveguide layer 905 on the interposer 901. The first etch stop layer 922 of the BH laser forms a surface 926 that is brought into contact with top surface 925 of the alignment feature 934 on the interposer 901 to form the alignment of the lateral projections of the optical axes 908 of the PIC assembly 902 that includes the BH laser die 900 and interposer 901.

Portions of the planar waveguide layer 905 of the interposer 901 are shown in the interposer pillars 934, 935. A portion of the planar waveguide layer 905 is also shown in dotted lines in the interposer of FIG. 9(iii). In practice, the planar waveguides formed from the planar waveguide layer 905 would, in general, be positioned out of the plane of the page, in alignment with the optical output of the emission layer 966 from the ridge 945 of the laser 900. (This alignment between the output of the laser and planar waveguides formed in the interposer is shown in more detail herein.)

In the assembly, side surface 928 of the lateral alignment feature 937 is shown in contact with side surface 929 of the complementary lateral alignment feature 935 of the interposer 901. The side surfaces 927,928 of the lateral alignment features 937,935, respectively, constrain the lateral movement of the BH laser die 900 on the interposer 901 when a contact is formed.

FIG. 9(iv) shows a cross-section schematic drawing of an embodiment of the BH laser die 900 for which the first etch stop layer 922 is formed at or near to the surface of the optional semiconductor layer 964 (below the semiconductor layer 464 in the orientation of the BH laser die 900 shown in FIG. 9(iv)) and a second etch stop layer 924 in this embodiment is as shown below the active layer 966 of the BH laser layer structure of BH laser die 900 oriented at shown. In this embodiment 900, the first and second etch stop layers are positioned similarly to the positions of the first and second etch stop layers shown in FIG. 9(ii), but the first etch stop layer and the optional semiconductor layer 964 is not etched in the first patterning step, namely Step 390, of method 310.

As in the embodiments shown in FIGS. 9(i)-9(iii), the protrusion 923 of lateral alignment feature 937 is formed with a distance equal to, or approximately equal to, the distance between the first and second etch stop layers 922,924, respectively, corresponding to the distance, or approximate distance, between the horizontal surface 926 of the vertical alignment aid 936 and the surface of the second etch stop layer 924 on the lateral alignment pillar 937. The vertical distance between the first etch stop layer 922 and the middle of the active layer 966, assumed in the example to be the location of the optical axis for the laser, is the distance, or approximate distance, that can be used on a complementary interposer between the planar waveguide layer 905 and the top surface 925 of the vertical alignment pillar 934. The first etch stop layer 922 of the BH laser forms a horizontal surface 926 that is brought into contact with top surface 925 of the alignment feature 934 on the interposer 901 to form the alignment of the lateral projections of the optical axes 908 of the PIC assembly 902 that includes the BH laser die 900 and interposer 901.

In the embodiment shown in FIG. 9(iv), the vertical distance between the active layer 966 and the first etch stop layer 922 is considerably less than this distance in the embodiments of FIGS. 9(i) and 9(iii), and comparable to that of the embodiment shown in FIG. 9(ii). As in the embodiment shown in FIG. 9(ii), the reduced vertical spacing between the active layer 966 and the first etch stop layer requires a reduction in the vertical distance between the top surface 925 of the interposer pillar 934 and the optical axis of the planar waveguide layer 905 for complementary interposer structures that can be utilized with the embodiment of FIG. 9(iv). In a complementary interposer 901, the spacing between the horizontal surface 926 of vertical alignment aid 936 and the optical axis of the BH laser 900 is equal to, or approximately equal to, the spacing between the top of alignment pillar 935 and planar waveguide layer 905 on the interposer 901 as shown.

In a complementary interposer 901, the spacing between the horizontal surface 926 of vertical alignment aid 936 and the optical axis of the BH laser 900 is equal to, or approximately equal to, the spacing between the top of alignment pillar 935 and planar waveguide layer 905 on the interposer 901. The first etch stop layer 922 of the BH laser forms a surface 926 that is brought into contact with top surface 925 of the alignment feature 934 on the interposer 901 to form the alignment of the lateral projections of the optical axes 908 of the PIC assembly 902 that includes the BH laser die 900 and interposer 901.

Portions of the planar waveguide layer 905 of the interposer 901 are shown in the interposer pillars 934, 935. A portion of the planar waveguide layer 905 is shown in dotted lines in the interposer shown in FIG. 9(iv). In practice, planar waveguides formed from the planar waveguide layer 905 would, in general, be positioned out of the plane of the page, in alignment with the optical output of the emission layer 966 from the ridge 945 of the laser 900. (This alignment between the output of the laser and planar waveguides formed in the interposer is shown in more detail herein.)

In the assembly, side surface 928 of the lateral alignment feature 937 is shown in contact with side surface 929 of the complementary lateral alignment feature 935 of the interposer 901. The side surfaces 927,928 of the lateral alignment features 937,935, respectively, constrain the lateral movement of the BH laser die 900 on the interposer 901 when a contact is formed.

In FIGS. 9(i)-9(iv), some examples of variations in the spacing between the first etch stop layer 922 and second etch stop layer 924 in embodiments of the BH laser die 900 are presented. The spacing between the first etch stop layer 922 and the second etch stop layer 924 affects the height of the protrusion 923 of the lateral alignment features 937 formed in these embodiments, and affects the required spacing between the top of the alignment pillar 935 and the planar waveguide layer 905 of the complementary interposers 901 to which the embodiments of the BH laser die 900 can be mounted.

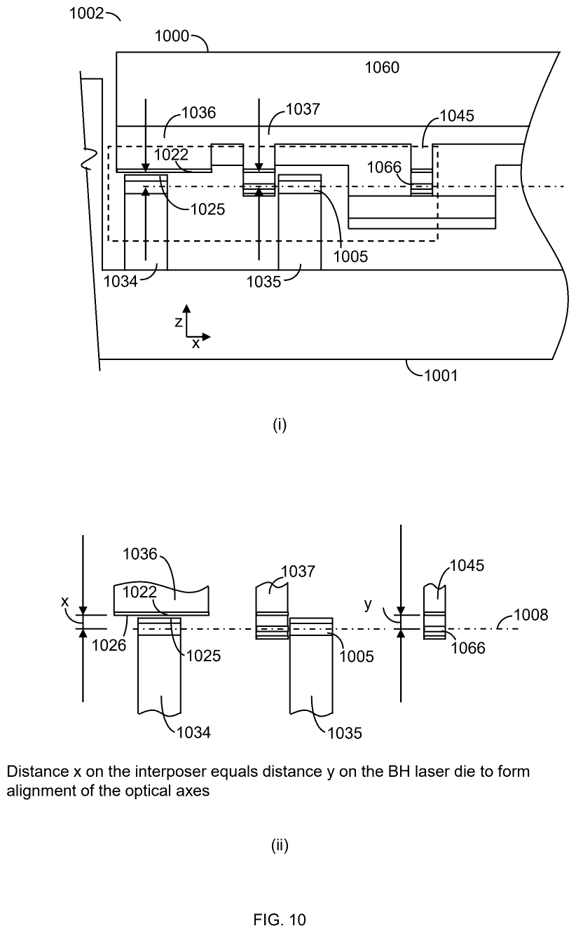

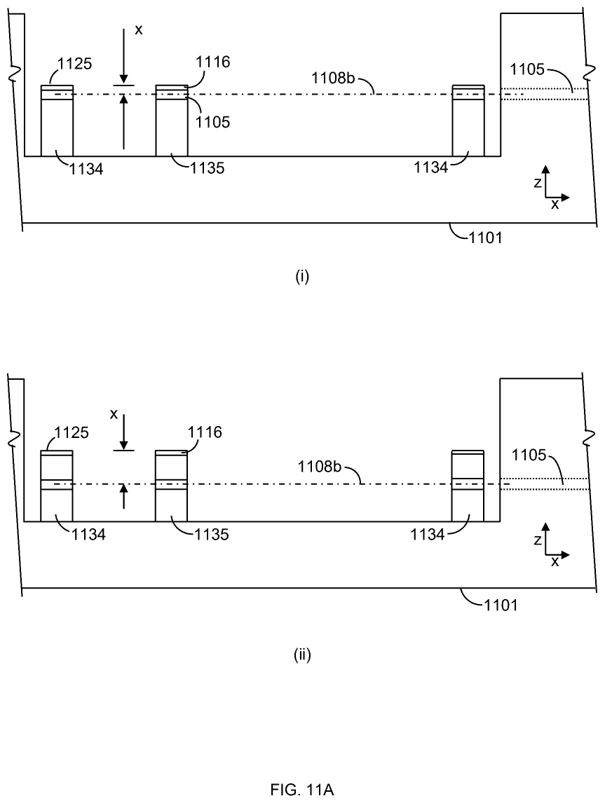

FIG. 10(i) shows a cross section of a portion of an embodiment of a BH laser die 1000 with alignment features mounted on a portion of an interposer 1001, forming PIC assembly 1002, and the effect of the positioning of the first and second etch stop layers 1022, 1024, respectively, on the alignment of the lateral projection of the optical axes 1008 between the BH laser die 1000 and a planar waveguide layer 1005 on the interposer 1001. The spacing between the optical axis of the BH laser on the BH laser die 1000 and the surface 1026 of the first etch stop layer 1022 is formed to be equal to, or approximately equal to, the spacing between the top horizontal surface 1025 of the vertical alignment aid 1034 and the optical axis of the planar waveguide layer 1005 on the interposer 1001. FIG. 10(ii) shows an enlarged cross-section drawing of the area enclosed in dotted lines of FIG. 10(i). In the embodiment shown in FIGS. 10(i) and 10(ii), alignment of the optical axis of the BH laser die and the optical axis of the planar waveguide layer 105 to form an aligned optical axis 1008 for the assembly 1002 can be obtained for spacings between the optical axis of the BH laser of the BH laser die 1000 and the first etch stop layer 1022, namely spacing “x”, that are equal to, or approximately equal to, the spacing between the horizontal surface 1026 of the vertical alignment aid 1036 and the optical axis of the planar waveguide layer 1005 on the interposer 1001, namely spacing “y”. In embodiments for which the spacing “x” and spacing “y” are equal, or approximately equal, the lateral projection of the optical axis of the planar waveguide layer 1005 is in alignment with the optical axis of the BH laser 1000. In the embodiment shown in FIG. 10, the optical axis of the BH laser is shown centered within the active layer 1066. In practice, the optical axis may or may not align with the center of the active layer 1066 of the BH laser 1000.

The embodiment in FIG. 10 shows an example of the spacings between features of a BH laser die and the features of a complementary interposer to which the BH laser die can be mounted. Other complementary spacings can also be used and remain within the scope of embodiments.

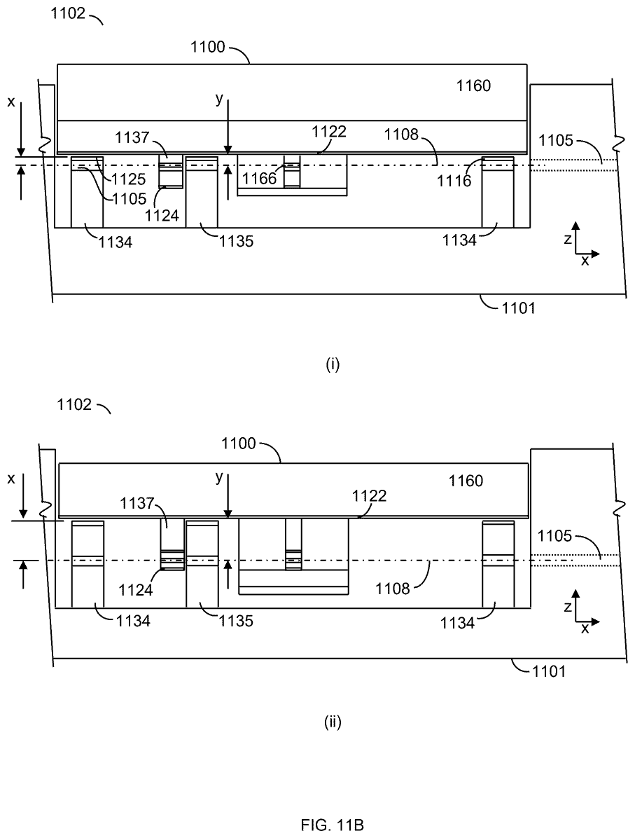

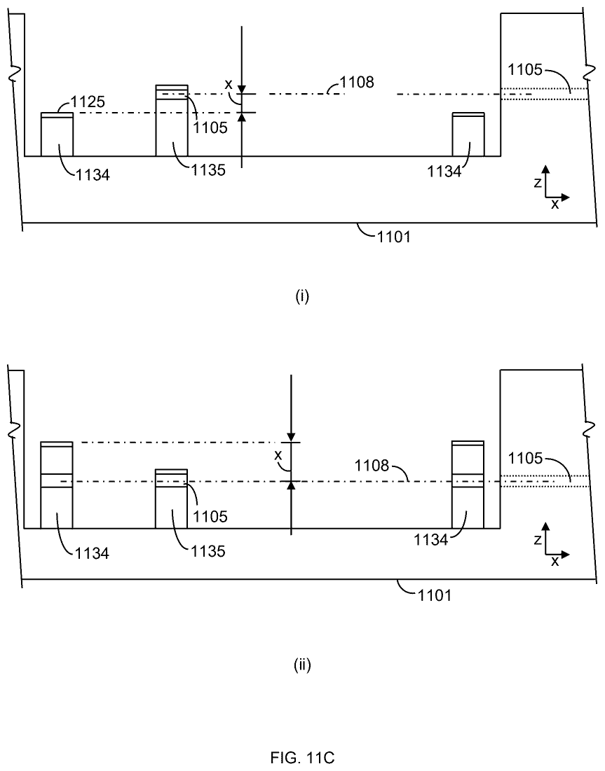

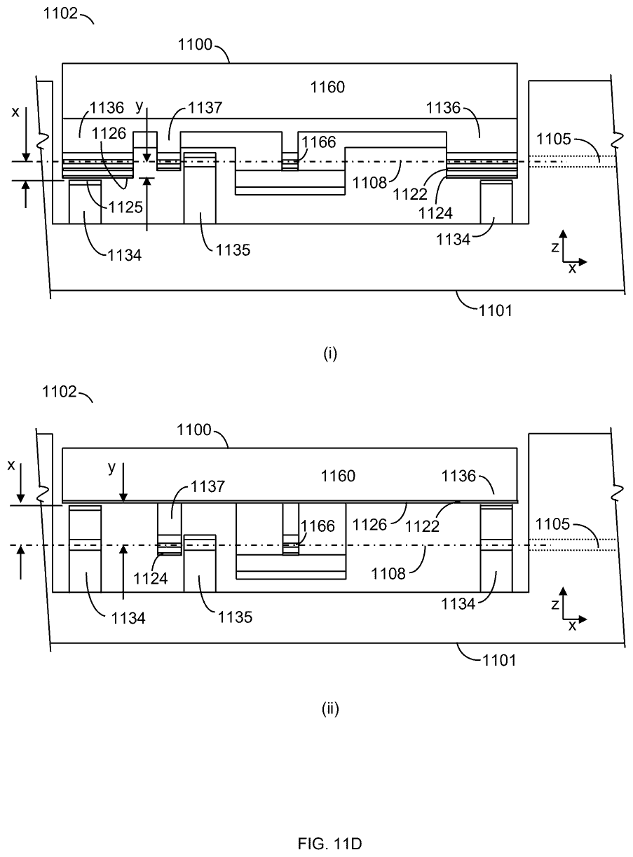

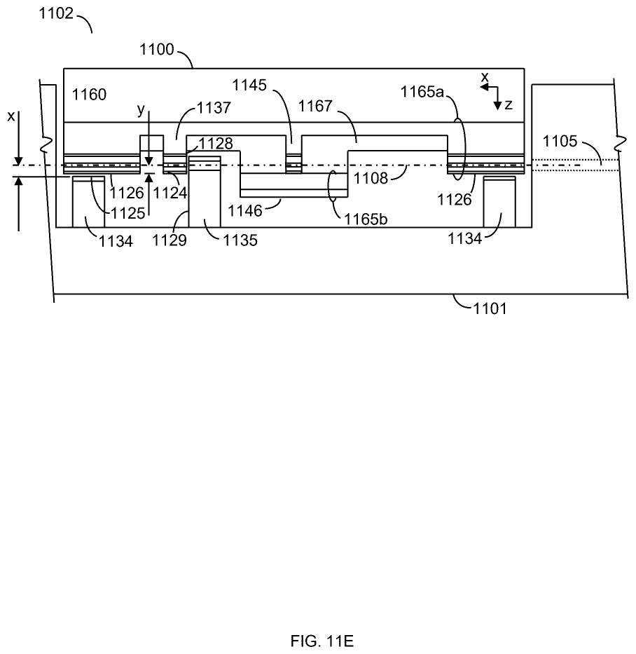

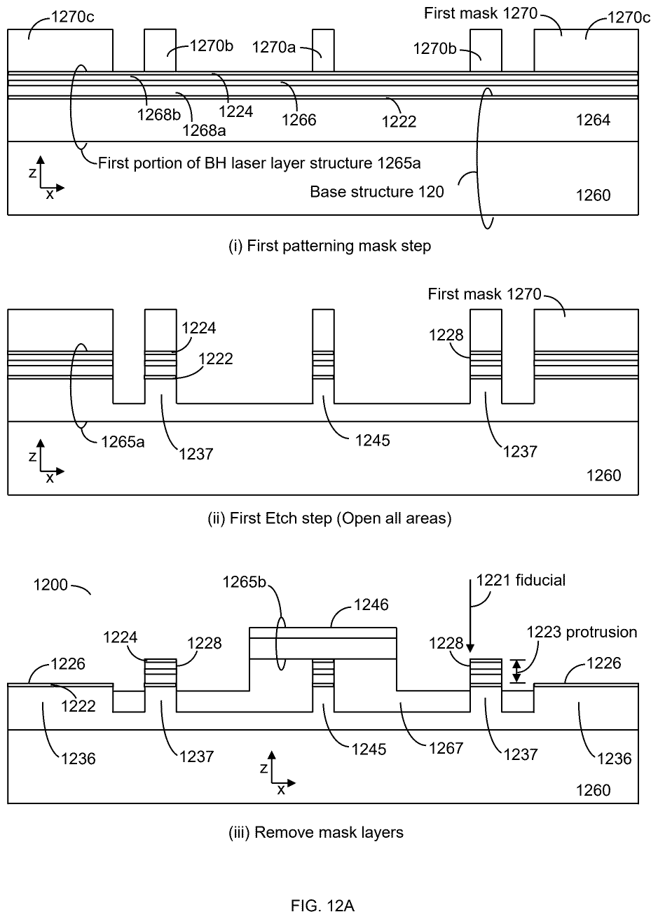

FIGS. 11A and 11B show some examples of interposers having at least one planar waveguide layer and the effect of the vertical positioning of the planar waveguide layer on the alignment of the lateral projection of the optical axis of an embodiment of a BH laser die with the alignment of the optical axis of the interposer planar waveguide layer.

FIG. 11A(i) shows a cross section drawing of an embodiment of a complementary interposer 1101 configured for mounting a BH laser die 1100 having alignment aids in which the planar waveguide layer 1105 of the interposer 1101 is positioned near the top of an alignment pillar 1134,1135. Mask layer 1116, used in the formation of the alignment pillars 1134,1135, is shown with the planar waveguide layer 1105 positioned just below the mask layer 1116. The lateral projection of the optical axis 1108b is shown in planar waveguide layer 1105 for the interposer 1101 in the embodiment. Planar waveguide layer 1105 is formed on the example interposer, as further described herein, and a portion of the planar waveguide layer 1105 can remain in the alignment pillars 1134,1135 on the interposer 1101. Distance “x” as shown is the distance between the top surface 1125 of the alignment pillar 1134 and the optical axis 1108b of the interposer 1101.

FIG. 11A(ii) shows a cross section drawing of an embodiment of a complementary interposer 1101 configured for mounting an embodiment of a BH laser die 1100 having alignment aids in which the planar waveguide layer 1105 of the interposer 1101 is positioned further from the top surface 1125 of an alignment pillar 1134,1135 than the interposer structure shown in FIG. 11A(i). Mask layer 1116, used, for example, in the formation of the alignment pillars 1134,1135, is shown. The lateral projection of the alignment axis 1108b is shown in planar waveguide layer 1105 for the interposer 1101 in the embodiment. Planar waveguide layer 1105 is formed on the example interposer, as further described herein, and a portion of the planar waveguide layer 1105 can remain in the alignment pillars 1134,1135 on the interposer 1101. Distance “x” as shown is the distance between the top surface 1125 of the alignment pillar 1134 and the optical axis 1108b of the interposer 1101.

FIGS. 11B(i) and 11B(ii) show cross section drawings of the interposers of FIGS. 11A(i) and 11A(ii) with embodiments of BH laser die 1100 in PIC assemblies 1102. FIGS. 11B(i) and 11B(ii) further show the effect of the positioning of the planar waveguide layer 1105 formed on the interposer 1101 on the formation of complementary alignment aids on embodiments of the BH laser die 1100. More particularly, FIGS. 11B(i) and 11B(ii) provide examples in which the spacing between the first etch stop layer 1122 and the optical axis of an embodiment of a BH laser 1100 can be aligned with the spacing between the optical axis of the planar waveguide layer 1105 and the horizontal surface 1125 of the vertical alignment pillar 1134 on the interposer 1101.

FIG. 11B(i) shows a cross section drawing for the interposer 1101 having alignment pillars 1134, 1135 with a planar waveguide layer 1105 positioned near the top of the interposer pillar, just below the hard mask layer 1116, and FIG. 11B(ii) shows the cross section drawing for the interposer 1101 having alignment pillars 1134, 1135 with a planar waveguide layer 1105 positioned further from the top horizontal surface 1125 of the interposer alignment pillars 1134,1135. Spacing “x” and spacing “y” are shown in the drawings for each embodiment. The formation of BH laser die 1100 with a spacing “y” between the optical axis 1108 through or near to the emission layer 1166 provides alignment of the lateral projections of the optical axes 1108 for the assembly 1102 for interposers having spacing “x” between the top horizontal surface 1125 of the alignment pillar 1134 and the optical axis through the planar waveguide layer 1105.

In comparing the alignment pillars 1137 of the embodiments of the BH laser die 1100, the effect of the increased spacing between the first etch stop layer 1122 and the optical axis of the BH laser 1100, namely spacing “y” on the position of the planar waveguide layer 1105 in the complementary interposers 1101 is made more apparent in that the increased spacing between the first etch stop layer 1122 and the optical axis of the BH laser 1100 shown in FIG. 11B(ii) results in an increased distance between the top of the alignment pillar 1134 and the alignment axis of the planar waveguide layer 1105 on the interposer 1101 in comparison to the embodiment shown in FIG. 11B(i).

In some embodiments of BH laser die 1100, the vertical alignment aids 1136 and the lateral alignment aids 1137 can be formed to accommodate multiple alignment pillar heights on a complementary interposer 1101. FIGS. 11C(i) and 11C(ii) show interposers 1101 having complementary alignment pillars 1134,1135 that are formed at multiple heights. FIG. 11C(i) shows an interposer 1101 in which the alignment aids 1134 that align with complementary vertical alignment aids 1136 on an embodiment of a BH laser die 1100 are formed at a first height, and the alignment aids 1135 that provide a lateral constraint for lateral alignment aids 1137 are formed at a second height. In the example interposer shown in FIG. 11C(i), the vertical alignment aid 1134 at the first height is lower than the lateral alignment aid 1135 at the second height.

In FIG. 11C(i), the distance between the horizontal surface 1125 of the vertical alignment pillar 1135 on the interposer 1101 and the optical axis of the planar waveguide 1105, is shown labeled as distance “x”. For an embodiment of a BH laser die 1100, the distance between the optical axis of the BH laser, and the horizontal surface 1126 of the one or more vertical alignment aids 1136 is formed equal to, or approximately equal to, this distance “x” in order to provide an assembly 1102 in which the lateral projections of the optical axes of the BH laser 1100 and the interposer are aligned.

Alternatively, FIG. 11C(ii) shows an interposer 1101 in which the alignment aids 1134 on the interposer 1101 that align with complementary vertical alignment aids 1136 on an embodiment of BH laser die 1100 are formed at a first height, and the alignment aids 1135 on the interposer 1101 that provide a lateral constraint for lateral alignment aids 1137 on the BH laser die 1100 are formed at a second height. In the example interposer shown in FIG. 11C(ii), the vertical alignment aid 1134 at the first height is taller than the lateral alignment aid 1135 at the second height.

In FIG. 11C(ii), the distance between the horizontal surface 1125 of the vertical alignment pillar 1135 on the interposer 1101 and the optical axis of the planar waveguide 1105, is shown labeled as distance “x”. For an embodiment of a BH laser die 1100, the distance between the optical axis of the BH laser, and the horizontal surface 1126 of the one or more vertical alignment aids 1136 is formed equal to, or approximately equal to, this distance “x” in order to provide an assembly 1102 in which the lateral projections of the optical axes of the BH laser 1100 and the interposer are aligned.

The multiple height alignment pillars 1134, 1135 on interposer 1101 can be accommodated with embodiments of the BH laser die 1100.

FIGS. 11D(i) and 11D(ii) show the interposer structures of FIGS. 11C(i) and 11C(ii) with embodiments of BH laser die 1100 that are formed with complementary alignment aids 1136,1137. Embodiments of the BH laser die 1100 are configured to conform to the multiple height alignment pillar configurations of the interposers 1101 shown in the PIC assemblies 1102 in FIGS. 11D(i) and 11D(ii).

In FIGS. 11D(i) and 11D(ii), the distances between the horizontal surfaces 1125 of the vertical alignment pillars 1134 on the interposers 1101 and the optical axes of the planar waveguides 1105, in each figure, is shown labeled as distance “x”. For an embodiment of a BH laser die 1100, the distance between the optical axis of the BH laser 1100, and the horizontal surface 1126 of the one or more vertical alignment aids 1136, labeled distance “y”, is formed equal to, or approximately equal to, distance “x” in order to provide an assembly 1102 in which the lateral projections of the optical axes of the BH laser 1100 and the interposer are aligned. For the alignment in the vertical direction, wherein the lateral projections of the optical axes are brought into alignment, the matching, or approximate matching of the “x” and “y” distances, is applicable for embodiments with multiple height alignment pillars on the interposer 1101.

The two etch stop layers 1122,1124 are positioned below the active emission layer 1166 of the BH laser 1100 in the embodiment shown in FIG. 11D(i). Other embodiments of the BH laser die 1100 can also be used to form assemblies 1102 with interposers 1101 having multiple height alignment pillars 1134,1135 in which the one or more vertical alignment pillars 1134 are shorter than the lateral alignment pillar 1135.

In the embodiment shown in FIG. 11D(ii), one of the two etch stops 1122, 1124 is positioned below the active emission layer of the BH laser 1100 and the other is positioned above the active emission layer of the BH laser. The reduced height of the lateral alignment aid 1135 on the interposer 1101 requires a taller alignment pillar 1137 on the BH laser 1100, and thus a larger spacing between the first etch stop layer 1122 and the optical axis of the BH laser 1100. Other embodiments can also be used for other interposers 1101 having multiple height alignment pillars 1134,1135 in which the vertical alignment pillar 1134 is taller than the lateral alignment pillar 1135.

FIGS. 11D(i) and 11D(ii) illustrate additional embodiments of the BH laser 1100 that can be coupled to complementary interposers 1101 that include alignment pillars 1134,1135 to form PIC assemblies 1102. BH laser die 1100 that include vertical alignment aids 1136 and lateral alignment aids 1137 having heights and protrusions formed from various positionings of the first and second etch stop layers, can be formed that lead to aligned optical axes of the laser die and planar waveguides on the interposer 1101. The heights of a complementary set of alignment aids, such as vertical alignment aid 1136 on a BH laser die 1100 and pillar 1134 on the interposer, can be formed over a range of heights that are compatible such that a lateral projection of the optical axis is aligned upon placement of the BH laser die 1100 onto the interposer (such that a contact is formed between the horizontal surface 1126 of the vertical aid 1136 and the top surface 1125 of the alignment pillar 1135.) Additionally, the heights of the complementary alignment aids, such as lateral alignment aids 1137 on a BH laser die 1100 and pillar 1135 on the interposer, can be formed over a range of heights that are compatible such that the height of the protrusion 1123 overlaps with the pillar 1135 on the interposer to form a lateral constraint.

FIG. 11E shows an assembly 1102 that includes the embodiment of a BH laser die 1100 as described in FIG. 8 using the embodiment of the method of formation as described in the flowchart in FIG. 7. The embodiment of the BH laser die 1100 shown in FIGS. 8(ii) and 11E for which the first etch stop layer 1122 is an optional layer, shows vertical and lateral alignment aids 1136,1137 on the BH laser die 1100 that are formed at the same height using the etch stop properties of the second etch stop layer 1124 to form the top horizontal alignment surfaces 1126 on the vertical alignment aids 1136 and a corresponding horizontal surface on the lateral alignment aids 1137. Since the alignment aids 1136,1137 on the embodiment of the BH laser die 1100 are formed at a same height, the alignment aids 1134,1135 on a complementary interposer 1101 must be formed at multiple heights. An example of a complementary interposer 1101 to which the embodiment of the BH laser die 1100 of FIG. 8(ii) can be mounted, is shown in the assembly 1102 of FIG. 11E. In the assembly 1102 of FIG. 11E, interposer 1101 is configured to provide alignment pillars 1134, 1135 at multiple heights to provide the vertical and lateral alignment capability that is provided in other embodiments. In this assembly, the horizontal surface 1126 of the vertical alignment aid 1136 on BH laser 1100 forms a contact with horizontal surface 1125 of the vertical alignment aid 1134 on the interposer 1101 to form the alignment of the lateral projection 1108 of the optical axes of the BH laser die 1100 and the planar waveguide layer 1105 of the interposer 1101. In the absence of a protrusion 1123 on the BH laser 1100, as in other embodiments, lateral alignment aids 1135 on the interposer 1101, are formed taller than the vertical alignment aids 1134 on the interposer 1101. The increased height of the lateral alignment aids 1135 on the interposer 1101 provides vertical surface 1129 on the lateral alignment feature 1135 to which a contact can be formed with the vertical surface 1128 of the lateral alignment aid 1137 on the embodiment of the BH laser die 1100.

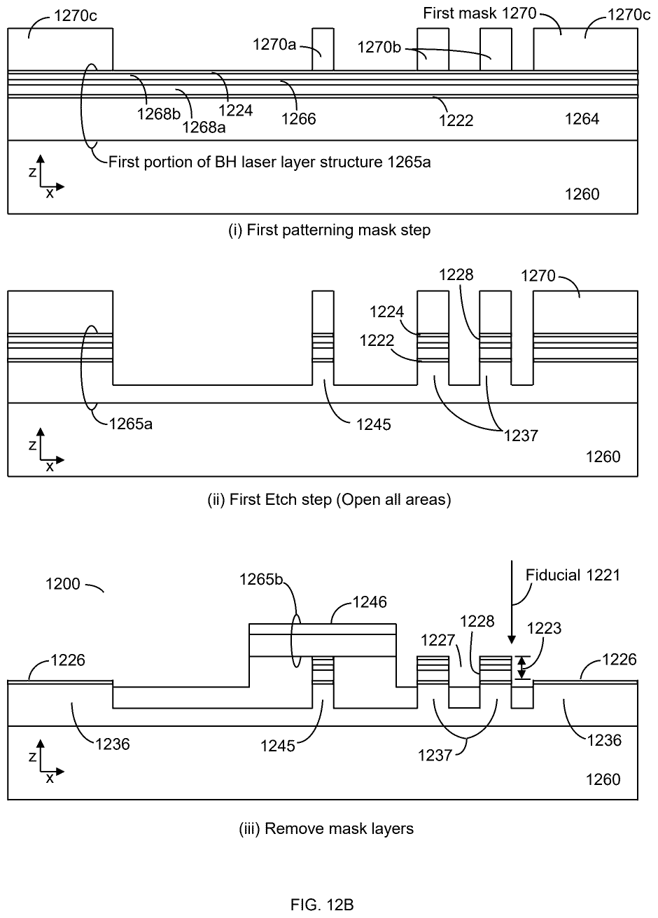

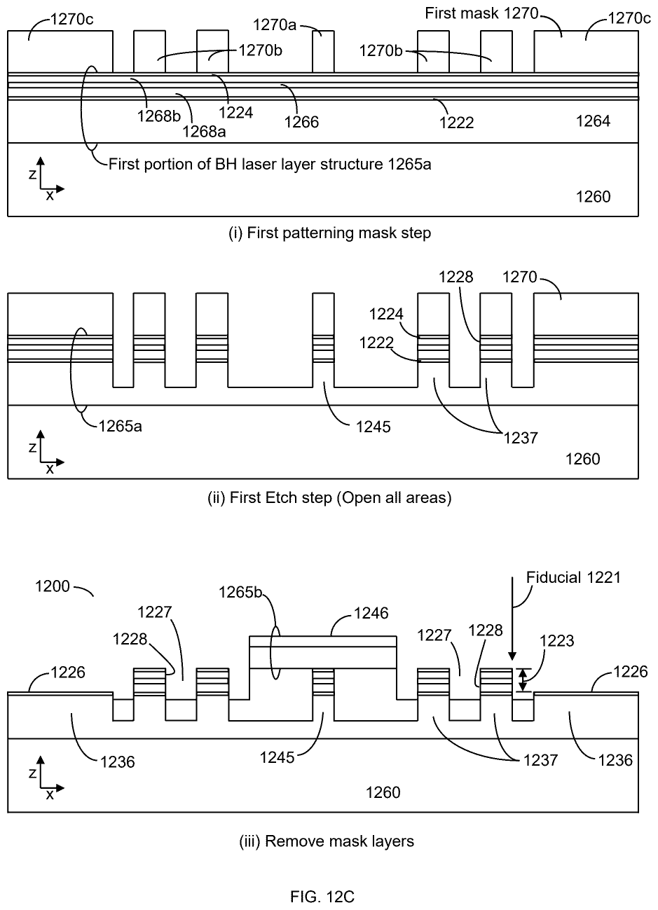

FIGS. 12A-12C show a number of embodiments of BH laser die that include an embodiment having multiple pillar-type lateral alignment features, an embodiment having a single cavity-type lateral alignment features, and an embodiment having multiple cavity-type lateral alignment features, respectively. FIGS. 12A-12C can be compared with the single pillar-type lateral alignment feature structure of FIG. 1A.

FIGS. 12A(i)-12A(iii) show cross section drawings of some steps in the formation of a BH laser die having alignment aids for an embodiment that includes multiple pillar-type lateral alignment aids. A more complete embodiment of the method of formation of BH lasers with alignment aids is provided in flowchart 310. FIG. 12A(i)-12A(iii) show a selected number of steps that are similar to steps from the process flow 310 as described for example in FIGS. 4(i)-4(xiii).

FIG. 12A(i) shows a cross section drawing that includes first mask 1270. First mask 1270 includes portion 1270a that is used in the patterning and formation of a ridge structure of a BH laser layer structure. First mask 1270 also includes multiple portions 1270b that are used in the patterning and formation of multiple pillar-type lateral alignment features. In the embodiment shown, first mask 1270 also includes multiple portions 1270c that are used in the patterning and formation of multiple vertical alignment features on the BH laser die. The first mask layer 1270 is formed on a first portion of a BH laser structure 1265a that includes a first stack of semiconductor layers formed on a base structure 1215, wherein the base structure includes a first etch stop 1222, an optional semiconductor layer 1264, and a substrate 1260.

The first stack of semiconductor layers 1265a, as shown, includes an active layer 1266, lower and upper semiconductor layers 1268a, 1268b, respectively, and second etch stop layer 1224. The active layer 1266 is an emission layer for the BH laser structure and may include one or more quantum wells. Quantum well structures used in the formation of BH lasers are known in the art of BH laser fabrication as are other methods for forming the emission layers of these devices. Lower and upper semiconductor layers 1268a, 1268b can be confinement layers, graded index layers, waveguiding layers, grating layer, or other layers used in the formation of BH layer structures. Lower semiconductor layer 1268a may be a similar structure to that of the upper semiconductor layer 1268b or the layer 1268a may be a different structure to that of the upper semiconductor layer 1268b. The lower and upper semiconductor layers 1268a,1268b may be such to provide coincidence in the heights of the center of the optical emission of a laser and the center of the optical signal mode of the waveguiding layers or the lower and upper semiconductor layers 1268a,1268b may be such to provide an offset in the heights of the center of the optical emission layer and the center of the optical signal mode of the waveguiding layers.

The second etch stop layer 1224 is shown as a top layer of the first portion of the BH laser layer structure 1265a. Second etch stop layer 1224 may be a layer specifically introduced into the first stack of semiconductor layers 1265a as an etch stop layer or the second etch stop layer 1224 may be a layer within the structure that has another role in the functioning of the BH laser. A graded index layer, for example, formed from a quaternary compound layer may be used as second etch stop layer 1224.

FIG. 12A(ii) shows a BH laser layer structure after a patterning step in which all or a portion of the first stack of semiconductor layers of a first portion 1265a of an embodiment of a BH laser structure is patterned to form all or a portion of a ridge structure 1245 for a BH laser and all or a portion of a vertical surface 1228 of multiple pillar-type lateral alignment features 1237, wherein the patterning step includes the patterning of the second etch stop layer 1224, and optionally includes the patterning of the first etch stop layer 1222. FIG. 12A(ii) shows an embodiment in which the first etch stop layer 1222 is optionally patterned.

In FIG. 12A(iii), the BH laser structure 1200 is shown after formation of the BH laser pedestal 1246 that includes BH ridge structure 1245, the multiple pillar-type lateral alignment features 1237 having vertical surface 1228, and vertical alignment features 1236. In the embodiment shown in the FIG. 12A(iii), BH laser structure 1200 includes multiple pillar-type lateral alignment features 1237 and multiple pillar-type vertical alignment features 1236. Multiple pillar-type lateral alignment features facilitate constraints against movement in multiple lateral directions. FIG. 12A(iii) shows the protrusion 1223 of the lateral alignment aids 1237 formed in part by the second etch stop layer 1224, the fiducial formed from vertical surface 1228 of a lateral alignment aid 1237, and vertical alignment aids 1236 having alignment surface 1226 formed on first etch stop layer 1222. The ridge structure 1245 is shown in pedestal 1246. The patterned second portion 1265b of the BH laser layer structure is shown in the pedestal with the current blocking layer 1267.

FIGS. 12B(i)-12B(iii) show cross section drawings of some steps in the formation of another embodiment of a BH laser die having alignment aids for an embodiment that includes a single cavity-type lateral alignment aid. A more complete embodiment of the method of formation of BH lasers with alignment aids is provided in flowchart 310. FIGS. 12B(i)-12B(iii) show a selected number of steps that are similar to steps from the process flow 310 as described for example in FIGS. 4(i)-4(xiii).

FIG. 12B(i) shows a cross section drawing that includes first mask 1270. First mask 1270 includes portion 1270a that is used in the patterning and formation of a ridge structure of a BH laser layer structure. First mask 1270 also includes portion 1270b used in the patterning and formation of a cavity-type lateral alignment feature. In the embodiment shown, first mask 1270 also includes multiple portions 1270c that are used in the patterning and formation of multiple vertical alignment features on the BH laser die. The first mask layer 1270 is formed on a first portion of a BH laser structure 1265a that includes a first stack of semiconductor layers formed on a base structure 1215, wherein the base structure includes a first etch stop 1222, an optional semiconductor layer 1264, and a substrate 1260.

FIG. 12B(ii) shows a BH laser layer structure after a patterning step in which all or a portion of the first stack of semiconductor layers of a first portion 1265a of an embodiment of a BH laser structure is patterned to form all or a portion of a ridge structure 1245 for a BH laser and all or a portion of a vertical surface 1228 of a cavity-type lateral alignment feature 1237, wherein the patterning step includes the patterning of the second etch stop layer 1224, and optionally includes the patterning of the first etch stop layer 1222. FIG. 12B(ii) shows an embodiment in which the first etch stop layer 1222 is optionally patterned.

In FIG. 12B(iii), the BH laser structure 1200 is shown after formation of the BH laser pedestal 1246 that includes BH ridge structure 1245, the cavity-type lateral alignment feature 1237, and vertical alignment features 1236. In the embodiment shown in the FIG. 12B(iii), BH laser structure 1200 includes the cavity-type lateral alignment feature 1237 having cavity 1227 and vertical or near vertical wall surfaces 1228, and multiple pillar-type vertical alignment features 1236 having horizontal surfaces 1226. Cavity-type lateral alignment feature 1237 facilitates constraint against movement in multiple lateral directions as further described herein. FIG. 12A(iii) shows the protrusion 1223 of the lateral alignment aids 1237 formed in part by the second etch stop layer 1224, the fiducial formed from vertical surface 1228 of a lateral alignment aid 1237, and vertical alignment aids 1236 having alignment surface 1226 formed on first etch stop layer 1222. The ridge structure 1245 is shown in pedestal 1246. The patterned second portion 1265b of the BH laser layer structure is shown in the pedestal with the current blocking layer 1267.

FIGS. 12C(i)-12C(iii) show cross section drawings of some steps in the formation of yet another embodiment of a BH laser die having alignment aids for an embodiment that includes multiple cavity-type lateral alignment aids. A more complete embodiment of the method of formation of BH lasers with alignment aids is provided in flowchart 310.

FIGS. 12C(i)-12C(iii) show a selected number of steps that are similar to steps from the process flow 310 as described for example in FIGS. 4(i)-4(xiii).

FIG. 12C(i) shows a cross section drawing that includes first mask 1270. First mask 1270 includes portion 1270a that is used in the patterning and formation of a ridge structure from the BH laser layer structure. First mask 1270 also includes multiple portions 1270b that are used in the patterning and formation of multiple lateral alignment features. In the embodiment shown, first mask 1270 also includes multiple portions 1270c that are used in the patterning and formation of multiple vertical alignment features on the BH laser die. The first mask layer 1270 is formed on a first portion of a BH laser structure 1265a that includes a first stack of semiconductor layers formed on a base structure 1215, wherein the base structure includes a first etch stop 1222, an optional semiconductor layer 1264, and a substrate 1260.

FIG. 12C(ii) shows a BH laser layer structure after a patterning step in which all or a portion of the first stack of semiconductor layers of a first portion 1265a of an embodiment of a BH laser structure is patterned to form all or a portion of a ridge structure 1245 for a BH laser and all or a portion of one or more vertical surfaces 1228 of multiple cavity-type lateral alignment features 1237, wherein the patterning step includes the patterning of the second etch stop layer 1224, and optionally includes the patterning of the first etch stop layer 1222. FIG. 12C(ii) shows an embodiment in which the first etch stop layer 1222 is optionally patterned.

In FIG. 12C(iii), the BH laser structure 1200 is shown after formation of the BH laser pedestal 1246 that includes BH ridge structure 1245, multiple cavity-type lateral alignment features 1237, and vertical alignment features 1236. In the embodiment shown in the FIG. 12C(iii), BH laser structure 1200 includes multiple cavity-type lateral alignment features 1237 having cavities 1227 and interior vertical or near vertical wall surfaces 1228, and multiple pillar-type vertical alignment features 1236. Multiple cavity-type lateral alignment features facilitate constraints against movement in multiple lateral directions and can reduce the potential for breakage that can occur with pillar-type lateral alignment aids. FIG. 12(iii) shows the protrusion 1223 of the lateral alignment aids 1237 formed in part by the second etch stop layer 1224, the fiducial formed from vertical surface 1228 of a lateral alignment aid 1237, and vertical alignment aids 1236 having alignment surface 1226 formed on first etch stop layer 1222. The ridge structure 1245 is shown in pedestal 1246. The patterned second portion 1265b of the BH laser layer structure is shown in the pedestal with the current blocking layer 1267.

The BH laser die 1200 with alignment aids shown in FIGS. 12A-12C show some variations in the structure and quantity of lateral alignment aids in embodiments having pillar-type and cavity type lateral alignment aids 1237. Other embodiments for which a lateral alignment surface 1228 is provided can also be used and remain within the scope of embodiments. Similarly, other embodiments for which a horizontal alignment surface 1226 is provided can also be used and remain within the scope of embodiments.

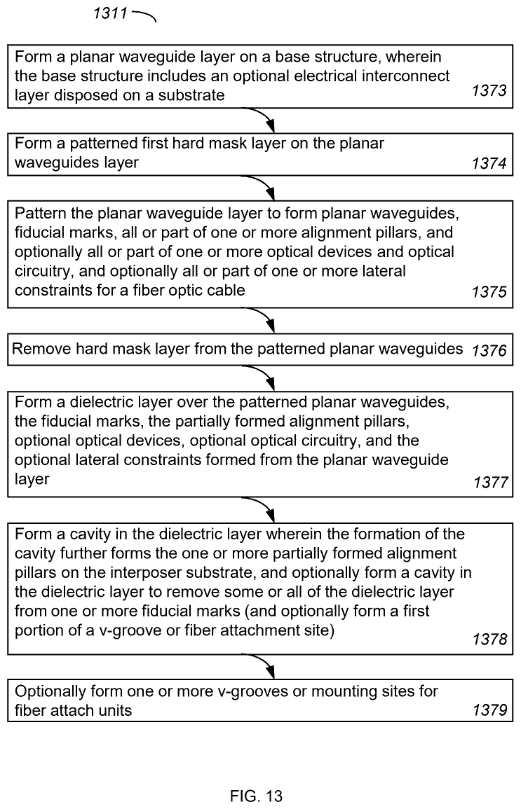

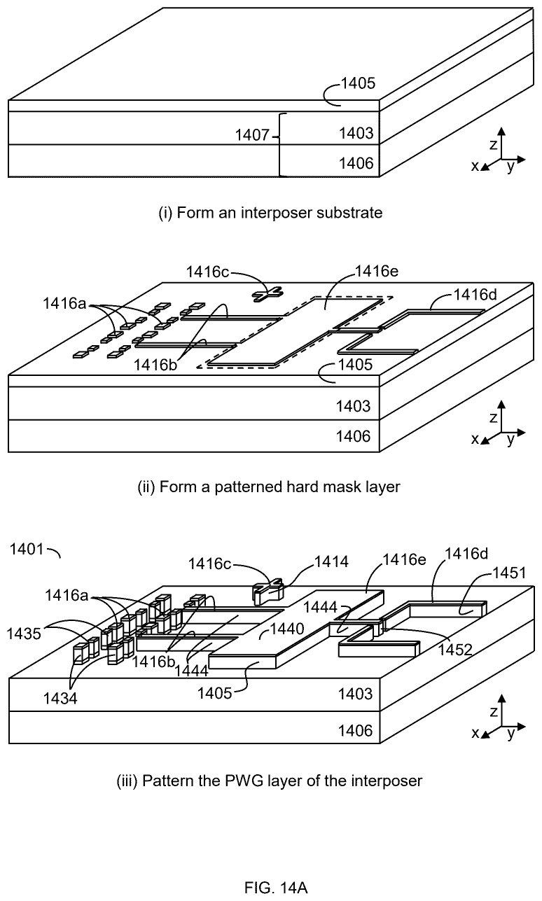

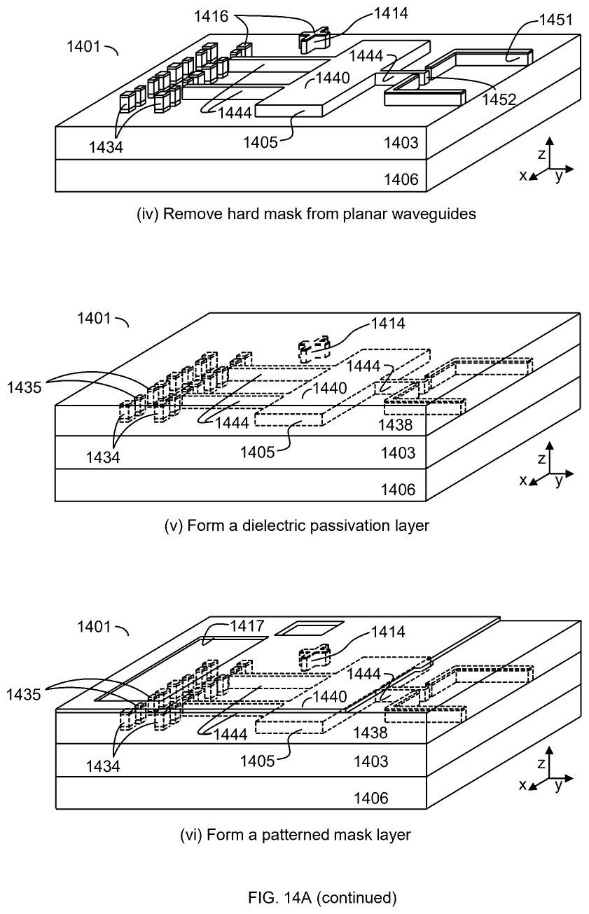

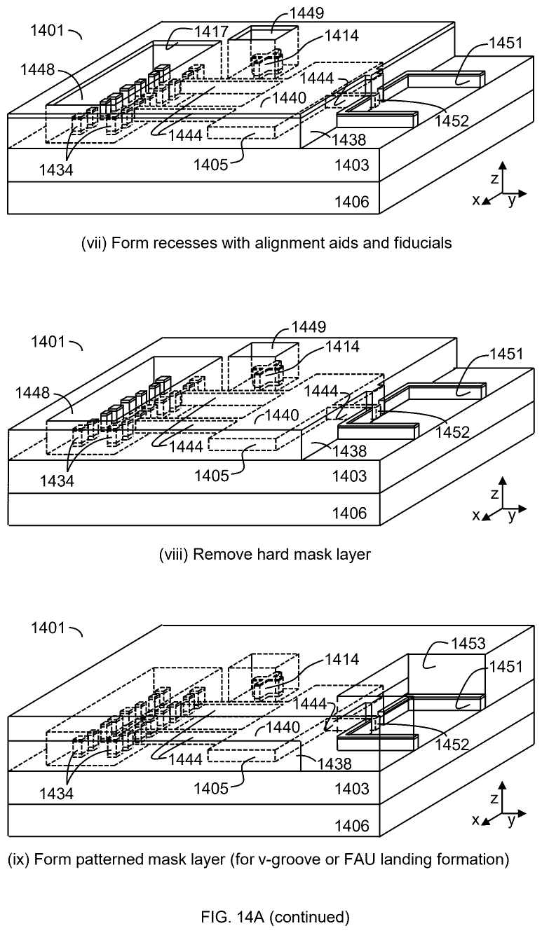

FIG. 13 shows a flow chart for an embodiment of a method 1311 of forming an interposer with a planar waveguide layer and alignment pillars, among other features, compatible with BH laser die having alignment features disclosed herein.

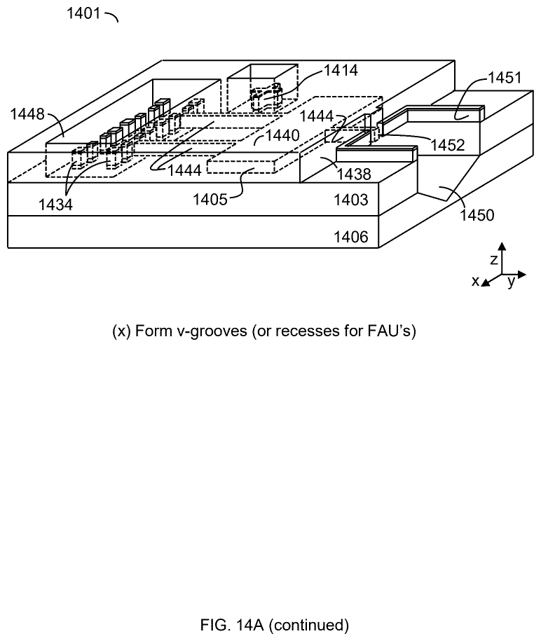

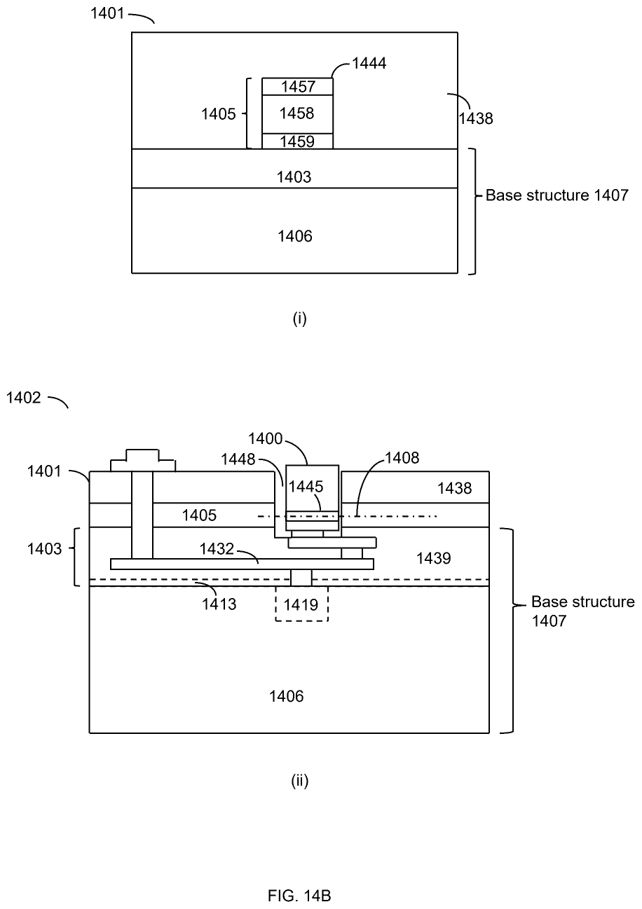

The steps in the flowchart in FIG. 13 are provided in conjunction with the perspective drawings in FIGS. 14A(i)-14A(x).

Step 1373 of method 1311 is a forming step in which a planar waveguide layer is formed on a base structure, wherein the base structure includes an optional electrical interconnect layer disposed on a substrate. FIG. 14A(i) shows a perspective drawing of an embodiment of a planar waveguide layer 1405 on base structure 1407, wherein the base structure 1407 includes optional electrical interconnect layer 1403 disposed on substrate 1406.

Planar waveguide layer 1405 is a medium through which optical signals can propagate. Planar waveguide layer 1405 can be a dielectric layer such as a layer of silicon nitride, silicon oxynitride, or silicon oxide. Planar waveguide layer 1405 can be a polymer layer. In preferred embodiments, planar waveguide layer is comprised of a core layer, an upper cladding layer, and a lower cladding layer. Planar waveguide layer 1405 may include one or more of a spacer layer, buffer layer, a planarization layer, or other layer. The core layer can be a single layer, or can be comprised of multiple layers. In some embodiments, the planar waveguide layer 1405 may be a portion of a planar waveguide layer that includes a lower cladding layer and all or a portion of a core layer, for which a portion of the core layer, and all or a portion of the upper cladding layer is formed in a subsequent processing step as described herein.

Optional electrical interconnect layer 1403 is a layer comprised of one or more metal layers and one or more dielectric layers and may include other layers as further described herein. In some embodiments, the electrical interconnect layer 1403 is not in direct contact with the substrate but rather an intervening layer is present. Similarly, the planar waveguide layer 1405, in some embodiments, is not in direct contact with the underlying electrical interconnect layer 1403 but rather an intervening layer or layers may be present.

Substrate 1406 is a mechanical support layer and may be a semiconductor such as silicon or another semiconductor. In some embodiments, substrate 1406 includes one or more layers of a semiconductor material such as silicon, indium phosphide, gallium arsenide, or another semiconductor. In other embodiments, a ceramic or insulating substrate is used. In yet other embodiments, a metal substrate is used. And in yet other embodiments, a combination of one or more semiconductor layers, insulating layers, and metal layers are used to form a substrate 1406 upon which the optional electrical interconnect layer 1403 and the planar waveguide layer 1405 are formed.

Step 1374 of method 1311 is a forming step in which a first patterned hard mask is formed on a planar waveguide layer. FIG. 14A(ii) shows a perspective drawing of an embodiment of a first patterned hard mask layer 1416 formed on planar waveguide layer 1405. The first patterned hard mask layer 1416 is preferably a mask that provides high etch selectivity between the planar waveguide layer 1405 and the mask material. In an embodiment, a patterned aluminum layer is used to form the hard mask 1416. In other embodiments, an alloy with a high percentage of aluminum is used to form the patterned hard mask. Other hard mask materials may also be used. Aluminum and aluminum alloys have a low etch rate, for example, in fluorine-containing plasma etch chemistries used in the patterning of dielectric materials such as silicon oxynitride that can be used in the formation of planar waveguides such as planar waveguide layer 1405.

In the embodiment shown in FIG. 14A(ii), hard mask layer 1416 has patterned portions 1416a for the formation of alignment pillars, patterned portions 1416b for the formation of planar waveguides, patterned portions 1416c for the formation of fiducials, patterned portions 1416d for the formation of v-grooves or landings for fiber attach units, and patterned portions 1416e for the formation of optical devices or optical circuitry. In other embodiments, additional hard mask portions may be included. And in yet other embodiments, one or more of the hard mask portions shown in FIG. 14A(ii) may not be included. And in yet other embodiments, one or more of the hard mask portions may not be included and one or more additional hard mask portions may be included.

Inclusion of the patterned hard mask portions 1416a, 1416b, 1416c, 1416d, 1416e ensures that these features are aligned within the tolerances of the lithographic processes. Lithographic processes that have sub-micron level accuracy between features are commonly used in semiconductor processing. Use of a same hard mask to provide each of the patterned portions 1416a, 1416b, 1416c, 1416d, 1416e ensures sub-micron accuracy in the positioning of each of the features formed from the patterned hard mask in the underlying planar waveguide layer 1405.

Step 1375 of method 1311 is a patterning step in which the planar waveguide layer is patterned to form one or more planar waveguides, one or more fiducial marks, all or a part of one or more alignment pillars, all or part of one or more lateral alignment constraints, and all or part of one or more optical devices or optical circuitry. FIG. 14A(iii) shows a perspective drawing of an embodiment of a planar waveguide layer 1405 on base structure 1407, wherein the planar waveguide layer 1405 is patterned to form one or more planar waveguides 1444, one or more fiducial marks 1414, all or a part of one or more alignment pillars 1434,1435, all or part of one or more lateral alignment constraints 1451, and all or part of one or more optical devices or optical circuitry 1440. Lateral constraint 1451, in the embodiment shown, is a lateral constraint for a self-aligned v-groove or fiber attach unit. Each of the features formed in the planar waveguide layer 1405 from the patterned hard mask 1416 in patterning step 1375 is aligned with other features formed in the planar waveguide layer 1405 from the patterned hard mask 1416.

Step 1376 of method 1311 is a removing step in which the hard mask layer is removed from at least a patterned planar waveguide. FIG. 14A(iv) shows a perspective drawing of an embodiment of a patterned planar waveguide layer 1405 on base structure 1407, wherein the hard mask layer 1416c has been removed from the planar waveguides 1444 formed in the planar waveguide layer 1405. The removal of aluminum or other metal hard mask layers is necessary to facilitate the formation of one or more of a dielectric waveguide cladding layer, spacer layer, and a buffer layer, among others, over and aside the planar waveguides 1444. In embodiments, the mask material can optionally be removed from other portions of the patterned planar waveguide layer 1405. In the embodiment shown, the hard mask layer 1416d is also shown removed from optional device 1440.

Step 1377 of method 1311 is a forming step in which a dielectric layer is formed at least partially over one or more of the patterned planar waveguides, fiducial marks, partially formed alignment pillars, optional optical devices, optional optical circuitry, and optional lateral constraints. FIG. 14A(v) shows a perspective drawing of an embodiment of a patterned planar waveguide layer 1405 on base structure 1407, wherein the hard mask layer 1416c has been removed from the planar waveguides 1444 and the planar optical devices 1440 formed in the planar waveguide layer 1405, and a dielectric layer 1438 has been formed over the patterned planar waveguide layer 1405. The dielectric layer 1438 in some embodiments, provides one or more of a dielectric waveguide cladding layer, spacer layer, and a buffer layer, among others, over and aside planar waveguides 1444, optical devices 1440, optical circuitry 1440, the alignment pillars 1434,1435, the fiducials 1414, and the lateral constraints 1451. In this embodiment, the hard mask has not been removed from the partially formed alignment pillars 1434,1435, the fiducials 1414, and the lateral constraints 1451. In other embodiments, the hard mask 1416 may be removed from one or more of these portions of the interposer 1401.

Step 1378 of method 1311 is a forming step in which one or more cavities are formed in the dielectric layer to further form the one or more partially formed alignment pillars and to remove some or all of the dielectric layer from the fiducial marks. Optionally, other portions of the dielectric layer 1438 can be removed. FIGS. 14A(vi)-14A(viii) show a sequence of steps in the formation of cavity 1448 in dielectric layer 1438 wherein the formation of the cavity 1448 further forms alignment pillars 1434, 1435, and wherein the formation of cavity 1449 results in the removal of the dielectric layer 1438 from the fiducial mark 1414. In the sequence of steps shown in FIGS. 14A(vi)-14A(viii), a portion of the dielectric layer is also removed to enable formation of one or more v-grooves for the positioning of fiber optic cables onto a PIC formed from the interposer 1401.

FIG. 14A(vi) shows a perspective drawing of a patterned planar waveguide layer 1405 on base structure 1407 wherein a dielectric layer 1438 has been formed over the patterned planar waveguide layer 1405, and second patterned hard mask 1417 has been formed over the dielectric layer 1438. The second patterned hard mask layer 1417 has openings that enable the formation of cavity 1448 and cavity 1449. Second hard mask 1417 can be an aluminum hard mask, for example, or can be an alloy of aluminum. Other hard mask materials may also be used that provide a high etch selectivity for the dielectric layer 1438. A high etch rate for the dielectric layer 1438 is preferred in comparison to the hard mask layer 1417.

FIG. 14A(vii) shows a perspective drawing after an etching step in which the dielectric layer 1438 has been etched through the patterned hard mask 1417. FIG. 14A(vii) shows the further formation of the alignment pillars 1434,1435 in cavity 1448 and the removal of the dielectric layer 1438 from the fiducial mark 1414 in cavity 1449. FIG. 14A(vii) also shows the removal of the dielectric layer in proximity to the lateral constraint 1451. Lateral constraint 1451 is an alignment feature that enables accurate placement of a fiber optic cable onto a PIC formed from the interposer 1401.

FIG. 14A(viii) shows a perspective drawing after the removal of second hard mask layer 1449 from the interposer 1401.

Step 1379 of method 1311 is an optional forming step in which one or more v-grooves or one or more mounting sites for fiber attach units are formed on the interposer. FIGS. 14A(ix) and 14A(x) show a sequence of steps in the formation of v-groove 1450 on interposer 1401. FIG. 14A(ix) shows a forming step in which a patterned mask layer 1453 is formed on the interposer 1401. Openings in the mask layer provide access to locations in the substrate of the interposer through which v-grooves can be formed. Mask layer 1453, can be, for example, a patterned photoresist layer formed on the interposer 1401. A pattern can be formed in the mask layer 1453 to reveal all or a portion of the opening between one or more lateral constraints 1451 described in FIG. 14A(vii) through which the one or more v-grooves are formed in the substrate through the openings in the mask layer 1453. After formation of the patterned mask layer 1453, the dielectric layer of the electrical interconnect layer 1403 is removed using for example, a dry etch process. V-grooves can be formed in the substrate using, for example, a potassium hydroxide etch or other wet etch chemistry that selectively etches along crystallographic planes to form the “v” in the v-grooves. FIG. 14A(x) shows a perspective drawing of interposer 1401 after formation of a v-groove 1450. The v-groove is shown formed through lateral constraint 1451. The lateral constraint 1451 provides a lateral alignment feature that facilitates the alignment of a fiber optic cable coupled into the v-groove to a planar waveguide 1444 or other optical device on the interposer 1401. Formation of the lateral constraints 1451 from the planar waveguide layer 1405 from which the planar waveguides 1444, optical devices 1440, alignment pillars 1434, 1435, and the fiducials 1414 are also formed, provides accurate relative positioning of these features on the interposer.

An alternative to the formation of v-grooves on the interposer is the formation of one or more mounting sites for one or more fiber attach units to facilitate mounting of one or more fiber optic cables to the interposer 1401.

FIG. 14B(i) shows a cross section drawing of a planar waveguide 1444, formed from the planar waveguide layer 1405 on the interposer 1401. Waveguide 1444 is shown formed on base structure 1407 that includes an optional electrical interconnect layer 1403 on substrate 1406. The planar waveguide layer 1405 shown in FIG. 14B(i) includes core layer 1458 and top and bottom cladding layers 1457, 1459, respectively. Other planar waveguide structures can also be used on the interposer 1401. In some embodiments, all or a portion of the upper cladding layer 1457 may be excluded from the planar waveguide layer 1405 and included in the dielectric layer 1438.

FIG. 14B(ii) shows a cross section drawing of an example interposer 1401 that includes features of the electrical interconnect layer 1403. Optional electrical interconnect layer 1403 and substrate 1406 form base structure 1407. Electrical interconnect layer 1403 includes metallization layers 1432 and intermetal dielectric layers 1439 and may include high thermal conductivity layer 1413 and electrical devices 1419. Planar waveguide layer 1405 is shown on electrical interconnect layer 1403. Cavity 1448 is shown in dielectric layer 1438. Dielectric layer 1438 can be one or more of a cladding layer, spacer layer, buffer layer, planarization layer, insulating layer, isolation layer, or other layer. Dielectric layer 1448 is shown on the planar waveguide layer 1405. Optical die 1400 is shown mounted in cavity to the electrical connections below the cavity. Optical die 1400 may be mounted on alignment features formed in the cavity as described herein. The optical axis of the optical die, shown in BH laser ridge feature 1445, is aligned with the optical axis of the planar waveguide layer to form aligned optical axis 1408 for the assembly 1402.

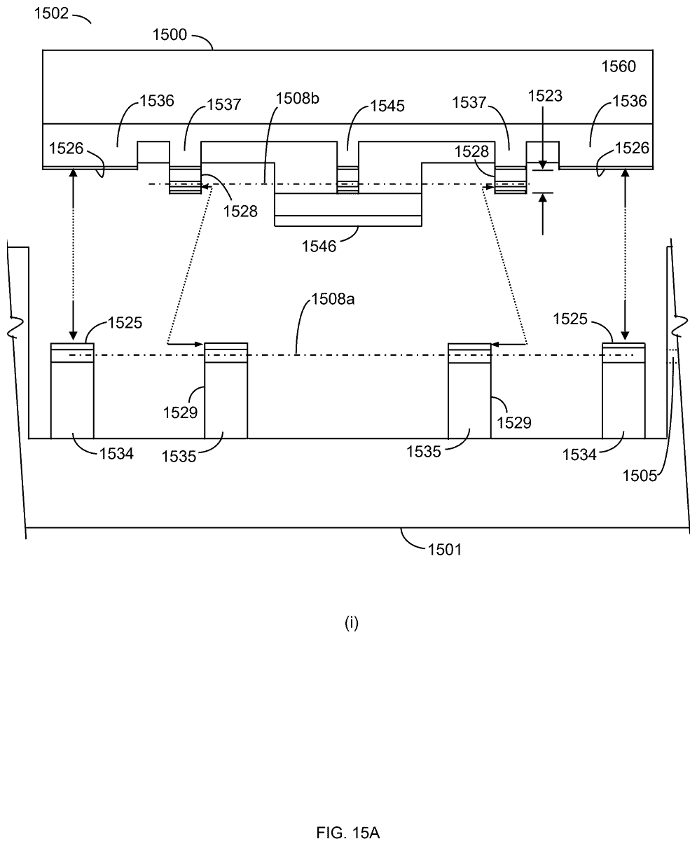

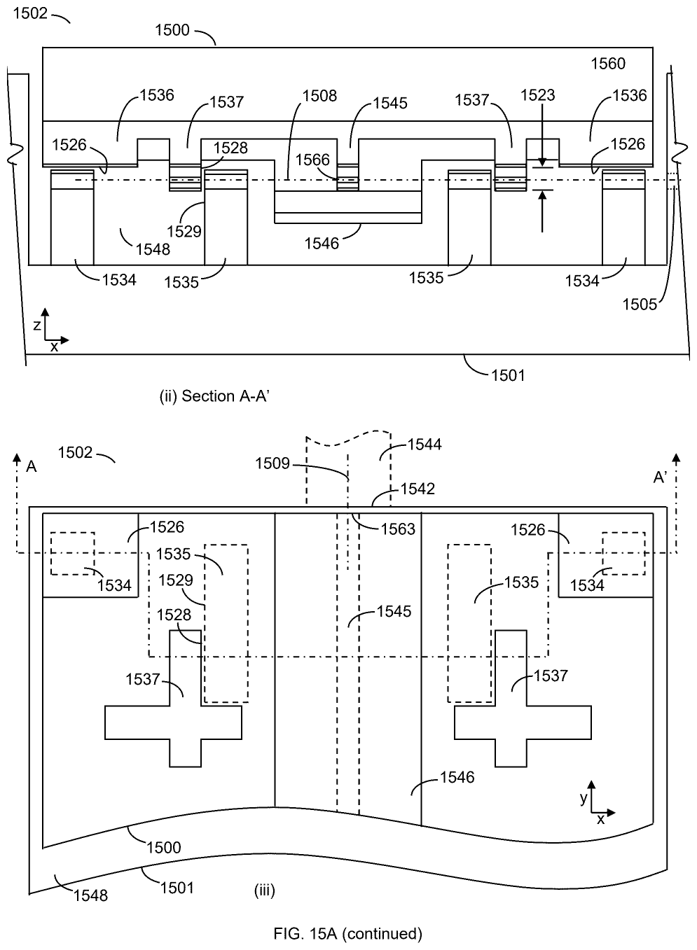

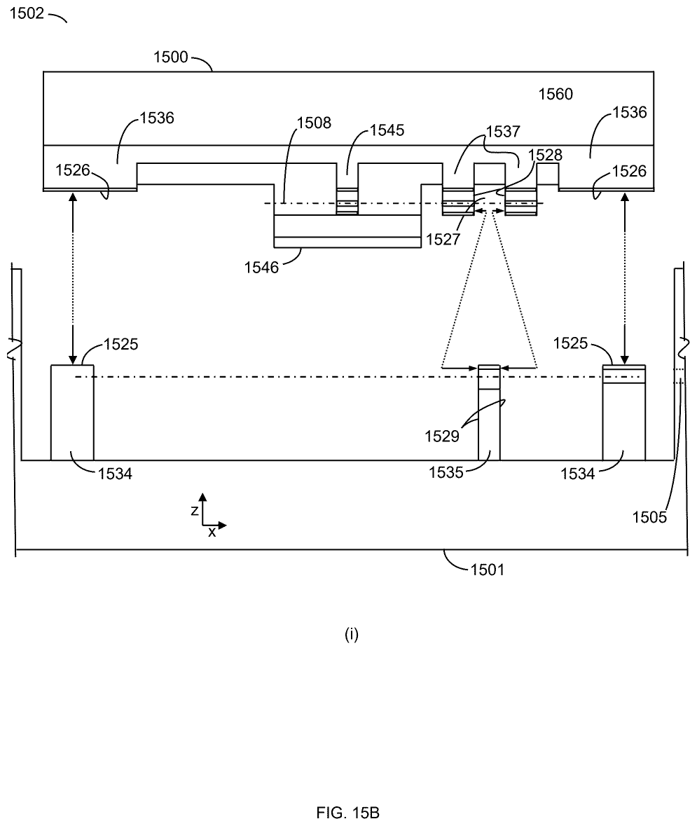

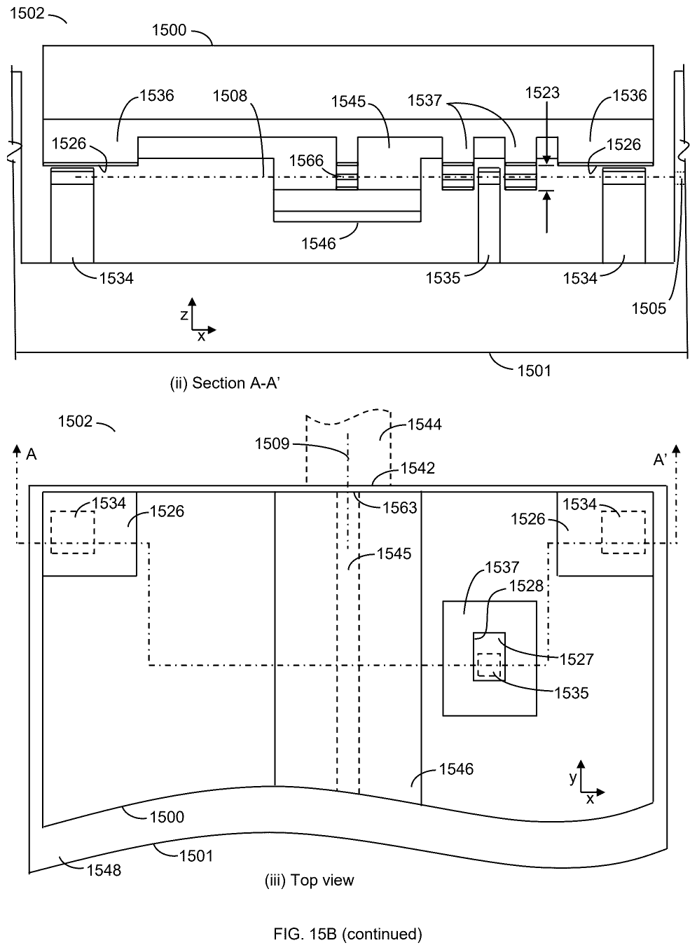

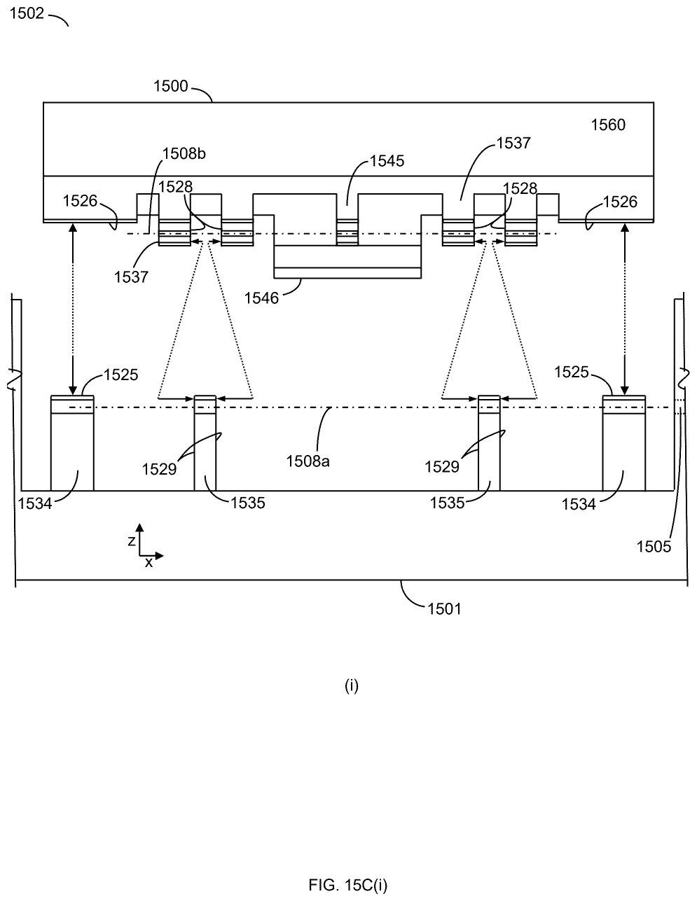

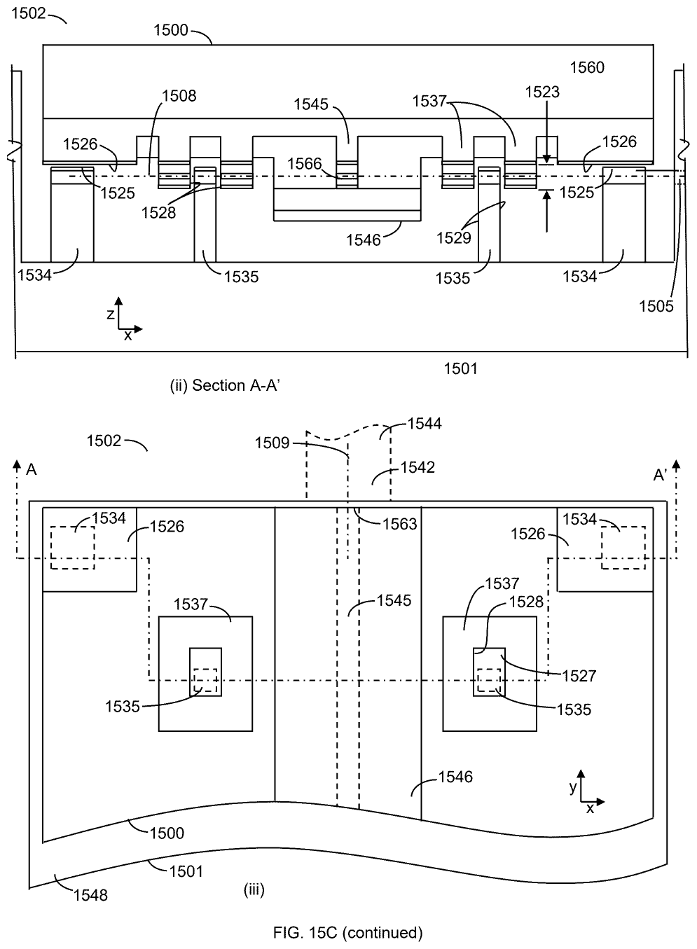

FIGS. 15A-15C show PIC assemblies 1502 that include embodiments of BH laser die 1500 and interposers 1501. In these figures, the example embodiments described in FIGS. 12A-12C are shown with interposers, formed with complementary alignment aids, to form the PIC assemblies 1502.

FIG. 15A(i) shows an exploded cross section drawing of an assembly 1502 that includes an embodiment of a BH laser die 1500 having multiple vertical alignment aids 1536 and multiple pillar-type lateral alignment aids 1537 and positioned on an interposer 1501 having complementary vertical alignment aids 1534 and complementary lateral alignment aids 1535. BH laser die 1500 is formed on substrate 1560 using, for example, a process described in the flowchart in FIG. 3. The vertical alignment aids 1536 on the BH laser die 1500 are formed having horizontal surfaces 1526 that, in the assembly 1502, form a contact with a horizontal surface 1525 on complementary vertical alignment aid 1534 on interposer 1501.

The lateral alignment aids 1537 on the embodiment of the BH laser die 1500 shown in FIG. 15A(i) are formed having vertical surfaces 1528 that, in the assembly 1502, provide one or more lateral constraints to restrict the range of movement in the lateral direction during one or more of an assembly and an alignment procedure. Movement is restricted in the lateral direction during assembly or alignment when a contact is formed between one or more vertical surfaces 1528 on one or more lateral alignment features 1537 on the BH laser die 1500 and one or more vertical surfaces 1529 on one or more complementary lateral alignment feature 1535 on the interposer 1501. BH laser pedestal 1546 is shown with ridge structure 1545. The lateral projection 1508a of the optical axis of the interposer 1501, through the planar waveguide layer 1505, is shown. The lateral projection 1508b of the optical axis of the BH laser die 1500 is also shown.

FIG. 15A(ii) shows the unexploded cross section drawing of the PIC assembly 1502 of FIG. 15A(i) that includes an embodiment of a BH laser die 1500 and an interposer 1501. The cross section is Section A-A′ from FIG. 15A(iii). FIG. 15A(iii) shows a top view of the BH laser die 1500 and interposer 1501. The lateral projections 1508a, 1508b of the optical axes of BH laser die 1500 and interposer 1501, respectively, are shown in alignment to form aligned optical axis 1508 as a result of one or more horizontal surfaces 1526 of the BH laser die 1500 being brought into contact with one or more horizontal surfaces 1525 of the interposer 1501. In the PIC assembly 1502 shown in FIG. 15A(ii), the vertical alignment features 1536 of the BH laser die 1500 have been positioned upon vertical alignment pillars 1534 within a recess 1548 formed in interposer 1501.

Alignment of the lateral projections of the optical axes to form the aligned optical axis 1508 of the PIC assembly 1502 forms an alignment of the active emission mode of the BH laser die 1500 with the planar waveguide layer 1505 of the interposer 1501. In the top view of the assembly shown in FIG. 15A(iii), a portion of BH laser die 1500 is shown in recess 1548 with solid lines depicting the features on the bottom side of the BH laser die 1500 and the dotted lines depicting the hidden features on the interposer 1501. FIGS. 15A(ii) and 15A(iii) also show BH laser pedestal 1546 and ridge structure 1545. In the top view of FIG. 15A(iii), the front facet 1563 of the BH laser die 1500 is shown in alignment with facet 1542 of a planar waveguide 1544 formed in the planar waveguide layer 1505 of the interposer 1501.

The pillar-type lateral alignment aids 1537 on the BH laser die 1500 having vertical surfaces 1528 are shown positioned in proximity to the complementary lateral alignment aids 1535 on interposer 1501 that, in the assembly 1502, provide a lateral constraint for movement in one or more lateral directions. Movement is restricted during an assembly or an alignment process, for example, when a contact is formed between one or more vertical surfaces 1528 on one or more lateral alignment features 1537 on the BH laser die 1500 and one or more vertical surfaces 1529 on one or more complementary lateral alignment features 1535 on the interposer 1501. Protrusion 1523 on the BH laser die 1500 provides overlap of the vertical surface 1528 with that of the vertical surface 1529 on interposer 1501 in the assembly 1502. The protrusion 1523, in the embodiment, is equal to, or approximately equal to, the distance between the first and second etch stop layers in the BH laser structure 1500 as described herein.

The aligned vertical projection of the optical axis 1509 of the assembly 1502 is shown in the top view of FIG. 15A(iii). Alignment of the vertical projection of the optical axis 1509 of the assembly 1502 is facilitated in part by the restriction in lateral movement provided by the side surface 1528 of the lateral alignment aid 1535 of the BH laser die 1500 forming a contact with the side surface 1529 of the lateral alignment feature 1535 of the interposer 1501. The lateral alignment aids 1535, 1537 can be formed in a variety of shapes that facilitate the restriction in lateral movement and can vary in quantity. The embodiment of the BH laser die 1500 in FIGS. 15A(i)-15A(iii) shows two pillar-type alignment features 1537 on the BH laser die 1500 with a plus-sign shape in the top view. In other embodiments, more than two pillar-type lateral alignment features 1537 may be provided. In the PIC assembly 1502, contact need not be formed between the sides 1528,1529 of the lateral alignment aids 1537,1535, respectively, for the movement of the die 1500 to be constrained in a lateral direction on the interposer 1501. The lateral alignment features, for example, may not make contact but rather act to limit the movement should the side 1528 of the BH laser die 1500 form a contact with side 1529 of the interposer 1501. In some embodiments, a planar waveguide 1544 formed on the interposer 1501 that is wider or significantly wider, than the BH laser ridge structure 1545 such that the effective alignment of the vertical projection of the optical axis of the ridge structure 1545 and the planar waveguide 1544 can be formed over a range of available spacing between the lateral alignment aids 1537.

The potential range of movement, in the embodiment described in FIGS. 15A(i)-15A(iii) is limited in the “+x” direction, the “−x” direction, and the “+y” direction by the lateral alignment aids 1537 on the embodiment of the BH laser die 1500 and the complementary alignment aids 1535 on the interposer 1501. In other embodiments, as described herein, lateral movement can be constrained in the “+x” direction, the “−x” direction, the “+y” direction, and the “−y” direction as referenced by the coordinate system superimposed on the drawings.

FIG. 15B(i) shows an exploded cross section drawing of an assembly 1502 that includes an embodiment of a BH laser die 1500 having multiple vertical alignment aids 1536 and a single cavity-type lateral alignment aid 1537. BH laser die 1500 is positioned on an interposer 1501 having complementary vertical alignment aids 1534 and having a complementary pillar-type lateral alignment aid 1535. BH laser die 1500 is formed on substrate 1560 using, for example, a process described in the flowchart in FIG. 3. The vertical alignment aids 1536 on the BH laser die 1500 are formed having horizontal surfaces 1526 that, in the assembly 1502, form a contact with a horizontal surface 1525 on complementary vertical alignment aid 1534 on interposer 1501.

The lateral alignment aid 1537 in the embodiment of the BH laser die 1500 shown in FIG. 15B(i) is a cavity-type lateral alignment aid having a cavity 1527. The cavity-type lateral alignment aid 1537 on the BH laser die 1500 is formed having vertical surfaces 1528 that, in the assembly 1502, provide one or more lateral constraints to restrict the range of movement in the lateral direction during one or more of an assembly or alignment procedure. Movement is restricted in the lateral direction during assembly or alignment when a contact is formed between one or more vertical surfaces 1528 on one or more lateral alignment features 1537 on the BH laser die 1500 and one or more vertical surfaces 1529 on one or more complementary lateral alignment feature 1535 on the interposer 1501. BH laser pedestal 1546 is shown with ridge structure 1545. The lateral projection 1508a of the optical axis of the interposer 1501, within the planar waveguide layer 1505, is shown. Lateral projection 1508b of the optical axis of the BH laser die 1500 is also shown.

FIG. 15B(ii) shows the unexploded cross section drawing of the PIC assembly 1502 of FIG. 15B(i) that includes an embodiment of a BH laser die 1500 and an interposer 1501. The cross section is Section A-A′ from FIG. 15B(iii). FIG. 15B(iii) shows a top view of the BH laser die 1500 and interposer 1501. The lateral projections 1508a and 1508b of the optical axes of BH laser die 1500 and interposer 1501, respectively, are shown in the assembly cross section drawing in FIG. 15B(ii) in alignment to form aligned optical axis 1508 as a result of one or more horizontal surfaces 1526 of the BH laser die 1500 being brought into contact with one or more horizontal surfaces 1525 of the interposer 1501. In the PIC assembly 1502 shown in FIG. 15B(ii), the vertical alignment features 1536 of the BH laser die 1500 have been positioned upon vertical alignment pillars 1534 within a recess 1548 formed in interposer 1501.

Alignment of the lateral projections of the optical axes to form the aligned optical axis 1508 of the PIC assembly 1502 forms an alignment of the active emission layer 1566 of the BH laser die 1500 with the planar waveguide layer 1505 of the interposer 1501. In the top view of the assembly shown in FIG. 15B(iii), a portion of BH laser die 1500 is shown in recess 1548 with solid lines depicting the features on the bottom side of the BH laser die 1500 and the dotted lines depicting the hidden features on the interposer 1501. FIGS. 15B(ii) and 15B(iii) also show BH laser pedestal 1546 and ridge structure 1545. In the top view of FIG. 15B(iii), the front facet 1563 of the BH laser die 1500 is shown in alignment with facet 1542 of a planar waveguide 1544 formed in the planar waveguide layer 1505 of the interposer 1501.

The cavity-type lateral alignment aids 1537 on the BH laser die 1500 having vertical surfaces 1528 are shown positioned over a pillar-type complementary lateral alignment aid 1535 on interposer 1501 that, in the assembly 1502, provides a lateral constraint for movement in one or more lateral directions. Movement is restricted during an assembly or an alignment process, for example, when a contact is formed between one or more vertical surfaces 1528 on one or more lateral alignment features 1537 on the BH laser die 1500 and one or more vertical surfaces 1529 on one or more complementary lateral alignment features 1535 on the interposer 1501. Protrusion 1523 on the BH laser die 1500 provides overlap of the vertical surface 1528 with that of the vertical surface 1529 on interposer 1501 in the assembly 1502. The protrusion 1523, in the embodiment, is equal to, or approximately equal to, the distance between the first and second etch stop layers in the BH laser structure 1500 as described herein.

The aligned vertical projection of the optical axis 1509 of the assembly 1502 is shown in the top view of FIG. 15B(iii). Alignment of the vertical projection of the optical axis 1509 of the assembly 1502 is facilitated in part by the restriction in lateral movement provided by the side surface 1528 of the lateral alignment aid 1535 of the BH laser die 1500 forming a contact with the side surface 1529 of the lateral alignment feature 1535 of the interposer 1501. The lateral alignment aids 1535, 1537 can be formed in a variety of shapes that facilitate the restriction in lateral movement and can vary in quantity. The embodiment of the BH laser die 1500 in FIGS. 15B(i)-15B(iii) shows a single cavity-type alignment feature 1537 on the BH laser die 1500 with a top-down shape as shown in the top view of FIG. 15C(iii). In other embodiments, more than one cavity-type lateral alignment feature 1537 may be provided. And in yet other embodiments, cavity-type alignment features in other shapes can be used. In the PIC assembly 1502, contact need not be formed between the sides 1528,1529 of the lateral alignment aids 1537,1535, respectively, for the movement of the die 1500 to be constrained in a lateral direction on the interposer 1501. The lateral alignment features, for example, may not make contact but rather limit the movement in the event that the side 1528 of the alignment feature 1537 on the BH laser die 1500 form a contact with side 1529 of the alignment feature 1535 on the interposer 1501 during an assembly or alignment process. The potential range of movement, in the embodiment described in FIGS. 15B(i)-15B(iii) is limited in the “+x” direction, the “−x” direction, the “+y” direction, and the “−y” direction by the cavity-type lateral alignment aids 1537 on the embodiment of the BH laser die 1500 in combination with the complementary pillar-type alignment aids 1535 on the interposer 1501.

In other example embodiments, one or more of the surfaces 1528 and one or more of the walls of the cavity-type alignment aids 1537 supporting a surface 1528 can be eliminated from the cavity-type alignment feature as shown and remain within the scope of embodiments. In another embodiment, for example, a U-shaped alignment structure 1537 may be formed such that the movement in the “+y” direction is not limited by the open end of the U-shaped lateral alignment aid 1537 but rather by the wall of the cavity 1548.

FIG. 15C(i) shows an exploded cross section drawing of an assembly 1502 that includes an embodiment of a BH laser die 1500 having multiple vertical alignment aids 1536 and multiple cavity-type lateral alignment aids 1537. BH laser die 1500 is positioned on an interposer 1501 having complementary vertical alignment aids 1534 and having a complementary pillar-type lateral alignment aid 1535. BH laser die 1500 is formed on substrate 1560 using, for example, a process described in the flowchart in FIG. 3. The vertical alignment aids 1536 on the BH laser die 1500 are formed having horizontal surfaces 1526 that, in the assembly 1502, form a contact with a horizontal surface 1525 on complementary vertical alignment aid 1534 on interposer 1501.

The lateral alignment aids 1537 on the embodiment of the BH laser die 1500 shown in FIG. 15C are cavity-type lateral alignment aids having cavities 1527. The lateral alignment aids 1537 on the BH laser die 1500 are formed having vertical surfaces 1528 that, in the assembly 1502, provide one or more lateral constraints to restrict the range of movement in the lateral direction during one or more of an assembly or alignment procedure. Movement is restricted in the lateral direction during assembly or alignment when a contact is formed between one or more vertical surfaces 1528 on one or more lateral alignment features 1537 on the BH laser die 1500 and one or more vertical surfaces 1529 on one or more complementary lateral alignment feature 1535 on the interposer 1501. BH laser pedestal 1546 is shown with ridge structure 1545. The lateral projection 1508a of the optical axis of the interposer 1501, within the planar waveguide layer 1505, is shown. The lateral projection 1508b of the optical axis of the BH laser die 1500 is also shown.

FIG. 15C(ii) shows the unexploded cross section drawing of the PIC assembly 1502 of FIG. 15C(i) that includes an embodiment of a BH laser die 1500 and an interposer 1501. The cross section is Section A-A′ from FIG. 15C(iii). FIG. 15C(iii) shows a top view of the BH laser die 1500 and interposer 1501. The lateral projections 1508a and 1508b of the optical axes of BH laser die 1500 and interposer 1501, respectively, are shown in the assembly cross section drawing in FIG. 15C(ii) in alignment to form aligned optical axis 1508 as a result of one or more horizontal surfaces 1526 of the BH laser die 1500 being brought into contact with one or more horizontal surfaces 1525 of the interposer 1501. In the PIC assembly 1502 shown in FIG. 15C(ii), the vertical alignment features 1536 of the BH laser die 1500 have been positioned upon vertical alignment pillars 1534 within a recess 1548 formed in interposer 1501.

Alignment of the lateral projections of the optical axes to form the aligned optical axis 1508 of the PIC assembly 1502 forms the alignment of the active emission layer 1566 of the BH laser die 1500 with the planar waveguide layer 1505 of the interposer 1501. In the top view of the assembly shown in FIG. 15C(iii), a portion of BH laser die 1500 is shown in recess 1548 with solid lines depicting the features on the bottom side of the BH laser die 1500 and the dotted lines depicting the hidden features on the interposer 1501. FIGS. 15C(ii) and 15C(iii) also show BH laser pedestal 1546 and ridge structure 1545. In the top view of FIG. 15C(iii), the front facet 1563 of the BH laser die 1500 is shown in alignment with facet 1542 of a planar waveguide 1544 formed in the planar waveguide layer 1505 of the interposer 1501.

The cavity-type lateral alignment aids 1537 on the BH laser die 1500 having vertical surfaces 1528 are shown positioned over pillar-type complementary lateral alignment aids 1535 on interposer 1501 that, in the assembly 1502, provide a lateral constraint for movement in one or more lateral directions. Movement is restricted during an assembly or an alignment process, for example, when a contact is formed between one or more vertical surfaces 1528 on one or more lateral alignment features 1537 on the BH laser die 1500 and one or more vertical surfaces 1529 on one or more complementary lateral alignment features 1535 on the interposer 1501. Protrusion 1523 on the BH laser die 1500 provides overlap of the vertical surface 1528 with that of the vertical surface 1529 on interposer 1501 in the assembly 1502. The protrusion 1523, in the embodiment, is equal to, or approximately equal to, the distance between the first and second etch stop layers in the BH laser structure 1500 as described herein.

The aligned lateral projections of the optical axis 1509 of the assembly 1502 is shown in the top view of FIG. 15C(iii). Alignment of the lateral projections of the optical axis 1509 of the assembly 1502 is facilitated in part by the restriction in lateral movement provided by the side surface 1528 of the lateral alignment aid 1535 of the BH laser die 1500 forming a contact with the side surface 1529 of the lateral alignment feature 1535 of the interposer 1501. The lateral alignment aids 1535, 1537 can be formed in a variety of shapes that facilitate the restriction in lateral movement and can vary in quantity. The embodiment of the BH laser die 1500 in FIGS. 15C(i)-15C(iii) shows two cavity-type alignment features 1537 on the BH laser die 1500 with a top-down shape as shown in the top view of FIG. 15C(iii). In other embodiments, more than two cavity-type lateral alignment features 1537 may be provided. And in yet other embodiments, cavity-type alignment features in other shapes can be used. In the PIC assembly 1502, contact need not be formed between the sides 1528,1529 of the lateral alignment aids 1537,1535, respectively, for the movement of the die 1500 to be constrained in a lateral direction on the interposer 1501. The lateral alignment features, for example, may not make contact but rather limit the movement in the event that the side 1528 of the alignment feature 1537 on the BH laser die 1500 form a contact with side 1529 of the alignment feature 1535 on the interposer 1501 during an assembly or alignment process. The potential range of movement, in the embodiment described in FIGS. 15C(i)-15C(iii) is limited in the “+x” direction, the “−x” direction, the “+y” direction, and the “−y” direction by the cavity-type lateral alignment aids 1537 on the embodiment of the BH laser die 1500 in combination with the complementary pillar-type alignment aids 1535 on the interposer 1501.

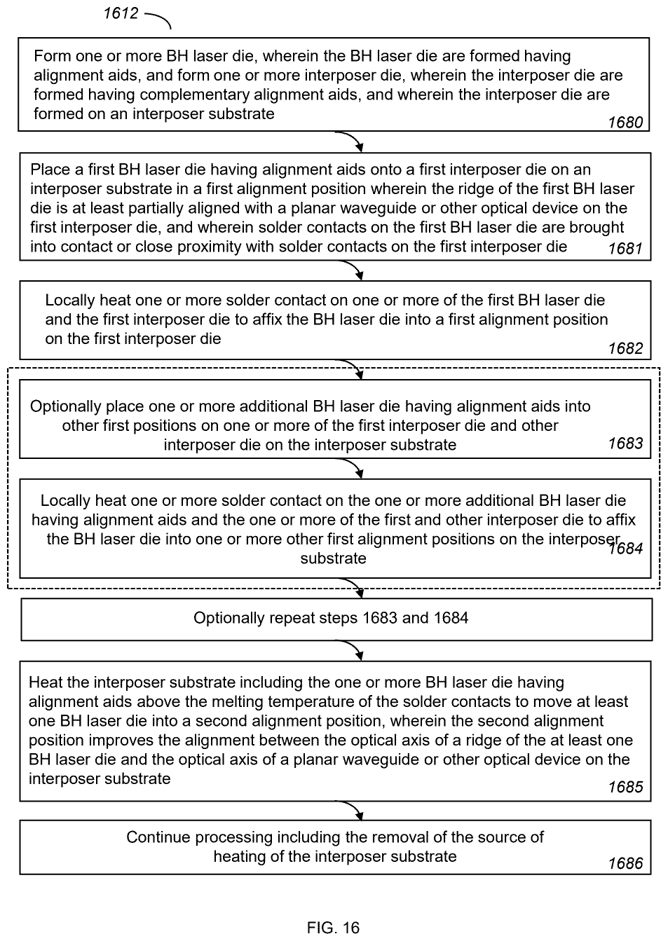

FIG. 16 shows a flow chart of an embodiment for a method of forming an assembly that includes one or more BH lasers with alignment aids and an interposer.

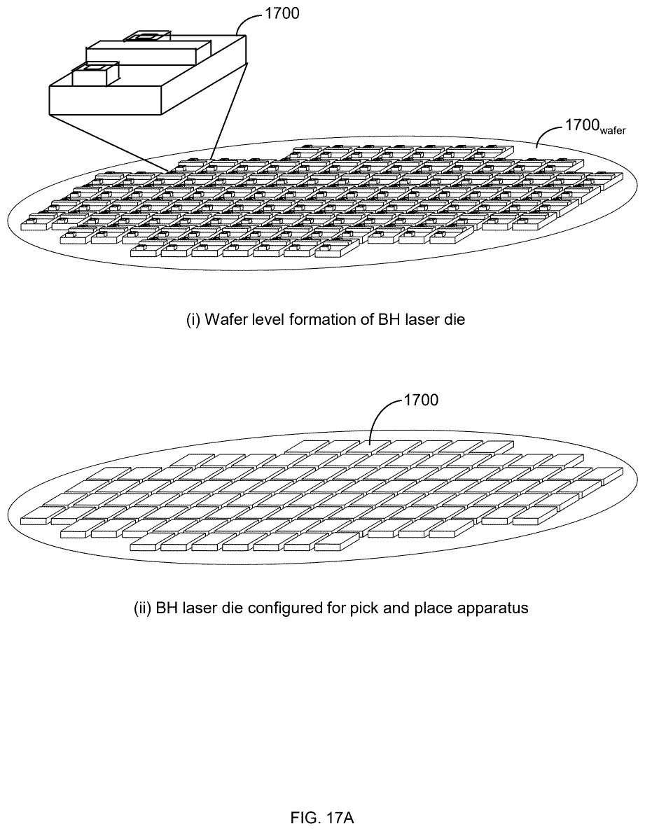

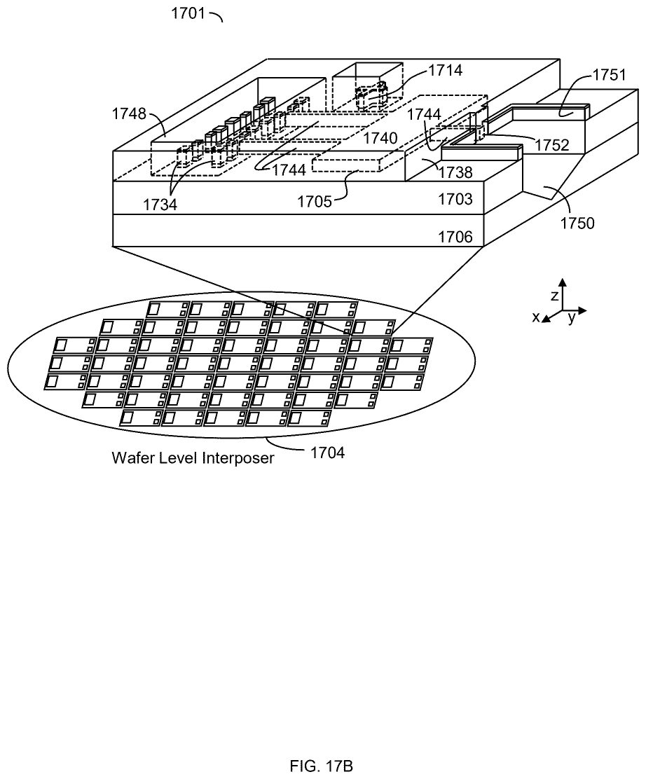

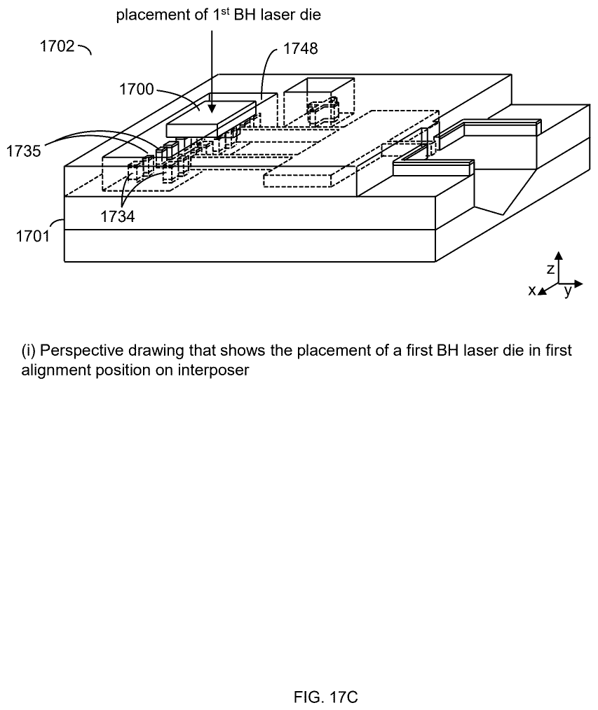

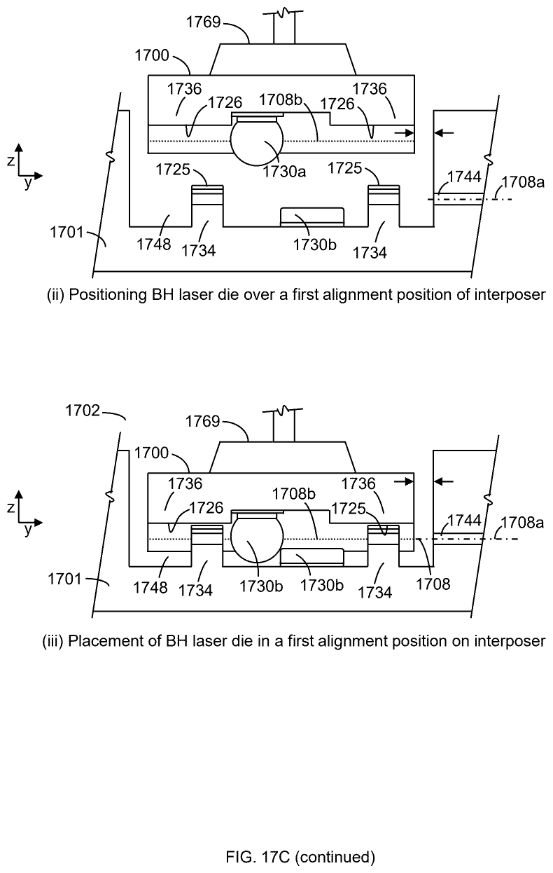

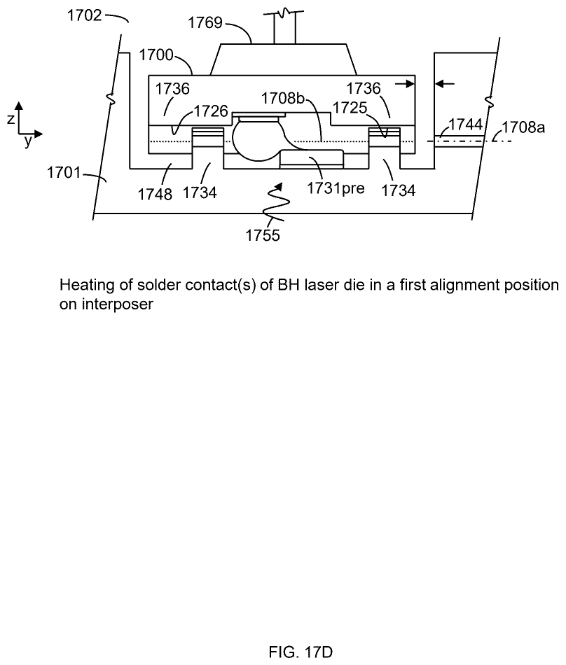

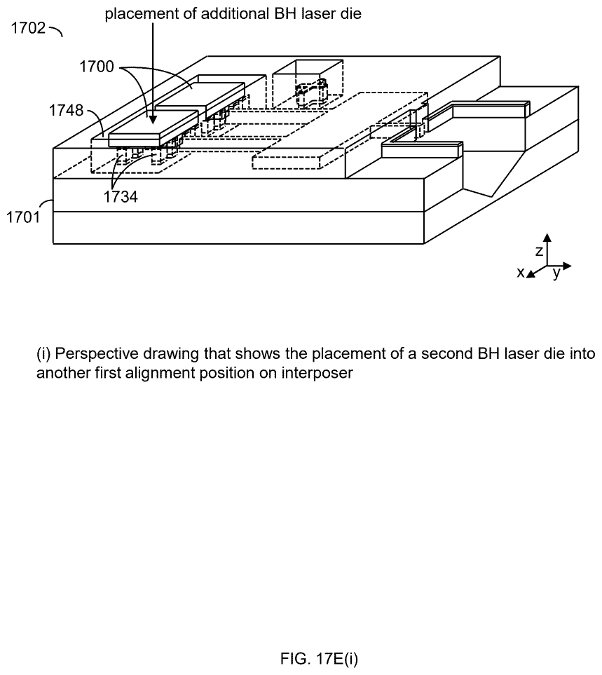

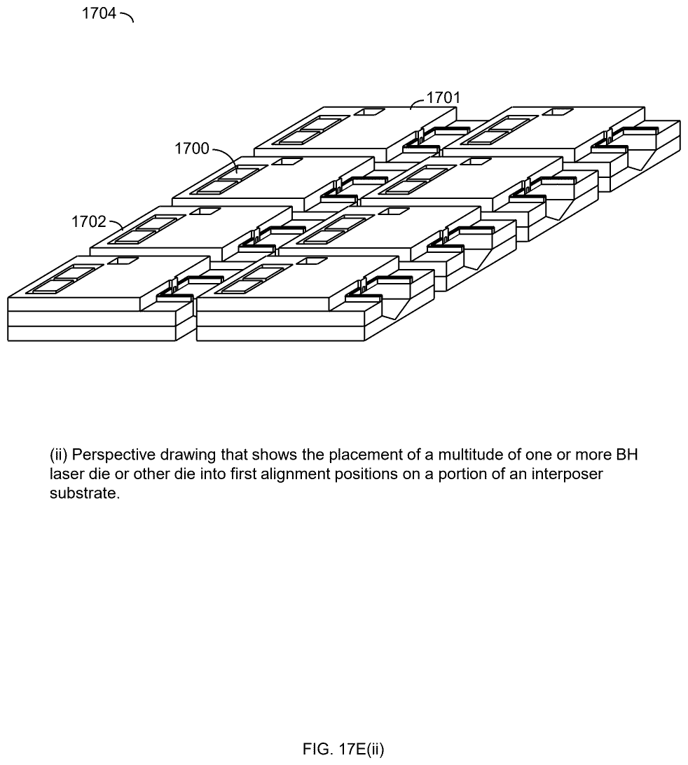

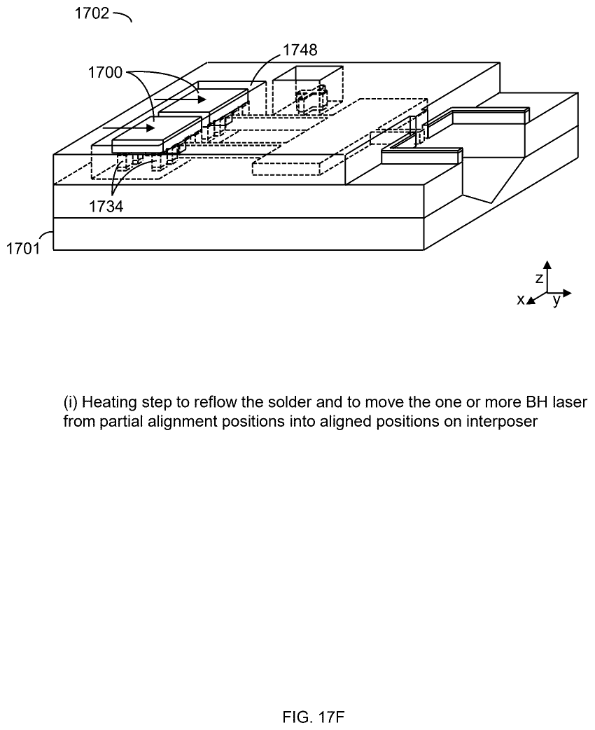

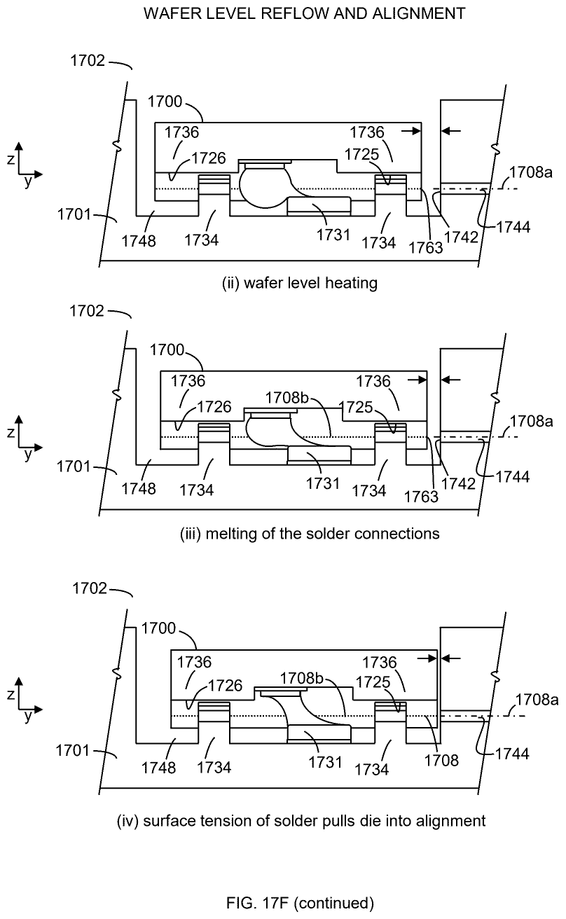

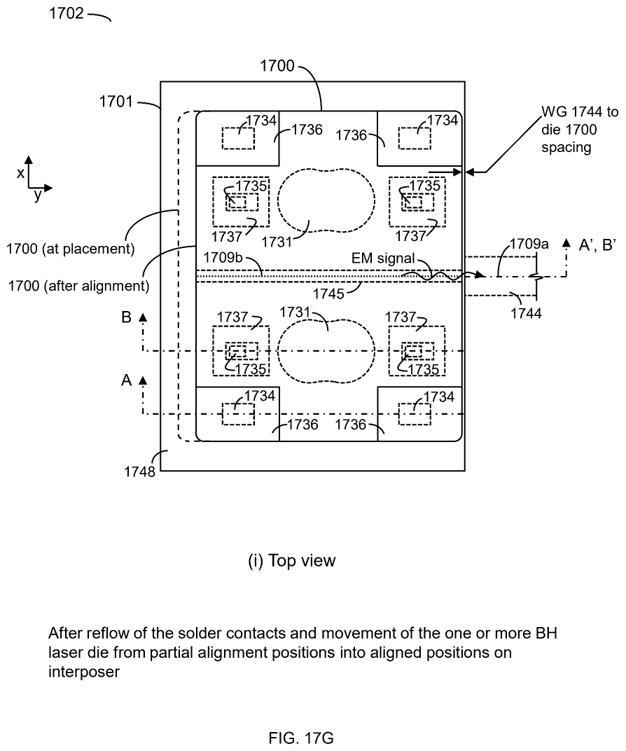

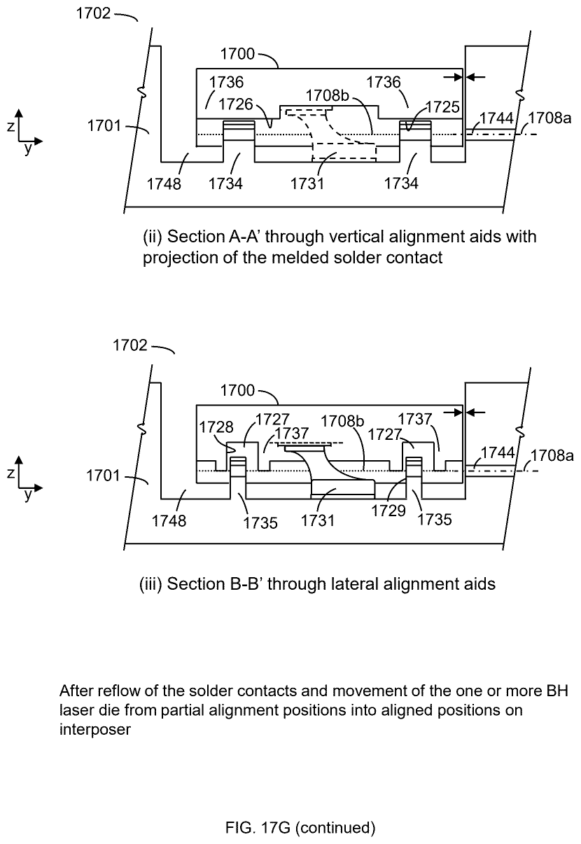

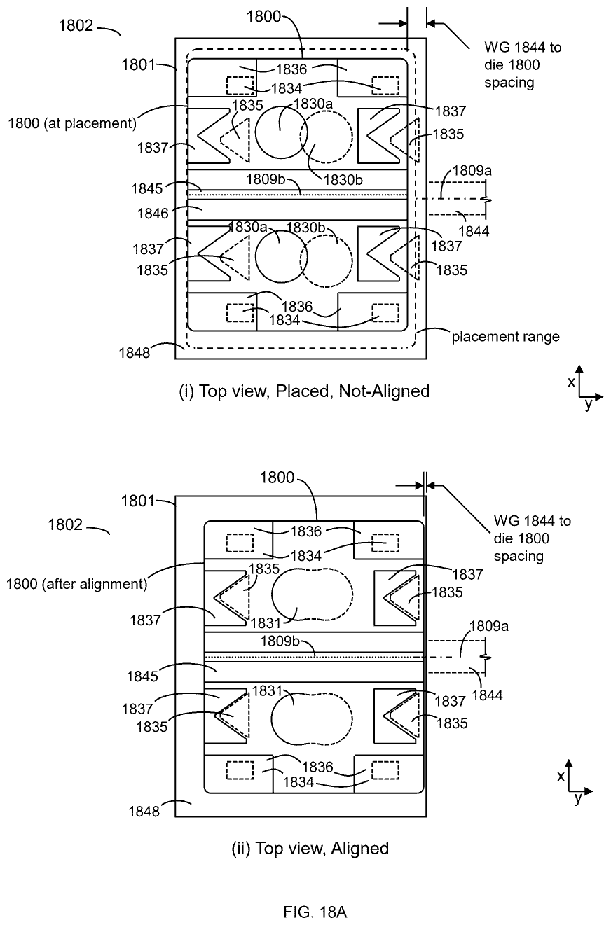

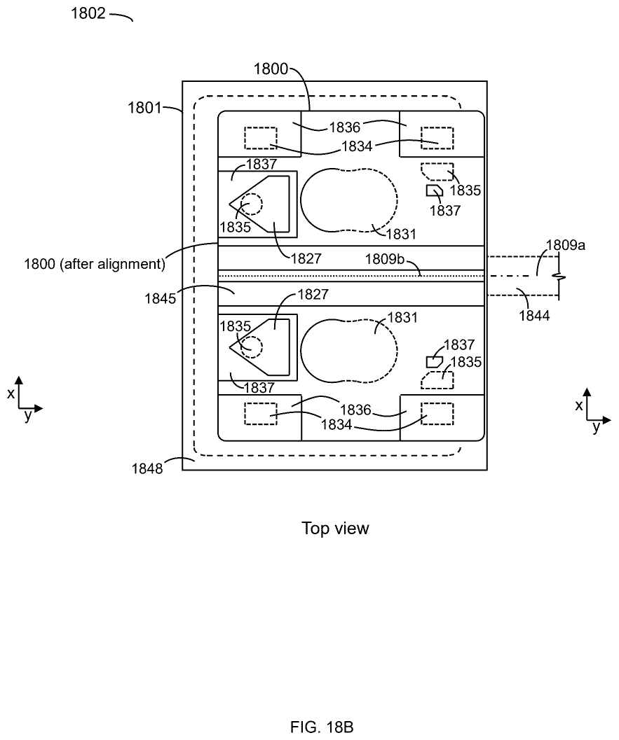

The method 1612 of FIG. 16 is described in conjunction with FIGS. 17A-17F that show perspective and cross section schematic drawings for a number of steps in an embodiment of the method 1612 of forming an assembly that includes a BH laser having vertical and lateral alignment aids and an interposer having complementary vertical and lateral alignment aids.

Step 1680 of method 1612 is a forming step in which one or more BH laser die are formed with alignment aids and one or more interposer substrates are formed with complementary alignment aids. FIG. 17A(i) shows a perspective drawing of substrate 1700_{wafer} comprised of BH laser die 1700. Wafer level processing is used to form a multitude of BH laser die 1700 on substrate 1700_{wafer}. BH laser die 1700 are BH laser die formed having alignment aids using, for example, the method described in FIG. 3 and elsewhere herein. FIG. 17A shows a circular substrate, although other substrate shapes may also be used. In preferred embodiments, the die 1700 are singulated and positioned for pick-and-place apparatus that enables the use of automated equipment to pick individual die 1700 from the substrate 1700_{wafer} for placement onto the interposer. FIG. 17A(ii) shows a wafer with singulated BH laser die 1700 preferably positioned for use with pick-and-place apparatus. The BH laser die 1700 are positioned in FIG. 17A(ii) for “flip-chip” installation such that the vertical alignment aids on the BH laser die can form a contact with the vertical alignment aids on the interposer.

In forming Step 1680, one or more interposer substrates 1701 are also formed having alignment aids, wherein the alignment aids on the interposer are complementary to the alignment features on the BH laser die 1700. FIG. 17B shows a perspective drawing of substrate 1704 comprised of interposer die 1701. Interposer die 1701 have mounting locations suitable for the mounting of the BH laser die 1700. The individual interposer die 1701 on interposer substrate 1704 may be one or more of singulated, partially singulated, or unsingulated. FIG. 17B shows a circular substrate, although other substrate shapes may also be used.

Step 1681 of method 1612 is a placement step in which a first BH laser die with alignment aids is placed onto an interposer substrate in a first alignment position to at least partially align the ridge of the first BH laser die with a planar waveguide or other optical device on the interposer, wherein solder contacts on the first BH laser die are brought into contact or close proximity with solder contacts on the interposer such that upon localized heating of the solder, one or more melded contacts can be formed between the solder or metal contact on the BH laser die and the solder or metal contact on the interposer to affix the BH laser die 1700 into a position on the interposer 1701. FIG. 17C(i) shows a perspective drawing of an interposer substrate 1701 with cavity 1748 on which a BH laser die 1700 has been placed as indicated by the downward pointing arrow with the label, “placement of 1^{st} BH laser die”. Cavity 1748 on the interposer includes vertical alignment aids 1734 and lateral alignment aids 1735.

Prior to the formation of contact between the vertical alignment aids of the BH laser die 1700 with the vertical alignment aids on the interposer 1701 in Placement Step 1681, the die 1700 is positioned over the interposer cavity 1748 as shown in the cross section schematic drawing in FIG. 17C(ii). FIG. 17C(ii) shows a BH laser die 1700 in a placement position over a cavity 1748 and held in position over the cavity 1748 using a pick-and-place apparatus 1769. Fiducials on the BH laser die 1700 and the interposer die (as described herein) facilitate accurate positioning of the BH laser die 1700 over the cavity 1748. As the BH laser die 1700 is brought into a pre-placement position over the cavity 1748, horizontal surfaces 1726 of the vertical alignment features 1736 on the BH laser die 1700 are positioned over horizontal surfaces 1725 of vertical alignment features 1734 on the interposer 1701. Solder contacts 1730a on the BH laser die 1700 are shown in FIG. 17C(ii) in position, in part, over contacts 1730b on the interposer 1701. Unaligned lateral projections of the optical axes of the BH laser die 1700 and a planar waveguide 1744 on the interposer 1701 are shown in FIG. 17C(ii). The opposing arrows in the figure show a gap between the output facet of the BH laser die and the facet of the planar waveguide 1744 on the interposer 1701.

In the embodiment in FIG. 17C(ii), a ball of solder is shown on the electrical contact 1730a on the BH laser die 1700. In other embodiments, the electrical contact 1730a BH laser die may not include a layer of solder. In some embodiments, solder may be included on the electrical contacts 1730a on the BH laser die 1700 and on the electrical contacts 1730b on the interposer 1701. And in yet other embodiments, solder may be included on the electrical contacts 1730b on the interposer.

FIG. 17C(iii) shows a cross section schematic drawing of a BH laser die 1700 after formation of physical contact in placement step 1681 between the vertical alignment aids 1736 of the BH laser die 1700 and the vertical alignment aids 1734 on the interposer 1701. Alternatively, the initial physical contact may be formed between the solder contact 1730a and contact 1730b on the interposer 1701 until subsequent processing has been completed to form the physical contact between the vertical alignment aids 1736 on the BH laser die 1700 and vertical alignment aids 1734 on the interposer 1701. In the embodiment shown, physical contacts are shown formed between a portion of a solder contact 1730a on the BH laser die and contact 1730b on the interposer 1701 and coincidently between the horizontal surfaces 1726 of the vertical alignment aids 1736 on the BH laser die 1700 and the horizontal surfaces 1725 of the vertical alignment aids 1735 on the interposer 1701, although in practice, contact may be limited initially to either the contacts 1730a,1730b or the horizontal surfaces 1726,1725 of the BH laser die 1700 and interposer 1701, respectively, until further processing is performed. In embodiments in which the contacts 1730a,1730b do not form an initial contact after the placement step 1681, subsequent processing can be required to form a solder contact with the contact 1730b of the interposer 1701. In some embodiments, for example, the contacts 1730a, 1730b may be positioned in close proximity, such that upon heating, the process of the melting of the solder forms the electrical connection between the two contacts 1730a,1730b.

FIGS. 17C(ii) and 17C(iii) show the lateral projections of the optical axis 1708b of the ridge of the BH laser die 1700 and the optical axis 1708a of a planar waveguide 1744 in the interposer 1701. As a BH laser die 1700 is placed onto the interposer 1701 into a first alignment position, the optical axes of the two devices are brought into either a full or a partial alignment. In embodiments in which the horizontal surfaces 1726 on the vertical alignment features 1736 of the BH laser die 1700 are free to form a physical contact with the horizontal surfaces 1725 on the vertical alignment features 1735 of the interposer 1701, the lateral projections 1708a, 1708b can be are brought into alignment. In embodiments in which the horizontal surfaces 1726 on the vertical alignment features 1736 of the BH laser die 1700 are not free to form a contact with the horizontal surfaces 1725 on the vertical alignment features 1735 of the interposer 1701, due for example to interference between the contacts 1730a,1730b, the lateral projections 1708a, 1708b may be limited to a partial alignment in placement step 1681.

An objective of the use of the lateral and vertical alignment aids 1736,1737, respectively, on the BH laser die 1700 and on the lateral and vertical alignment aids 1735, 1734, respectively, on the interposer, is to enable the alignment of both the lateral and vertical projections 1708, 1709, respectively, of the optical axes to be brought into alignment to facilitate coupling between the optical output of the BH laser die 1700 and the planar waveguide 1744, or other optical device, on the interposer 1701.

Fiducial marks facilitate the placement of BH laser die 1700 onto the interposer. The formation of fiducials that can provide accuracy in the positioning and placement steps are advantageous over simple alignment markings on these devices. Accuracy in positioning and placement can lead to significant reductions in the sizes of the BH laser die 1700 and the interposers 1701. In embodiments, the fiducials 1714 in the planar waveguide layer of the interposer 1701 are formed from a single mask layer in alignment with the other features formed from the planar waveguide layer that include the alignment features 1734,1735 and the planar waveguides 1744, among other features as described herein. Similarly, in embodiments described herein for the BH laser die 1700, the fiducials on the BH laser die are formed from the same mask layer used in the formation of the lateral alignment aid 1737 and the BH laser ridge structure 1745.

For the BH laser die, the use of a same mask layer and subsequent patterning process can reduce the dimensional differences that may be observed in comparison to processes in which multiple masking processes are used and in comparison to processes in which the same mask layer is not used to form the emission layer in the ridge structure of the laser and the vertical surfaces 1728 of the lateral alignment features 1735 of the laser. Use of a same masking process can thus facilitate reductions in the required assembly clearances leading to potential reductions in the overall size of one or more of the BH laser die 1700 and the interposer die 1701. For a BH laser in which the ridge, lateral alignment features, and the fiducials are not formed using a same masking layer, for example, a cavity in the interposer may be required that is considerably larger than the die size of the laser to provide the necessary clearance to prevent the die from undesirable contact with the interposer 1701. Conversely, in embodiments in which the ridge, lateral alignment features, and fiducials are formed using a same masking layer, the necessary clearances between mechanical features on embodiments of the BH laser die and mechanical features on the interposer can be minimized.

In the embodiments described herein, a method of fabrication is described for which the lateral alignment aids 1737 and the ridge structure on the BH laser die 1700 are patterned using a same mask layer. The use of the same hard mask to form these features enables a reduction in the clearances required to reliably produce assemblies that include the embodiments of the BH lasers that are formed using a same masking layer to pattern the ridge and lateral alignment features. The use of the lateral alignment features 1737 as fiducial marks on the BH laser die 1700 further facilitates the accurate positioning of the lateral alignment features 1737 onto lateral alignment features 1735 on the interposer 1701.

For the interposer, use of the same mask layer to pattern the planar waveguides 1744 formed from the planar waveguide layer 1744 of the interposer 1701 and the lateral alignment features 1735 of the interposer 1710, among the other features described herein, can also facilitate reductions in the required assembly clearances enabling the use of interposer die that are smaller in area than those that use other fabrication methods. As described herein in FIG. 14A, a same mask layer 1416 is used to pattern the planar waveguide layer 1405 to form all or a portion of the planar waveguides 1444, the fiducials 1414, the vertical alignment features, and the lateral alignment features, among other features.

Step 1682 of method 1612 is a heating step in which one or more of the electrical contacts on one or more of the BH laser die and on the interposer are heated, wherein the heating affixes the first BH laser die into a first or partial alignment position on the interposer. FIG. 17D shows a cross section schematic drawing of a BH laser die 1700 in a placement position within cavity 1748 and held in position using a pick-and-place apparatus 1769. Localized heating 1755 of one or more contacts 1730a, 1730b is facilitated, for example, by emission from a laser or other radiation source. In an embodiment, a laser positioned below the interposer 1701 provides energy through the interposer substrate to induce heating of the one or more of the contacts 1730a, 1730b. Localized heating 1755 of step 1682 results in the formation of one or more partially bridged contacts 1731pre. The formation of one or more partially bridged contacts 1731pre affixes the BH laser die 1700 into a first alignment position on the interposer 1701. In some embodiments, the BH laser die 1700 is held in place by the pick and place apparatus 1769 during all or a portion of the heating step 1682. In other embodiments, the BH laser die 1700 is not held in place by the pick and place apparatus 1769 during all or a portion of the heating step 1682. In some embodiments, more than one die 1700 can be placed and heated coincidently during the heating step 1682. In embodiments, the localized heating step is a short duration step of approximately one second in duration, although durations of longer than one second and durations of shorter than one second may also be used.

Following the heating step 1682, the pick and place apparatus 1769 is decoupled from the BH laser die 1700. In some embodiments, the melted solder contact may be permitted to resolidify after formation prior to removal of the pick and place apparatus 1769. In other embodiments, the melted solder contacts may remain in a liquid or semi-liquid state as the pick and place apparatus 1769 is decoupled from the BH laser die 1700 and allowed to cool.

Step 1683 and step 1684 of method 1612 are optional placement steps and heating steps, respectively, in which one or more additional BH laser die 1700 are placed into first alignment positions on an interposer die and affixed into these first alignment positions on the interposer die 1701 after placement. FIG. 17E(i) shows a perspective drawing in which a second BH laser die 1700 is placed into another first alignment position on a same interposer die 1701. Following the placement, the contacts are subjected to localized heating to affix the BH laser die 1700 into the first alignment positions on the interposer die 1701. In the embodiment in FIG. 17E(i), two locations are shown on the interposer 1701 for mounting BH laser die 1700. In other embodiments, one location may be provided. And in yet other embodiments, more than two locations for the mounting of the BH laser die 1700 may be provided.

In addition to the mounting of one or more BH laser die 1700 onto a single interposer die 1701 on the interposer substrate 1704, additional BH laser die 1700 can be mounted onto other interposer die 1701 on the interposer substrate 1704. In preferred embodiments, all of the BH laser die 1700 to be mounted on the interposer substrate 1704 are mounted and affixed into position prior to commencement to step 1685. In some embodiments, locations for die other than BH laser die 1700 may be provided on the interposer die 1701, and in these embodiments, locations may be included for laser die, detector die, modulator die, among many other types of mountable die. In preferred embodiments in which locations are provided for other mountable die on the interposer die 1701, the other die may too be mounted in step 1683 and subjected to the localized heating in step 1684 to affix these die into first alignment positions on the interposer die 1701 prior to commencement to step 1685.

FIG. 17E(ii) shows a number of interposer die 1701 from a portion of interposer substrate 1704 onto which a number of BH laser die 1700 have been mounted. Multiple BH laser die 1700 are shown mounted on each of the interposer die 1701. The BH laser die 1700 in the embodiment shown in combination with the interposer 1701 form PIC's 1702.

In other embodiments, locations for die other than BH laser die may be provided. In other embodiments, for example, locations for other types of laser die, detector die, modulator die, among many other types of mountable die with or without alignment aids may be provided. In some preferred embodiments in which other die in addition to the BH laser die may be mounted onto the interposer, other die may be mounted into first alignment positions prior to commencement to Step 1685. Alternatively, in some embodiments in which other die in addition to the BH laser die 1700 may be mounted onto the interposer substrate 1704, the BH laser die 1700 may be subjected to step 1685 prior to the mounting of the non-BH laser die. And in yet other embodiments, some non-BH laser die may be mounted into first alignment positions on the interposer substrate prior to commencement to step 1685 and subjected to step 1685 coincident with the BH laser die 1700, and other non-BH laser die 1700 may be mounted after subjecting the mounted BH laser die 1700 to step 1685.

Step 1685 of method 1612 is a heating step in which the interposer substrate that includes the one or more BH laser die 1700 is heated above the melting temperature of the solder used in the electrical contacts 1730a,1730b to move at least one BH laser die into a second alignment position, wherein the movement into the second alignment position improves the alignment between the optical output from at least one BH laser die and a planar waveguide or other optical device on the interposer. In embodiments, the facet of the laser die 1700 is moved closer to the facet of the planar waveguide 1744 on the interposer 1701. FIG. 17F(i) shows a perspective drawing of two BH laser die 1700 mounted in cavity 1748 on interposer 1701. Upon exposure of the substrate 1704 to wafer level heating above the melting point of the partially bridged contact 1731pre, the one or more mounted BH laser die 1700 move to a second alignment position on the interposer die 1701 as described in FIGS. 17F(ii)-17F(iv). Resolidification of the solder contact will occur upon one or more of the removal of the substrate 1704 from the heating source, removal of the heating source to the substrate 1704, and reduction in temperature of the heating source to form bridged contact 1731. Wafer level heating can be performed in a reflow oven or other heating apparatus. In preferred embodiments, a reflow oven is used in which the temperature of the interposer 1701 is raised gradually to prevent thermal shock to the assembly, among other potential benefits.

FIG. 17F(ii) shows a cross section drawing in which the interposer substrate 1704 is subjected to wafer level heating. Upon heating of the substrate 1704, the partially bridged solder contact 1731pre begin to soften and surface tension in the molten solder in contact with metal contacts on the interposer and on the BH laser begins to pull the metal contacts closer together. As the metal contacts are drawn closer, the spatial gap between the facets 1763,1742 of BH laser die 1700 and the waveguide 1744 on the interposer 1701, respectively are also drawn closer together. Initially, after placement, a gap is present between the facet 1763 of the BH laser die 1700 and the facet 1742 of the planar waveguide 1744 on the interposer 1701 in the embodiment shown. This gap is presented on the drawing in FIG. 17F(ii) between the two opposing arrows. FIG. 17F(iii) shows a narrowing of the gap between the facet 1742 and facet 1763 as the solder rises in temperature and the surface tension in the solder begins to pull the molten solder contact together resulting in the reduction in the gap between the facets 1742,1763. In FIG. 17F(iv), the gap between the facet 1742 of the planar waveguide 1744 on the interposer and the facet 1763 of the BH laser die 1700 has been minimized as the limit in lateral movement is reached. The lateral movement can be limited in embodiments, for example, by physical contact formed between one or more portions of the BH laser die 1700 and one or more portions of the interposer 1701. Physical contact that can limit the lateral movement can be formed, for example, between the lateral alignment aids 1737 on the BH laser die 1700 and alignment aids 1735 on the interposer 1701. Physical contact may also be formed between a portion of the facet 1742 and a portion of the facet 1763. Physical contact may also be formed, for example, between a portion of the substrate 1760 or other portion of the BH laser die 1700 and a wall of the cavity 1748 on the interposer 1701.

In some embodiments, multiple solder materials that have differing melting temperatures may be used in which one or more die 1700 are subjected to a first reflow step 1685 using a first solder contact material, and one or more additional die 1700 or other additional die, such as other laser die, detector die, modulator die, among many other types of mountable die, are mounted to the interposer 1701 using a solder contact material with a lower melting point than that used in the first reflow step. The additional die are subjected to local heating step 1682 and subsequently subjected to a second reflow step 1685 sufficient to form the solder contacts using the solder contact material with the lower melting point. Additional solders and solder melding temperatures can used to add yet additional die 1700 or other additional die such as other laser die, detector die, modulator die, among many other types of mountable die.

FIGS. 17G(i)-17G(iii) show additional views of an embodiment of a PIC assembly 1702 that includes BH laser die 1700 on an interposer 1701. In the top view of FIG. 17G(i), the bridged contact 1731 between the BH laser 1700 and the interposer 1701 are shown. In the embodiment, cavity-type lateral alignment features 1737 on the BH laser die 1700 are shown with complementary pillar-type lateral alignment features 1735 on the interposer 1701. In the embodiment shown in FIG. 17G(i), four lateral alignment features are provided on the BH laser die 1700 with four complementary lateral alignment features on the interposer 1701. In other embodiments, other quantities of lateral alignment features may be provided.

Also shown in the embodiment in FIG. 17G(i) are vertical alignment aids 1736 on the BH laser die 1700 with complementary vertical alignment aids 1734 on the interposer die 1701. In the embodiment shown in FIG. 17G(i), four vertical alignment features are provided on the BH laser die 1700 with four complementary vertical alignment features on the interposer 1701. In other embodiments, other quantities of vertical alignment features may be provided.

In the top view of FIG. 17G(i), the drawing shows a partial trace with a dotted line that shows an initial placement position for the BH laser die 1700 onto the interposer die 1701. The actual position of the die 1700 is shown after a reflow step such as the heating step 1685 described herein. FIG. 17G(i) also shows ridge structure 1745 of the BH laser within which the electromagnetic signal is generated. The electromagnetic signal is shown propagating from the ridge structure 1745 of the BH laser to a portion of a planar waveguide 1744 on the interposer die 1701. In the top view, the vertical projection 1709b of the optical axis of the BH laser die 1700 is shown in alignment with the vertical projection 1709a optical axis of the planar waveguide 1744 of the interposer 1701. In the embodiment shown, a planar waveguide 1744 is shown that is wider than the ridge 1745 of the BH laser. In preferred embodiments, the planar waveguide 1744 is made wider than the ridge 1745 to compensate for the spacing that is required for placement of the BH laser die 1700 onto the interposer 1701 and in particular the clearance required between the lateral alignment features 1737 on the BH laser die 1700 and the lateral alignment features 1735 on the interposer 1701.

FIG. 17G(ii) and FIG. 17G(iii) show Section A-A′ and Section B-B′ from the PIC assembly 1702 of FIG. 17G(i), respectively. In Section A-A′ of FIG. 17G(ii), the cross section drawing includes the vertical alignment aids 1734,1736 of the interposer 1701 and BH laser die 1700, respectively and in Section B-B′ of FIG. 17G(iii), the cross section drawing includes the lateral alignment aids 1735,1737 of the interposer 1701 and BH laser die 1700, respectively. The lateral projection 1708b of the optical axis of the BH laser die 1700 is shown in alignment with the lateral projection 1709a of the optical axis of the planar waveguide 1744 on the interposer 1701 that results from the formation of the contact between one or more horizontal surfaces 1726 of the vertical alignment aids 1736 on the BH laser die 1700 with the horizontal surfaces 1725 of the vertical alignment aids 1734 on the interposer 1701. FIG. 17G(ii) includes a projection of the bridged contact 1731, which is shown in the cross section of FIG. 17G(iii). The gap between the facets of the BH laser on the BH laser die 1700 and the facet of the planar waveguide 1744 on the interposer 1701 has been closed as the facets 1763,1742 are brought into close proximity (as indicated by the close positioning of the two arrows on the drawings in FIG. 17G) during one or more of an alignment and assembly process This closing of the gap resulted wholly or in part due to the bridging of the solder between contacts 1730a,1730b and the surface tension in the molten solder that acted to close the gap.

Section B-B′ of FIG. 17G(iii) also shows an embodiment of cavity-type lateral alignment features 1737 and complementary pillar-type alignment features 1734 on the interposer 1701. In embodiments, the cavity-type lateral alignment aids restrict the lateral movement of the BH laser die 1700 within the cavity 1748 during one or more of an assembly and an alignment process, in the “+x” and “−x” directions (as indicated on drawings throughout) as one or more contacts are formed between a side surface 1728 within cavity 1727 of the lateral alignment feature 1737 on the BH laser die 1700 and a side surface 1729 of the pillar-type alignment feature 1735 on the interposer 1701. In some embodiments, the cavity-type lateral alignment aids can also restrict the lateral movement of the BH laser 1700 within the cavity 1748 during one or more of an assembly and an alignment process, in the “+y” and “−y” directions (as indicated on drawings throughout) as one or more contacts are formed between a side surface 1728 within cavity 1727 of the lateral alignment feature 1737 on the BH laser die 1700 and a side surface 1729 of the pillar-type alignment feature 1735 on the interposer 1701.

Step 1686 of method 1612 is a continuation step in which the processing of the interposer and the full PIC assembly or partial PIC assembly formed on the interposer is continued.

The formation and use of nestable alignment aids in embodiments of BH lasers can further contribute to the alignment of the optical axes of the BH laser die with planar waveguides or other optical devices on an interposer. The alignment aids shown in the top view of FIG. 15A(iii), for example, constrain movement in the “+x” and “−x” directions (as indicated by the reference coordinate system) and restrict movement in the “+y” direction as the BH laser die is brought into alignment during an assembly or alignment step, for example. With embodiments having nestable alignment pillars, the alignment of the BH laser in the “+x” and “−x” directions can be greatly improved. Some example embodiments are provided in the following figures.

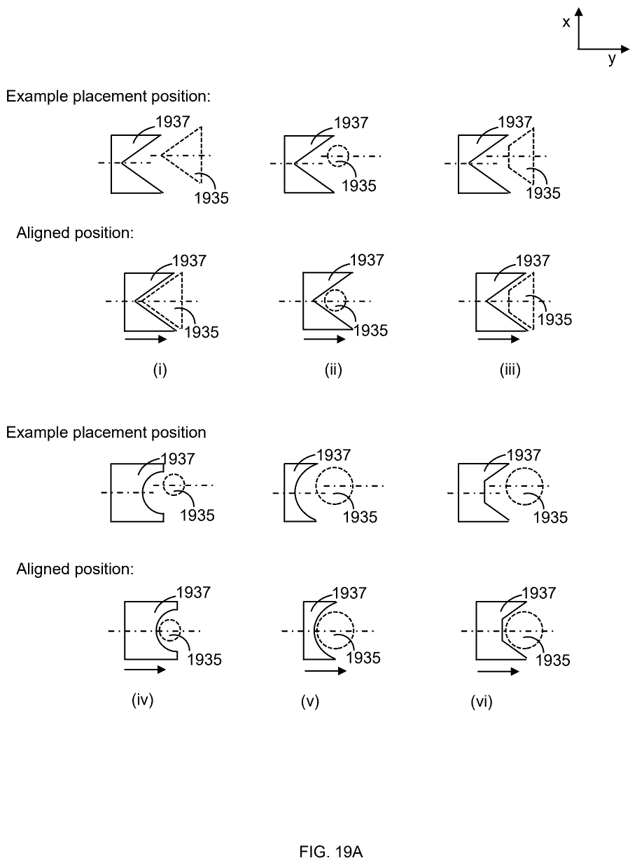

FIGS. 18A(i) and 18A(ii) show top views of an embodiment of a BH laser 1800 having nestable alignment aids 1837. BH laser 1800 is shown in assembly 1802 with interposer 1801.

FIG. 18A(i) shows a top view of an embodiment of a BH laser die 1800 positioned in cavity 1848 of interposer 1801 after an example placement step and prior to alignment. An example placement range for an example pick and place apparatus is shown in the dotted line labeled “placement range”. The “placement range” is an example of the range of placement positions that a typical pick and place apparatus might exhibit in the placement of the BH laser die 1800 into the interposer cavity 1848. The BH laser die 1800 is placed within the cavity 1848 with clearances around the die to prevent an unintentional collision between the die and cavity walls, for example. Alignment aids and laser pedestals for embodiments of the BH laser die are placed in the cavity 1848 with clearances that prevent unintentional collisions between the alignment aids, laser pedestals, and other features on the laser die with physical features on the interposer. Some advanced pick and place apparatus available in the semiconductor capital equipment market can position die onto substrates to within +/−0.3 microns positioning accuracy.

Precise positioning of the BH laser die onto the interposer, facilitated in part by the use of the same mask layer for the laser ridge, the alignment aids, and the fiducials on the BH laser die, and by the use of a same mask layer for the planar waveguides, alignment aids, and fiducials on an interposer as described herein, in addition to the positioning and placement accuracy provided by the pick and place apparatus, can further be aided by the use of nestable alignment aids on the BH laser die and interposer that are shaped to facilitate an additional source of alignment in the +x and −x directions.

FIG. 18A(i) shows an example of nestable pairs of alignment aids. Four lateral alignment aids 1837 are shown in FIG. 18A(i) that are each paired with a complementary lateral alignment aid 1835 on an interposer 1801. In the top view of FIG. 18A(i), an embodiment of a BH laser die is shown arbitrarily positioned within the “placement range” as defined by the pick and place apparatus. In the placement position shown, separations can be seen between the facets of the alignment aids 1837 in the die 1800 and the facets of the lateral alignment aids 1835 on the interposer 1801. Optical axis 1809b, within the ridge 1845 in laser pedestal 1846 of the laser die 1800, are shown out of alignment with the optical axis 1809a of the planar waveguide 1844 on the interposer 1801. The electrical contacts 1830a,1830b are shown prior to the heating and melting of the solder. The vertical alignment aids 1836 are shown in position over the vertical alignment aids 1834 on the interposer 1801. In the embodiment shown, with heating and the melting of the solder in one or more of the electrical contacts 1830a,1830b, the surface tension in the solder will act to align the electrical contact 1830a and the moveable BH laser die 1800 to which this contact 1830a is attached with the electrical contact 1830b of the interposer substrate 1801 below the die 1800.

FIG. 18A(ii) shows the BH laser die 1800 and interposer 1801 of the PIC assembly 1802 after an alignment step in which the solder has been raised above its melting temperature, and the BH laser die has moved into an aligned position on the interposer, guided by the nested alignment aids 1837 on the die 1800 and the interposer 1801. With the BH laser die moved into an aligned position, the optical axis 1809b of the BH laser die 1800 has moved into alignment with the optical axis 1809a of the planar waveguide 1844 on the interposer 1801. The alignment of the axes 1809a, 1809b has been facilitated in part in the embodiment shown in FIG. 18A(ii) by the nested triangular shapes, viewed as shown in the top view, As the surface tension in the melted solder acts to pull the electrical contact 1830a into alignment over the electrical contact 1830b on the interposer 1801, the open side of the v-shaped pillar 1837 on the BH laser die 1800 forms a contact with the complementary-shaped triangular pillar 1835 on the interposer 1801. Contacts formed between one or more of the four v-shaped pillars 1137 on the die 1800 with the triangle-shaped pillars 1835 on the interposer, guide the laser die 1800 and the optical axes 1809a, into alignment with the planar waveguide 1844 and its optical axis 1809b, respectively, on the interposer 1801. As the alignment aids 1837 on the die 1800 become fully, or substantially, nested with the alignment aids 1835 on the interposer 1801, the optical axes 1809a, 1809b become fully, or substantially, aligned.

The guidance during movement in an alignment step, facilitated by the nested v-shaped lateral alignment aids 1837 and the complementary triangle-shaped alignment aids 1835 on the interposer 1801, provides improved alignment of the BH laser die 1800 in the +x and −x directions as shown in the reference coordinate axes in FIG. 18A and in drawings throughout, in addition to a restriction in movement in the +y direction. In the embodiment shown in FIG. 18A, four pairs of complementary alignment aids 1837, 1835 are provided on the die 1800 and interposer 1801. In other embodiments other quantities of nested alignment aids 1837, 1835 can be used. In some embodiments, one, two, three, four, or more than four nested pairs of alignment aids may be used. In other embodiments, one, two, three, four, or more than four nested pairs of alignment aids may be combined with other alignment aids or pairs of alignments aids such as those described herein.

FIG. 18B shows yet another embodiment of a BH laser die 1800 having four alignment aids in which two cavity-type lateral alignment aids 1837 are paired with complementary pillar-type alignment aids 1835 on the interposer 1801, and two pillar-type alignment aids 1837 are paired with other complementary pillar-type alignment aids 1835 on the interposer 1801. FIG. 18B shows the BH laser 1800 after alignment in an aligned position on the interposer 1801. The circle-shaped pillar 1835 on the interposer 1801 is shown nested in the “V” of the V-shaped cavity on the laser die 1800 with the optical axis 1809b brought into alignment with the optical axis 1809a of the planar waveguide 1844 on the interposer 1801 after an alignment process. In embodiments in which a pillar-shaped alignment feature 1835 of the interposer 1801 is paired with a cavity-type alignment feature 1837 on the BH laser die 1800 that include a cavity 1827, the cavity structure 1837 can capture the pillar feature 1835 leading to reduction in the potential range of movement for the BH laser die during the heating process. The range of motion in cavity-type alignment structures is limited to the clearance between the interior walls of the cavity 1827 and the walls of the pillar-type alignment aid 1835 on the interposer 1801.

Cavity structures may also reduce the susceptibility for delamination in comparison to pillar-type structures particularly for features that are formed from layered structures. Some pillar-type-structures formed from a layered structure such as the epitaxial layers used in the formation of the BH laser structures, may be susceptible to delamination during an alignment process and the use of cavity-type features can reduce the likelihood of delamination.

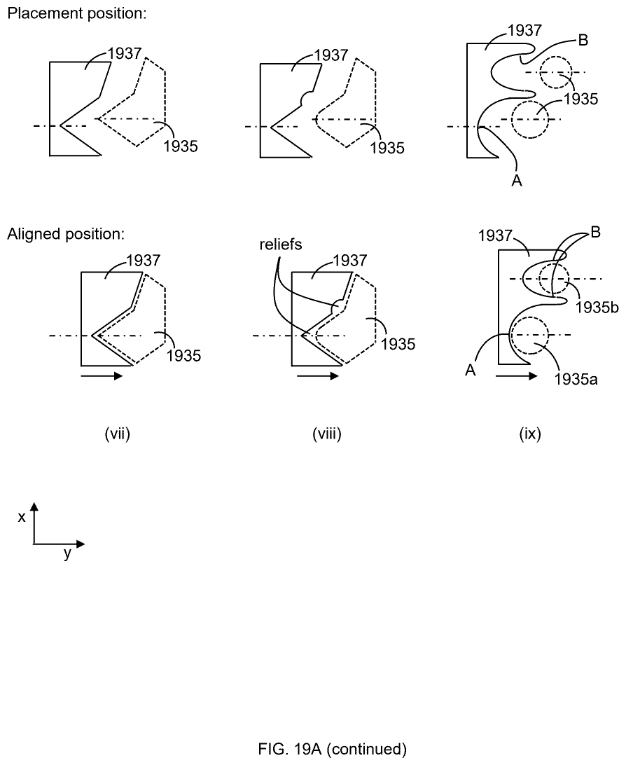

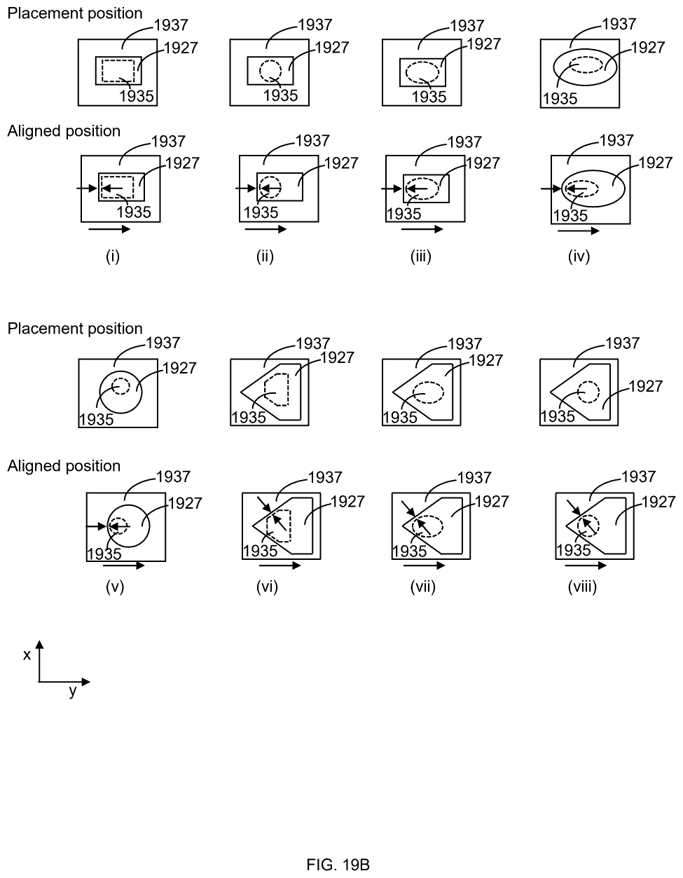

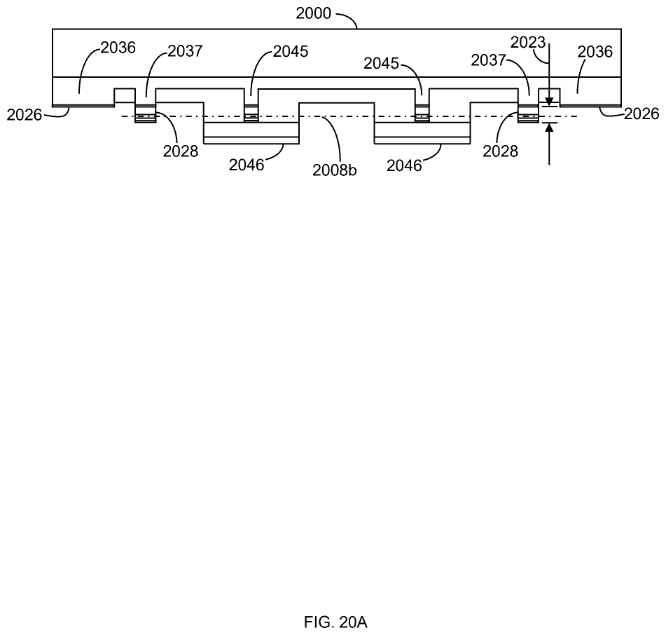

FIGS. 19A(i)-19A(ix) show additional examples of pillar-type alignment aids formed on embodiments of BH lasers with examples of complementary alignment aids that can be formed on interposers to which the embodiments can be combined to formed PIC assemblies. Each of the examples in FIGS. 19A(i)-19A(ix) shows an example of a position of the alignment aid 1937 of a BH laser relative to the alignment aid 1935 of an interposer after placement of the BH laser die onto the interposer. These positions are labeled, “Placement position.” Some misalignment is expected at placement given the required clearance to avoid unwanted collisions between the features on the BH laser and the features on the interposer. Each of the examples also shows a position of the alignment aids after the BH laser die is brought into alignment using a solder reflow process. These positions are labeled, “Aligned position.”

Shaped nestable features include the V-shaped pillars on an embodiment of a BH laser coupled with a triangle-shaped pillar as shown in FIG. 19A(i), circle-shaped pillars as shown in FIG. 19A(ii), and trapezoid-shaped pillars as shown in FIG. 19A(iii), although other shaped features and combinations of features may also be used and remain within the scope of embodiments. The V-shaped alignment aids on some embodiments of the BH laser die, form a contact with the alignment aids 1935 on the interposer to guide the BH laser into alignment during heating in a solder reflow step in which the surface tension in the molten solder pulls the BH laser die, and the alignment features 1937, toward the alignment features 1935 on the interposer.

Other examples of pillar-type alignment features 1937 are shown in FIGS. 19A(iv)-19A(vi). In FIG. 19A(vi), a semicircular-shaped recess is shown in the top view for the alignment aid 1937 on an embodiment of a BH laser, and this semicircular alignment aid 1937 is shown with a circle-shaped alignment aid 1935 on an interposer. As the solder in the electrical contacts is melted, the alignment aid on the laser die is brought into contact with the alignment aid on the interposer. The combination of the semicircular cavity of the BH laser die alignment aid 1937 in contact with the circle-shaped feature of the interposer alignment aid 1935 causes the movement of the alignment aids 1937,1935 into alignment as shown in the “aligned position” in FIG. 19A(iv). A similarly shaped pillar feature combination as that shown in FIG. 19A(iv) is shown in FIG. 19A(v) with variations in the curvature of the alignment aids on both the laser die and the interposer. Another example of an alignment aid 1937 on an embodiment of a laser die with yet another shape is shown in FIG. 19A(vi).

And yet additional examples of pillar-type alignment features 1937 are shown in FIGS. 19A(vii)-19A(ix). In FIG. 19A(vii), an additional shoulder is provided on the alignment aid 1937 in comparison to the V-shaped features shown in FIG. 19A(i), for example. The additional shoulder on the alignment aid can provide a broader capture area and a secondary restriction in lateral movement in combination with the example complementary alignment aid 1935 shown. FIG. 19A(vii) shows example of reliefs that can be formed in one or more of the alignment aids 1937 on the embodiments of the BH laser and the complementary alignment aids 1935 formed on an interposer. The reliefs can, for example, promote contact in the broader contact areas rather than in the more restricted portions of the structure such as at the vertex of the “v” in a v-shaped feature or at locations where transitions between surfaces can occur as shown. The reliefs can also prevent particle accumulation in the restricted and transitional areas that could interfere with the alignment process.

In yet another example of an alignment aid, shown in FIG. 19A(ix), multiple contact-forming locations can be provided on the alignment aids 1937 of the BH laser die that can be coupled to multiple alignment pillars 1935a,1935b on the interposer. Alignment pillar 1937 in FIG. 19A(ix) couples with multiple features 1935a,1935b on an interposer, with the potential for the formation of multiple contacts as the BH laser with alignment feature 1937 is brought into alignment on the interposer. Contacts, in this example, can be formed such that movement is restricted in the y-direction, as for example at the point labeled “A” between the alignment feature 1937 on the laser and the alignment feature 1935a, and can be made at the points labeled “B” between the alignment feature 1937 on the laser and the alignment feature 1935b on the interposer to constrain movement in the +x and −x directions allowable between the feature 1935b on the interposer and the opening on the BH laser feature 1937. The constrained movement within points “B” can facilitate guidance for the sliding movement of the feature 1935a with the pillar on the BH laser 1937 where the contact is formed.

The shapes of the alignment pillars 1937 on the embodiments of the BH laser die shown in FIG. 19A are examples of some shapes that can be used in the formation of pillar-type alignment aids, that in combination with complementary pillar-type alignment aids formed on an interposer, can facilitate lateral alignment of the alignment axes of the BH laser die with that of an optical device such as a planar waveguide on an interposer. The contribution to the lateral alignment for the embodiments of FIG. 19A, in the +x and −x directions as noted in the reference drawings provided and described herein, can be combined with the constraining lateral alignment aids described for example, in FIGS. 1A and 2A.

FIGS. 19B(i)-19B(viii) show additional examples of cavity-type alignment aids 1937 that are coupled with complementary pillar-type alignment aids 1935 of an interposer. Cavity-type alignment aids on embodiments of the BH laser are shown, for example, in FIGS. 2B, 2C, 12C, 15B, 15C, 17G and 18B. The cavity-type alignment aid shown in FIG. 19B(i) is similar to the alignment aid shown in FIG. 17G. For the rectangular cavity 1927 in the alignment pillar 1937 in FIGS. 19B(i)-19B(iii), the alignment pillars 1935 on a complementary interposer can be formed in a variety of shapes that include the rectangle-shaped pillar in FIG. 19B(i), the circle-shaped pillar in FIG. 19B(ii), and the oval-shaped pillar in FIG. 19B(iii), among many other shapes, such that in the aligned positions, one or more inside wall surfaces within the cavity form one or more of a constraint for movement and a contact with the alignment pillar 1935 that restricts movement on an interposer. Example contacts are shown between the arrows in each of the alignment aid configurations in the “Aligned position” shown in FIG. 19B. Embodiments of the BH laser can also be configured with other shaped cavities 1927 as for example, the configurations shown in FIGS. 19B(iv)-19B(viii). In the configurations shown in FIG. 19B(iv) an oval-shaped cavity 1927 on the alignment aid 1937 of the BH laser is coupled to an oval-shaped pillar-type alignment aid 1935 on an interposer, and in FIG. 19B(v), a circle-shaped cavity 1927 on the alignment aid 1937 of the BH laser is coupled to a circle-shaped pillar-type alignment aid 1935 on an interposer.

FIGS. 19B(vi)-19B(viii) show additional examples of a cavity that includes an angled portion that has a similar centering function as, for example, the embodiments shown in FIG. 19A. As the BH laser die moves into alignment, driven by the surface tension in the molten solder on the electrical contacts upon heating, the positioning of the contacting surfaces of the alignment aids 1935,1937 act to move the centers of the features into alignment for the embodiments shown. In the “Aligned position” for each embodiment, BH laser die is shown after one or more contacts have been formed between the interior cavity surface of the alignment aids 1937 and the outside surface of the alignment aids 1935 on the interposer. In FIGS. 19B(vi)-19B(viii), the interior wall of the cavity 1927 of the alignment aid 1937 on a BH laser is shown in contact with a trapezoid-shaped alignment feature 1935 of an interposer in FIG. 19B(vi), with an oval-shaped alignment feature 1935 of an interposer in FIG. 19B(vii), and with a circle-shaped alignment feature 1935 of an interposer in FIG. 19B(viii). Other shaped features may also be used for the cavity 1927 of the alignment features 1937 and for the pillar-type alignment aids 1935 of the interposer such that movement of the BH laser die is restricted in the y direction shown and such that the movement of the BH laser die is one or more of constrained and restricted in the +x and −x directions.

It should be noted that in embodiments, significant latitude is available in the shape of the outside of the alignment aid 1937 on the BH laser die. The inside surface or surfaces of the cavity-type alignment aids form the aligning contacts with the alignment aids 1935 on a complementary interposer. In embodiments for which the outside surfaces of the cavity-type alignment structure are used as aids to facilitate alignment, the descriptive aspects of the pillar-type alignment aids described herein are applicable. In some embodiments, however, the shape of the outside of the cavity-type alignment feature may contribute to the strength and robustness of the alignment aids 1937.

It should also be noted that the alignment aid structures described herein, in FIGS. 19A and 19B, for example, and throughout this disclosure, can be used individually or in combination with other alignment aids described herein. A cavity-type alignment aid such as the alignment aid 1937 shown in FIG. 19B(i), for example, may be combined with a pillar-type alignment aid such as the pillar-type alignment aid 1937 shown in FIG. 19A(i) to form a single alignment aid or combination of alignment aids.

In other embodiments, pillar-type alignment features 1937 can be formed on the BH laser and coupled to cavity-type alignment features 1935 formed on the interposer. In these embodiments, shaped pillar-type features are formed on the BH laser with shapes described herein for the interposer, and conversely, complementary cavity-type alignment aids are formed on an interposer.

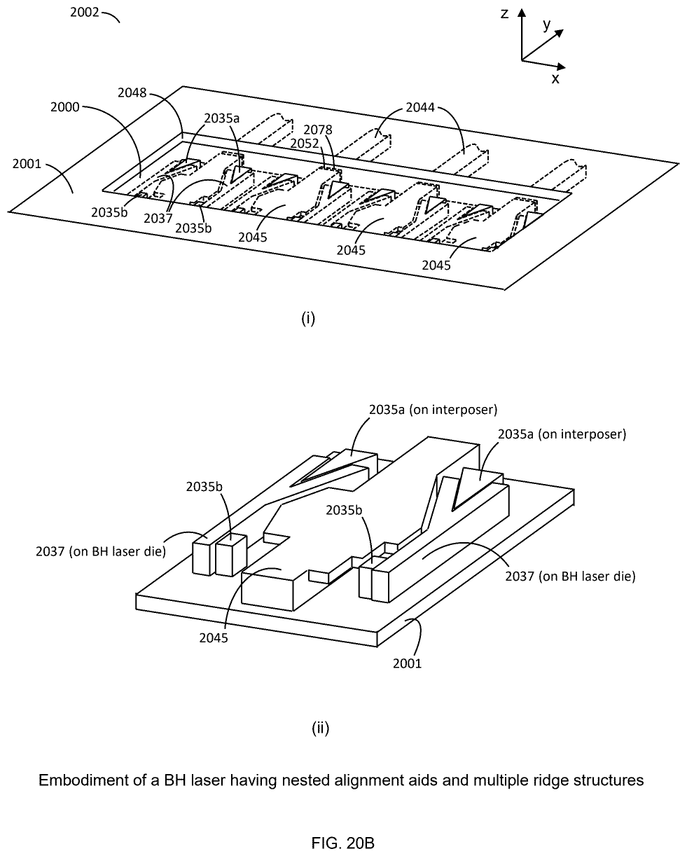

FIGS. 20A and 20B show embodiments of BH laser die that include multiple ridge structures. The formation of multiple ridge structures on a BH laser die enables the inclusion of multiple laser output signals for a single die placement onto an interposer.

FIG. 20A shows a cross section drawing of an embodiment of a BH laser die 2000 having two laser pedestals 2046. Each laser pedestal 2046 includes a ridge structure 2045 that further includes an emission layer for the laser (described herein.) BH laser die 2000 includes vertical alignment aids 2036 having horizontal alignment surfaces 2026 and lateral alignment aids 2037 having vertical alignment surfaces 2028 to enable vertical and lateral alignment with a complementary interposer, for example. BH laser die 2000 can be formed using the method of formation, for example, in FIG. 3 with the inclusion of more than one BH laser structure as described in Step 389 of method 310 shown in FIG. 3.

FIG. 20B(i) shows a perspective drawing of another embodiment of a BH laser 2000 having four BH laser pedestals 2046. In FIG. 20B(i), the embodiment 2000 is shown positioned within cavity 2048 on a portion of an interposer 2001. The four laser pedestals 2045 of the embodiment of the BH laser die 2000 are shown in alignment with planar waveguides 2044 formed in the interposer 2001. In embodiments, the optical axis for each of the ridge structures in the laser pedestals 2046 is aligned with an optical axis of a planar waveguide 2044 in the interposer 2001. Alignment aids 2037 of the BH laser die 2000 coupled to alignment aids 2035a,2035b on the interposer, enable simultaneous alignment of the four optical axes within the four laser pedestals 2045 with the corresponding four optical axes of the four planar waveguides 2044 on the interposer.

The embodiment of FIG. 20B(i) shows a configuration for the lateral alignment aids 2037 of the BH laser embodiment 2000 that form contacts with and are constrained in movement by the complementary triangle-shaped pillars 2035a and rectangle-shaped pillars 2035b shown on the example interposer. FIG. 20B(ii) shows an enlarged drawing of a portion of one of the pedestal and alignment aid portions of FIG. 20B(i). The substrate of the BH laser die is not shown in the enlarged drawing of FIG. 20B(ii) to more clearly show the laser pedestal and alignment aids in this figure. Each of the alignment structures 2037 shown in the embodiment in FIG. 20B are formed from a combination of a pillar-type lateral alignment aid portion that has an opening to receive the triangle-shaped interposer pillar 2035a, as shown for example in FIG. 19A(i), and a portion that forms a constraint for the rectangle-shaped interposer pillar 2035b on the interposer 2001, as shown, for example, in FIG. 1A. In the embodiment shown in FIG. 20B, the two alignment aids on the BH laser are coupled with two triangle-shaped alignment pillars and two rectangle shaped alignment aids on an interposer. Each laser pedestal 2046, in the embodiment shown is formed with an accompanying pair of alignment aids 2037.

The embodiment for the BH laser 2000 in FIG. 20A shows two laser pedestals 2046 and the embodiment for the BH laser 2000 in FIG. 20B shows four laser pedestals 2046, each containing a light emitting ridge portion. In other embodiments, other quantities of laser pedestals may be used.

The embodiment of FIG. 20A shows two pillar-type lateral alignment aids 2037. In other embodiments, other types and quantities of lateral alignment aids, as described herein, may be used. In some embodiments, for example, that include multiple BH laser ridge structures, cavity-type lateral alignment aids can be used. Other configurations of lateral and vertical alignment aids described herein, and combinations of lateral and vertical alignment aids described herein may be used.

In other embodiments with multiple pedestal and ridge structures, fewer or more alignment aids 2037, sets of alignment aids, and combinations of alignment aids than the number of laser pedestals may be provided. In an embodiment, for example, lateral alignment aids 2037 are provided only with the laser pedestals at the lateral ends of the BH laser die 2000. In embodiments with multiple ridge structures, one or more lateral alignment aids may be used. In some embodiments, lateral alignment aids may be provided with each of the laser pedestals.

Embodiments of BH laser die having alignment aids are described herein. Alignment aids in embodiments of BH laser die can be formed using common epitaxial growth techniques. The inclusion of etch stop layers in the BH laser layer structures facilitates the formation of vertical and lateral alignment aids, and the use of a same patterning process to form one or more BH laser ridge, one or more lateral alignment aids, and one or more fiducials in embodiments, enables the alignment of these features within the accuracy of the lithographic and patterning processes used.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

What is claimed is:

1. A method comprising
placing and localized heating one or more devices in sequence,
wherein placing a device of the one or more devices comprises placing a solder ball associated with the device to be in contact or in close proximity with a contact on a substrate, with the close proximity characterized as a separation that a melted contact is formed between the solder and the contact after the localized heating,
wherein localized heating the placed device comprises heating in a vicinity of the solder ball to bond the device with the contact for affixing the device with the substrate;
heating the substrate,
wherein the substrate heating is configured to move the one or more devices to respective aligned positions.

2. A method as in claim 1,
wherein heating in a vicinity of the solder ball comprises providing emission from a laser or another radiation source through the substrate to the solder ball.

3. A method as in claim 1,
wherein the substrate heating is performed in an oven, with temperature of the oven is raised gradually to at least a melting temperature of the solder.

4. A method as in claim 1, further comprising
repeating placing and localizing heating for one or more second devices and re-heating the substrate,
wherein the one or more second devices are associated with second solder balls having a lower melting temperature than a higher melting temperature of the solder balls associated with the one or more devices,
wherein re-heating the substrate comprises heating the substrate at the lower melting temperature as compared to heating the substrate at the higher melting temperature.

5. A method comprising
placing and localized heating one or more devices on a substrate in sequence,
wherein placing a device of the one or more devices comprises
placing the device on the substrate to align the device to an optical element of one or more optical elements on the substrate,
wherein a first contact on the substrate associated with the optical element is placed into contact or in close proximity to a second contact of the device through a solder ball, with the solder ball coupled to the first contact or to the second contact,
wherein the close proximity is characterized as a distance that a melted contact is formed between the first contact, the solder, and the second contact after the localized heating,
wherein localized heating the placed device comprises
heating in a vicinity of the solder ball,
wherein the localized heating is configured to bond the second contact with the first contact through the solder ball for affixing the device with the substrate;
heating the substrate,
wherein the substrate heating is configured to move the one or more devices to respective aligned positions.

6. A method as in claim 5,
wherein the substrate comprises one or more first alignment aids, with at least a first alignment aid of the one or more first alignment aids associated with the each optical element,
wherein at least a device of the one or more devices comprises at least a second alignment aid, with the at least a second alignment aid corresponded to the at least a first alignment aid to assist in aligning the at least a device to the each optical element.

7. A method as in claim 5,
wherein each device of the one or more devices is placed and then locally heated in series.

8. A method as in claim 5,
wherein multiple devices of the one or more devices are placed before locally heated in series.

9. A method comprising
providing a substrate,
wherein the substrate comprises one or more first contacts,
wherein the substrate comprises one or more optical elements, with each optical element of the one or more optical elements associated with a first contact of the one or more first contacts;
providing one or more devices,
wherein each device of the one or more devices comprises a second contact;
placing and localized heating the one or more devices in sequence,
wherein placing a device of the one or more devices comprises
placing the device on the substrate to align the device to an optical element,
wherein at least one of a first contact associated with the optical element or the second contact of the device is coupled to a solder ball,
wherein the solder ball is in contact or in close proximity with the first or second contacts, with the close proximity characterized as a melted contact is formed between the first contact, the solder, and the second contact after the localized heating,
wherein the device is at least partially align to the optical element,
wherein localized heating the placed device comprises
heating in a vicinity of the solder ball,
wherein the localized heating is configured to bond the second contact with the first contact through the solder ball for affixing the device with the substrate;
heating the substrate,
wherein the substrate heating is configured to move the one or more devices to respective aligned positions.

10. A method as in claim 9,
wherein the substrate comprises one or more cavities, with each cavity of the one or more cavities associated with the each optical element,
wherein the each cavity comprises at least one of a vertical alignment aid or a lateral alignment aid.

11. A method as in claim 9,
wherein the substrate comprises one or more vertical alignment aids, with the one or more vertical alignment aids configured to align the one or more devices in a direction perpendicular to the substrate.

12. A method as in claim 9,
wherein the substrate comprises one or more lateral alignment aids, with the one or more lateral alignment aids configured to restrict the one or more devices during the movements to the aligned positions.

13. A method as in claim 9,
wherein placing the device on the substrate comprises placing the device so that a vertical alignment aid of the device contacts a vertical alignment aid on the substrate.

14. A method as in claim 9,
wherein placing the device on the substrate to align the device to an optical element comprises placing the device to have a gap between an output facet of the device and a facet of the optical element.

15. A method as in claim 9,
wherein placing a device comprises a pick-and-place apparatus picking and placing the device on the substrate,
wherein the device is decoupled from the pick and place apparatus before heating the solder ball.

16. A method as in claim 9,
wherein placing a device comprises a pick-and-place apparatus picking and placing the device on the substrate,
wherein the device is supported by the pick and place apparatus during at least a portion of the localized heating.

17. A method as in claim 9,
wherein placing a device comprises a pick-and-place apparatus picking and placing the device on the substrate,
wherein the device is decoupled from the pick and place apparatus after heating the solder ball, with the solder still in a liquid or semi-liquid state when the pick and place apparatus is decoupled from the device.

18. A method as in claim 9,
wherein placing a device comprises a pick-and-place apparatus picking and placing the device on the substrate,
wherein the solder is solidified after the localized heating before the pick and place apparatus releases the device.

19. A method as in claim 9,
wherein the aligned positions of the one or more devices are configured to improve an alignment between optical outputs from the one or more devices and the optical elements, respectively.

20. A method as in claim 9,
wherein the substrate heating is configured to move facets of the one or more devices closer to facets of the optical elements, respectively.
